(19) United States
(12) Patent Application Publication
(10) Pub. No.: US 2014/0027723 A1
(43) Pub. Date: Jan. 30, 2014

(54) ORGANIC LIGHT EMITTING DEVICE INCLUDING COMPOUNDS

(71) Applicant: SAMSUNG DISPLAY CO., LTD, Yongin-City (KR)

(72) Inventors: Se-Hun Kim, Yongin-City (KR); Ji-Youn Lee, Yongin-City (KR); Mi-Kyung Kim, Yongin-City (KR); Kwan-Hee Lee, Yongin-City (KR); Soo-Young Park, Yongin-City (KR); lll-Hun Cho, Yongin-City (KR)

(73) Assignees: SEOUL NATIONAL UNIVERSITY P&DB FOUNDATION, Seoul (KR); SAMSUNG DISPLAY CO., LTD, Yongin-City (KR)

(21) Appl. No.: 13/736,404

(22) Filed: Jan. 8, 2013

(30) Foreign Application Priority Data
Jul. 30, 2012 (KR) 10-2012-0083509

(51) Int. Cl. H01L 51/00

(52) U.S. Cl. CPC H01L 51/0058; H01L 51/0072; H01L 51/0052; H01L 51/0055
USPC 257/40

(57) ABSTRACT

In one aspect, an organic light-emitting device including an anthracene-base compound and an indenophenanthrene-base compound is provided.

### CROSS-REFERENCE TO RELATED APPLICATION

This application claims priority to and the benefit of Korean Patent Application No. 10-2012-0083509, filed in the Korean Intellectual Property Office on Jul. 30, 2012, the disclosure of which is incorporated herein by reference in its entirety.

### BACKGROUND

1. Field

The described technology generally relates to an organic light-emitting device including a compound represented by Formula 1 and a compound represented by Formula 2.

2. Description of the Related Technology

Organic light-emitting devices (OLEDs), which are self-emitting devices, have advantages such as wide viewing angles, excellent contrast, quick response, high brightness, excellent driving voltage characteristics, and can provide multicolored images.

A typical OLED has a structure including a substrate, and an anode, a hole transport layer (HTL), an emission layer (EML), an electron transport layer (ETL), and a cathode which are sequentially stacked on the substrate. In this regard, the HTL, the EML, and the ETL are organic thin films formed of organic compounds.

An operating principle of an OLED having the above-described structure is as follows.

When a voltage is applied between the anode and the cathode, holes injected from the anode move to the EML via the HTL, and electrons injected from the cathode move to the EML via the ETL. The holes and electrons recombine in the EML to generate excitons. When the excitons drop from an excited state to a ground state, light is emitted.

Known light-emitting materials available for the OLED are chilate complexes, such as tris(8-quinolinolato)aluminum complex, coumarin derivatives, tetraphenylbutadien derivatives, bisstyrylarylene derivatives, oxadiazole derivatives, and the like. These light-emitting materials are known to emit light in a visible range of from blue to red colors, and thus are applicable in manufacturing color display devices. Use of a phenylanthracene derivative as a blue light-emitting material in a light-emitting device is disclosed. However, this light-emitting device needs further improvements in terms of color purity, efficiency, and lifetime.

### SUMMARY

The present embodiments provide an organic light-emitting device using an anthracene-base compound with a carbazole group and an indenophenanthrene compound as organic light-emitting materials, and thus having high color purity, high efficiency, and relatively long lifetime.

According to an aspect of the present embodiments, there is provided an organic light-emitting device including: a first electrode; a second electrode; and an organic layer disposed between the first electrode and the second electrode, wherein the organic layer includes a compound represented by Formula 1 below and a compound represented by Formula 2:

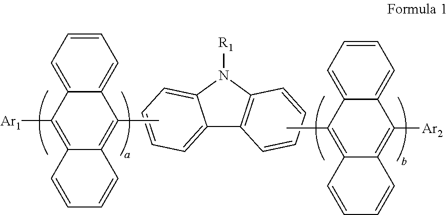

wherein, in Formula 1,

R₁ may be a hydrogen atom, a deuterium atom, a substituted or unsubstituted C₁-C₆₀ alkyl group, a substituted unsubstituted C₂-C₆₀ alkenyl group, a substituted unsubstituted C₂-C₆₀ alkynyl group, a substituted or unsubstituted C₆-C₆₀ aryl group, a substituted or unsubstituted C₃-C₆₀ heteroaryl group, a substituted or unsubstituted C₁-C₆₀ alkoxy group, a substituted or unsubstituted C₆-C₆₀ aralkyl group, a substituted or unsubstituted C₆-C₆₀ aryloxy group, a substituted or unsubstituted C₆-C₆₀ arylthio group, a substituted or unsubstituted C₁-C₆₀ alkoxycarbonyl group, a carboxyl group, a halogen group, a cyano group, a nitro group, or a hydroxyl group;

Ar₁ and Ar₂ may each be independently a hydrogen atom, a deuterium atom, a substituted or unsubstituted C₆-C₆₀ aryl group, or a substituted or unsubstituted C₃-C₆₀ heteroaryl group;

a may be an integer of 1 or 2; and b may be an integer from 0 to 2,

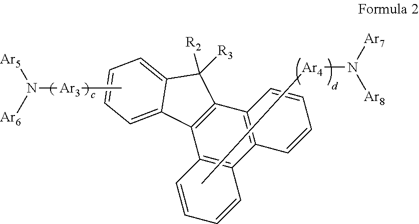

wherein, in Formula 2,

R₂ to R₃ may each be independently a hydrogen atom, a deuterium atom, a substituted or unsubstituted C₁-C₆₀ alkyl group, a substituted or unsubstituted C₃-C₆₀ cycloalkyl group, a substituted or unsubstituted C₁-C₂₀ alkoxy group, or a substituted or unsubstituted C₆-C₁₂ aryl group, and R₂ and R₃ are optionally linked to form a ring;

Ar₃ and Ar₄ may each be independently a substituted or unsubstituted C₆-C₅₀ arylene group;

Ar₅ and Ar₈ may each be independently a substituted or unsubstituted C₆-C₆₀ aryl group, or a substituted or unsubstituted C₃-C₆₀ heteroaryl group; and

c and d may each be independently an integer from 0 to 1.

According to another aspect of the present embodiments, there is provided a flat panel display device including the above-described organic light-emitting device, wherein the first electrode of the organic light-emitting device is electrically connected to a source electrode or a drain electrode of a thin-film transistor.

### BRIEF DESCRIPTION OF THE DRAWINGS

The above and other features and advantages of the present embodiments will become more apparent by describing in detail exemplary embodiments thereof with reference to the attached drawing in which:

FIG. 1 schematically illustrates the structure of an organic light-emitting device according to an aspect of the present embodiments.

### DETAILED DESCRIPTION

As used herein, the term “and/or” includes any and all combinations of one or more of the associated listed items. Expressions such as “at least one of,” when preceding a list of elements, modify the entire list of elements and do not modify the individual elements of the list.

According to an embodiment, an organic light-emitting device includes a first electrode, a second electrode, and an organic layer between the first electrode and the second electrode, the organic layer including a compound represented by Formula 1 and a compound represented by Formula 2.

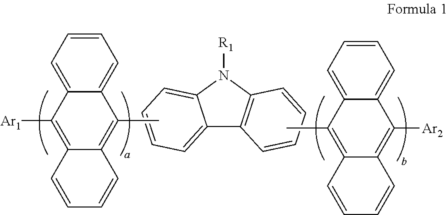

R₁ may be a hydrogen atom, a deuterium atom, a substituted or unsubstituted C₁-C₆₀ alkyl group, a substituted unsubstituted C₂-C₆₀ alkenyl group, a substituted unsubstituted C₂-C₆₀ alkynyl group, a substituted or unsubstituted C₆-C₆₀ aryl group, a substituted or unsubstituted C₃-C₆₀ heteroaryl group, a substituted or unsubstituted C₁-C₆₀ alkoxy group, a substituted or unsubstituted C₆-C₆₀ aralkyl group, a substituted or unsubstituted C₆-C₆₀ aryloxy group, a substituted or unsubstituted C₆-C₆₀ arylthio group, a substituted or unsubstituted C₁-C₆₀ alkoxycarbonyl group, a carboxyl group, a halogen group, a cyano group, a nitro group, or a hydroxyl group;

Ar₁ and Ar₂ are each independently a hydrogen atom, a deuterium atom, a substituted or unsubstituted C₆-C₆₀ aryl group, or a substituted or unsubstituted C₃-C₆₀ heteroaryl group;

a may be an integer of 1 or 2; and b may be an integer from 0 to 2.

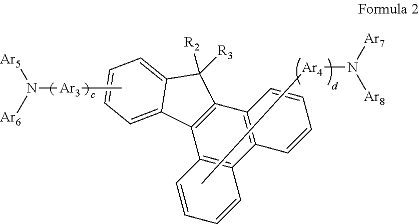

In Formula 2 above, R₂ to R₃ may each be independently a hydrogen atom, a deuterium atom, a substituted or unsubstituted C₁-C₆₀ alkyl group, a substituted or unsubstituted C₃-C₆₀ cycloalkyl group, a substituted or unsubstituted C₁-C₂₀ alkoxy group, or a substituted or unsubstituted C₆-C₁₂ aryl group, and R₂ and R₃ may be optionally linked to form a ring;

Ar₃ and Ar₄ may each be independently a substituted or unsubstituted C₆-C₅₀ arylene group;

Ar₅ and Ar₈ may each be independently a substituted or unsubstituted C₆-C₆₀ aryl group, or a substituted or unsubstituted C₃-C₆₀ heteroaryl group; and

c and d may each be independently an integer of 0 or 1;

The compound of Formula 1 may be a host, and the compound of Formula 2 may be a dopant.

According to the above-described embodiments, the organic light-emitting device may have high efficiency and relatively long lifetime characteristics, and thus is applicable in a full-color display device or a (stacked) white organic light-emitting device (for a LGD TV structure or a white illumination organic light-emitting device structure).

The compound of Formula 1 above does not include a linker between a carbazole moiety and an anthracene moiety, and thus has a reduced conjugation length and is able to emit darker blue light.

Substituents in the compound of Formula 1 will now be described in detail.

In an aspect of the present embodiments, the compound of Formula 1 may be a compound represented by Formula 3.

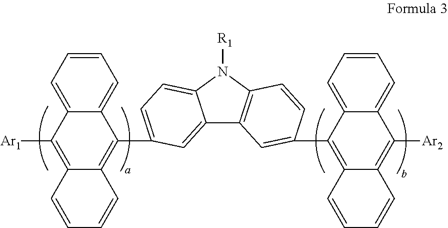

In Formula 3, R₁ may be a hydrogen atom, a deuterium atom, a substituted or unsubstituted C₁-C₆₀ alkyl group, a substituted unsubstituted C₂-C₆₀ alkenyl group, a substituted unsubstituted C₂-C₆₀ alkynyl group, a substituted or unsubstituted C₆-C₆₀ aryl group, a substituted or unsubstituted C₃-C₆₀ heteroaryl group, a substituted or unsubstituted C₁-C₆₀ alkoxy group, a substituted or unsubstituted C₆-C₆₀ aralkyl group, a substituted or unsubstituted C₆-C₆₀ aryloxy group, a substituted or unsubstituted C₆-C₆₀ arylthio group, a substituted or unsubstituted C₁-C₆₀ alkoxycarbonyl group, a carboxyl group, a halogen group, a cyano group, a nitro group, or a hydroxyl group;

Ar₁ and Ar₂ may each be independently a hydrogen atom, a deuterium atom, a substituted or unsubstituted C₆-C₆₀ aryl group, or a substituted or unsubstituted C₃-C₆₀ heteroaryl group; and

a may be an integer of 1 or 2; and b may be an integer from 0 to 2.

In an aspect of the present embodiments, the compound of Formula 2 may be a compound represented by Formula 4 below.

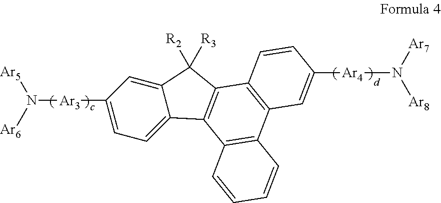

In Formula 4 above, R₂ to R₃ may each be independently a hydrogen atom, a deuterium atom, a substituted or unsubstituted C₁-C₆₀ alkyl group, a substituted or unsubstituted C₃-C₆₀ cycloalkyl group, a substituted or unsubstituted C₁-C₂₀ alkoxy group, or a substituted or unsubstituted C₆-C₁₂ aryl group, or R₂ and R₃ are linked to form a ring;

Ar₃ and Ar₄ may each be independently a substituted or unsubstituted C₆-C₅₀ arylene group;

Ar₅ and Ar₈ may each be independently a substituted or unsubstituted C₆-C₆₀ aryl group, or a substituted or unsubstituted C₃-C₆₀ heteroaryl group; and

c and d may each be independently an integer of 0 or 1;

In some embodiments, R₂ and R₃ in Formula 2 above may be linked together to form a ring.

In some embodiments, R₁ in Formula 1 may be a substituted or unsubstituted C₁-C₆₀ alkyl group, a substituted or unsubstituted C₆-C₆₀ aryl group, or a substituted or unsubstituted C₃-C₆₀ heteroaryl group.

In some embodiments, Ar₁ and Ar₂ in Formula 1 may be each independently a hydrogen atom, a deuterium atom, a substituted or unsubstituted C₆-C₆₀ aryl group, or a substituted or unsubstituted C₃-C₆₀ heteroaryl group.

In some embodiments, R₁ in Formula 1 may be a substituted or unsubstituted ethenyl group, a substituted or unsubstituted phenyl group, a substituted or unsubstituted naphthyl group, a substituted or unsubstituted pyridyl group, or a substituted or unsubstituted quinoline group.

In some embodiments, Ar₁ and Ar₂ in Formula 1 may be each independently a substituted or unsubstituted phenyl group, a substituted or unsubstituted naphthyl group, a substituted or unsubstituted pyridyl group, or a substituted or unsubstituted quinoline group.

In some embodiments, R₂ and R₃ in Formula 2 may be each independently a methyl group or a phenyl group.

In some embodiments, Ar₃ and Ar₄ in Formula 2 may be each independently one of the groups represented by Formulae 5 to 9 below:

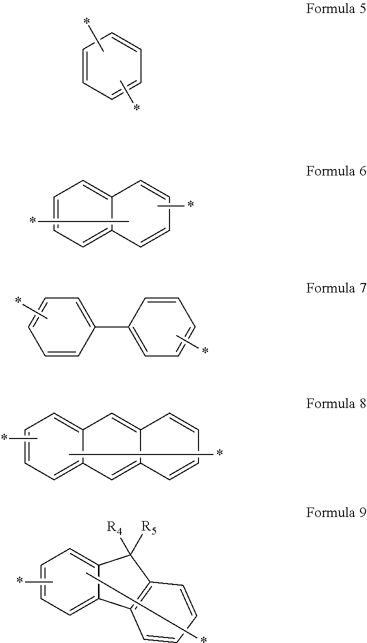

In Formula 9 above, R₄ and R₅ may be each independently a hydrogen atom, a deuterium atom, a substituted or unsubstituted C₁-C₂₀ alkyl group, a substituted or unsubstituted C₆-C₂₀ cycloalkyl group, a substituted or unsubstituted C₁-C₂₀ alkoxy group, or a substituted or unsubstituted C₆-C₁₂ aryl group, wherein R₄ and R₅ may be optionally linked to each other to form a ring. At least one hydrogen atom in Formulae 5 to 9 may be optionally replaced with a deuterium atom, a halogen atom, a hydroxyl group, a nitro group, a cyano group, an amino group, an amidino group, hydrazine, hydrazone, a carboxyl group or a salt thereof, a sulfonic acid group or a salt thereof, a phosphoric acid or a salt thereof, or a C₁-C₁₀ alkyl group, a C₁-C₁₀ alkoxy group, a C₂-C₁₀ alkenyl group, a C₂-C₁₀ alkynyl group, a C₆-C₁₆ aryl group, or a C₄-C₁₆ heteroaryl group, wherein * indicates the respective attachment point to the parent molecule.

In some embodiments, Ar₅ and Ar₈ in Formula 2 may be each independently one of the groups represented by Formulae 10 to 19 below:

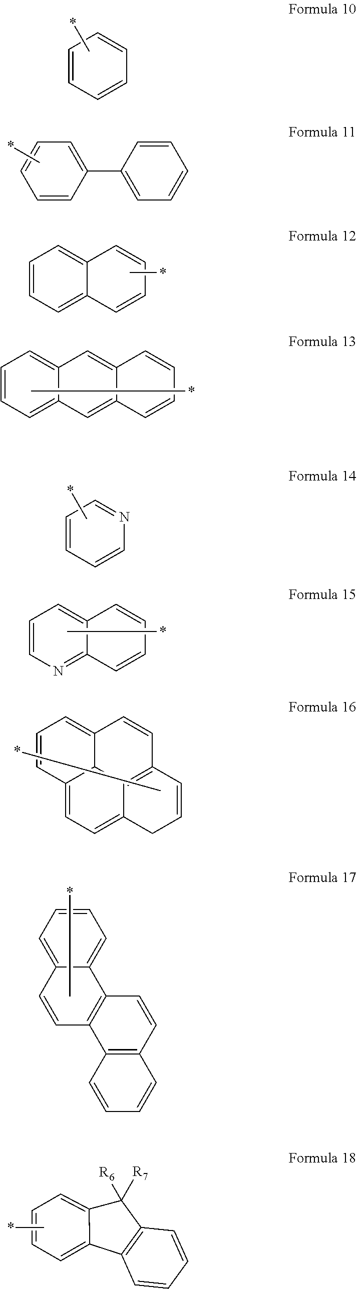

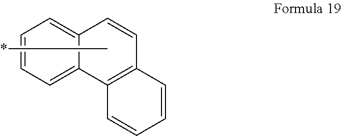

In Formula 18 above, R₆ and R₇ may be each independently a hydrogen atom, a deuterium atom, a substituted or unsubstituted C₁-C₂₀ alkyl group, a substituted or unsubstituted C₆-C₂₀ cycloalkyl group, a substituted or unsubstituted C₁-C₂₀ alkoxy group, or a substituted or unsubstituted C₆-C₁₂ aryl group, and R₆ and R₇ may be optionally linked to each other to form a ring. At least one hydrogen atom in Formulae 10 to 19 may be optionally substituted with a deuterium atom, a halogen atom, a hydroxyl group, a nitro group, a cyano group, an amino group, an amidino group, hydrazine, hydrazone, a carboxyl group or a salt thereof, a sulfonic acid group or a salt thereof, a phosphoric acid or a salt thereof, or a C₁-C₁₀ alkyl group, a C₁-C₁₀ alkoxy group, a C₂-C₁₀ alkenyl group, a C₂-C₁₀ alkynyl group, a C₆-C₁₆ aryl group, or a C₄-C₁₆ heteroaryl group, wherein * indicates a binding site.

Hereinafter, substituents described with reference to the formulae will now be described in detail. In this regard, the numbers of carbons in substituents are presented only for illustrative purposes and do not limit the characteristics of the substituents

The unsubstituted C₁-C₆₀ alkyl group used herein may be linear or branched. Non-limiting examples of the alkyl group are a methyl group, an ethyl group, a propyl group, an isobutyl group, a sec-butyl group, a pentyl group, an iso-amyl group, a hexyl group, a heptyl group, an octyl group, a nonanyl group, and a dodecyl group. At least one hydrogen atom of the alkyl group may be substituted with a deuterium atom, a halogen atom, a hydroxyl group, a nitro group, a cyano group, an amino group, an amidino group, hydrazine, hydrazone, a carboxyl group or a salt thereof, a sulfonic acid group or a salt thereof, a phosphoric acid group or a salt thereof, a C₁-C₁₀ alkyl group, a C₁-C₁₀ alkoxy group, a C₂-C₁₀ alkenyl group, a C₂-C₁₀ alkynyl group, a C₆-C₁₆ aryl group, or a C₄-C₁₆ heteroaryl group. (These listed substituents of the alkyl group may be available for any other substituted functional groups referred to herein.)

The unsubstituted C₂-C₆₀ alkenyl group indicates an unsaturated alkyl groups having at least one carbon-carbon double bond in the center or at a terminal of the alkyl group. Examples of the alkenyl group are an ethenyl group, a propenyl group, a butenyl group, and the like. At least one hydrogen atom in the unsubstituted alkenyl group may be substituted with any substituent described above in conjunction with the alkyl group.

The unsubstituted C₂-C₆₀ alkynyl group indicates an alkyl group having at least one carbon-carbon triple bond in the center or at a terminal of the alkyl group. Examples of the unsubstituted C₂-C₂₀ alkynyl group are acetylene, propylene, phenylacetylene, naphthylacetylene, isopropylacetylene, t-butylacetylene, diphenylacetylene, and the like. At least one hydrogen atom in the alkynyl group may be substituted with any substituent described above in conjunction with the alkyl group.

The unsubstituted C₃-C₆₀ cycloalkyl group indicates a C₃-C₆₀ cyclic alkyl group wherein at least one hydrogen atom in the cycloalkyl group may be substituted with any substituent described above in conduction with the C₁-C₆₀ alkyl group.

The unsubstituted C₁-C₆₀ alkoxy group indicates a group having a structure of —OA wherein A is an unsubstituted C₁-C₆₀ alkyl group as described above. Nonlimiting examples of the unsubstituted C₁-C₆₀ alkoxy group include a methoxy group, an ethoxy group, a propoxy group, an isopropyloxy group, a butoxy group, and a pentoxy group. At least one hydrogen atom of the alkoxy group may be substituted with any substituent described above in conjunction with the alkyl group.

The C₇-C₆₀ aralkyl group means a substituent with aryl and alkyl groups linked together. Non-limiting examples of the substituted or unsubstituted aralkyl group are benzyl, 1-phenylethyl, 2-phenylethyl, 1-phenylisopropyl, 2-phenylisopropyl, phenyl-t-butyl, α-naphthylmethyl, 1-α-naphthylethyl, 2-α-naphthylethyl, 1-α-naphthylisopropyl, 2-α-naphthylisopropyl, β-naphthylmethyl, 1-β-naphthylethyl, 2-β-naphthylethyl, 1-β-naphthylisopropyl, 2-β-naphthylisopropyl, 1-pyrrolylmethyl, 2-(1-pyrrolyl)ethyl, p-methylbenzyl, m-methylbenzyl, o-methylbenzyl, p-chlorobenzyl, m-chlorobenzyl, o-chlorobenzyl, p-bromobenzyl, m-bromobenzyl, o-bromobenzyl, p-iodobenzyl, m-iodobenzyl, o-iodobenzyl, p-hydroxybenzyl, m-hydroxybenzyl, o-hydroxybenzyl, p-aminobenzyl, m-aminobenzyl, o-aminobenzyl, p-nitrobenzyl, m-nitrobenzyl, o-nitrobenzyl, p-cyanobenzyl, m-cyanobenzyl, o-cyanobenzyl, 1-hydroxy-2-phenylisopropyl, and 1-chloro-2-phenylisopropyl groups.

With regard to the C₁-C₆₀ alkoxycarbonyl group, the alkoxycarbonyl group is represented by —COOZ, wherein Z may be methyl, ethyl, propyl, isopropyl, n-butyl, s-butyl, isobutyl, t-butyl, n-pentyl, n-hexyl, n-heptyl, n-octyl, hydroxymethyl, 1-hydroxyethyl, 2-hydroxyethyl, 2-hydroxyisobutyl, 1,2-dihydroxyethyl, 1,3-dihydroxyisopropyl, 2,3-dihydroxy-t-butyl, 1,2,3-trihydroxypropyl, chloromethyl, 1-chloroethyl, 2-chloroethyl, 2-chloroisobutyl, 1,2-dichloroethyl, 1,3-dichloroisopropyl, 2,3-dichloro-t-butyl, 1,2,3-trichloropropyl, bromomethyl, 1-bromoethyl, 2-bromoethyl, 2-bromoisobutyl, 1,2-dibromoethyl, 1,3-dibromoisopropyl, 2,3-dibromo-t-butyl, 1,2,3-tribromopropyl, iodomethyl, 1-iodoethyl, 2-iodoethyl, 2-iodoisobutyl, 1,2-diiodoethyl, 1,3-diiodoisopropyl, 2,3-diiodo-t-butyl, 1,2,3-triiodopropyl, aminomethyl, 1-aminoethyl, 2-aminoethyl, 2-aminoisobutyl, 1,2-diaminoethyl, 1,3-diaminoisopropyl, 2,3-diamino-t-butyl, 1,2,3-triaminopropyl, cyanomethyl, 1-cyanoethyl, 2-cyanoethyl, 2-cyanoisobutyl, 1,2-dicyanoethyl, 1,3-dicyanoisopropyl, 2,3-dicyano-t-butyl, 1,2,3-tricyanopropyl, nitromethyl, 1-nitroethyl, 2-nitroethyl, 2-nitroisobutyl, 1,2-dinitroethyl, 1,3-dinitroisopropyl, 2,3-dinitro-t-butyl, 1,2,3-trinitropropyl, or the like.

The unsubstituted C₅-C₆₀ aryl group indicates a carbocyclic aromatic system containing at least one ring. At least two rings may be fused to each other or linked to each other by a single bond. The term ‘aryl’ refers to an aromatic system, such as phenyl, naphthyl, or anthracenyl. At least one hydrogen atom in the aryl group may be substituted with any substituent described above in conjunction with the unsubstituted C₁-C₆₀ alkyl group.

Non-limiting examples of the substituted or unsubstituted C₆-C₆₀ aryl group are a phenyl group, a C₁-C₁₀ alkylphenyl group (for example, ethylphenyl group), a halophenyl group (for example, o-, m-, and p-fluorophenyl group, dichlorophenyl group), a cyanophenyl group, dicyanophenyl group, a trifluoromethoxyphenyl group, a biphenyl group, a halobiphenyl group, a cyanobiphenyl group, a C₁-C₁₀ alkyl biphenyl group, a C₁-C₁₀ alkoxybiphenyl group, a o-, m-, and p-toryl group, an o-, m-, and p-cumenyl group, a mesityl group, a phenoxyphenyl group, a (α,α-dimethylbenzene)phenyl group, a (N,N′-dimethyl)aminophenyl group, a (N,N′-diphenyl)aminophenyl group, a pentalenyl group, an indenyl group, a naphthyl group, a halonaphthyl group (for example, fluoronaphthyl group), a C₁-C₁₀ alkylnaphthyl group (for example, methylnaphthyl group), a C₁-C₁₀ alkoxynaphthyl group (for example, methoxynaphthyl group), a cyanonaphthyl group, an anthracenyl group, an azulenyl group, a heptalenyl group, an acenaphthylenyl group, a phenalenyl group, a fluorenyl group, an anthraquinolyl group, a methylanthryl group, a phenanthryl group, a triphenylene group, a pyrenyl group, a chrycenyl group, an ethyl-chrysenyl group, a picenyl group, a perylenyl group, a chloroperylenyl group, a pentaphenyl group, a pentacenyl group, a tetraphenylenyl group, a hexaphenyl group, a hexacenyl group, a rubicenyl group, a coronelyl group, a trinaphthylenyl group, a heptaphenyl group, a heptacenyl group, a pyranthrenyl group, and an ovalenyl group.

The unsubstituted C₃-C₆₀ heteroaryl group used herein includes one, two or three hetero atoms selected from N (nitrogen), O (oxygen), P (phosphorus) and S (sulfur). At least two rings may be fused to each other or linked to each other by a single bond. Non-limiting examples of the unsubstituted C₄-C₆₀ heteroaryl group are a pyrazolyl group, an imidazolyl group, an oxazolyl group, a thiazolyl group, a triazolyl group, a tetrazolyl group, an oxadiazolyl group, a pyridinyl group, a pyridazinyl group, a pyrimidinyl group, a triazinyl group, a carbazolyl group, an indolyl group, a quinolyl group, an isoquinolyl group, and a dibenzothiophene group. In addition, at least one hydrogen atom in the heteroaryl group may be substituted with any substituent described above in conjunction with the unsubstituted C₁-C₆₀ alkyl group.

The unsubstituted C₆-C₆₀ aryloxy group is a group represented by —OA₁ wherein A₁ may be a C₆-C₆₀ aryl group. An example of the aryloxy group is a phenoxy group. At least one hydrogen atom in the aryloxy group may be substituted with any substituent described above in conjunction with the unsubstituted C₁-C₆₀ alkyl group.

The unsubstituted C₆-C₆₀ arylthio group is a group represented by —OA₁ wherein A₁ may be a C₆-C₆₀ aryl group. Non-limiting examples of the arylthio group are a benzenethio group and a naphthylthio group. At least one hydrogen atom in the arylthio group may be substituted with any substituent described above in conjunction with the unsubstituted C₁-C₆₀ alkyl group.

The unsubstituted C₆-C₆₀ condensed polycyclic group used herein refers to a substituent including at least two rings wherein at least one aromatic ring and/or at least one non-aromatic ring are fused to each other, or refers to a substitutent having an unsaturated group in a ring that may not form a conjugate structure. The unsubstituted C₆-C₆₀ condensed polycyclic group are distinct from an aryl group or a heteroaryl group in terms of being non-aromatic.

A condensed polycyclic group including N (nitrogen), O (oxygen), or S (sulfur) used herein refers to a substituent including at least two rings wherein at least one aromatic ring and/or at least one non-aromatic ring are fused to each other, or refers to a substitutent having an unsaturated group in a ring that may not form a conjugate structure. The unsubstituted C₆-C₆₀ condensed polycyclic group refers to a non-aromatic compound.

In addition, at least one hydrogen atom in the condensed polycyclic group or in the condensed polycyclic group including N (nitrogen), O (oxygen), or S (sulfur) may be substituted with any substituent described in conjunction with the unsubstituted C₁-C₆₀ alkyl group.

Non-limiting examples of the compound represented by Formula 1 are Compounds 1 to 48 represented by the following formulae.

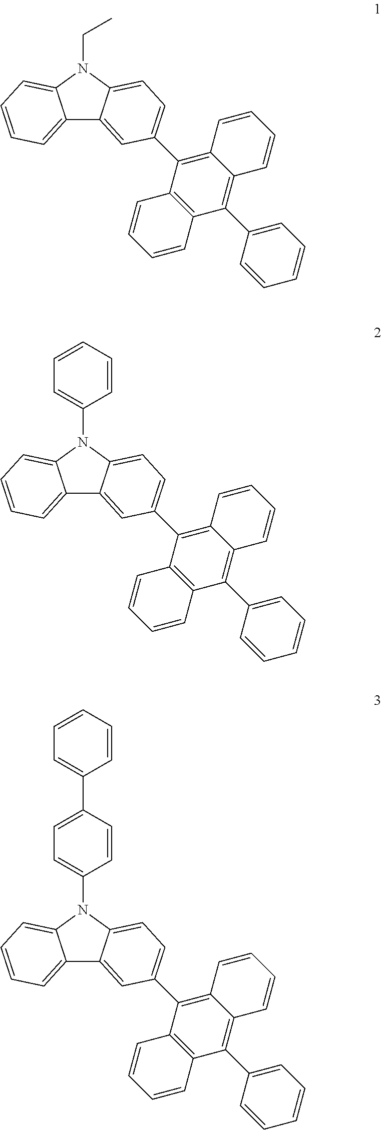 [SMILES: CCn1c2ccccc2c2cc(-c3c4ccccc4c(-c4ccccc4)c4ccccc34)ccc21 ; c1ccc(-c2c3ccccc3c(-c3ccc4c(c3)c3ccccc3n4-c3ccccc3)c3ccccc23)cc1 ; c1ccc(-c2ccc(-n3c4ccccc4c4cc(-c5c6ccccc6c(-c6ccccc6)c6ccccc56)ccc43)cc2)cc1]

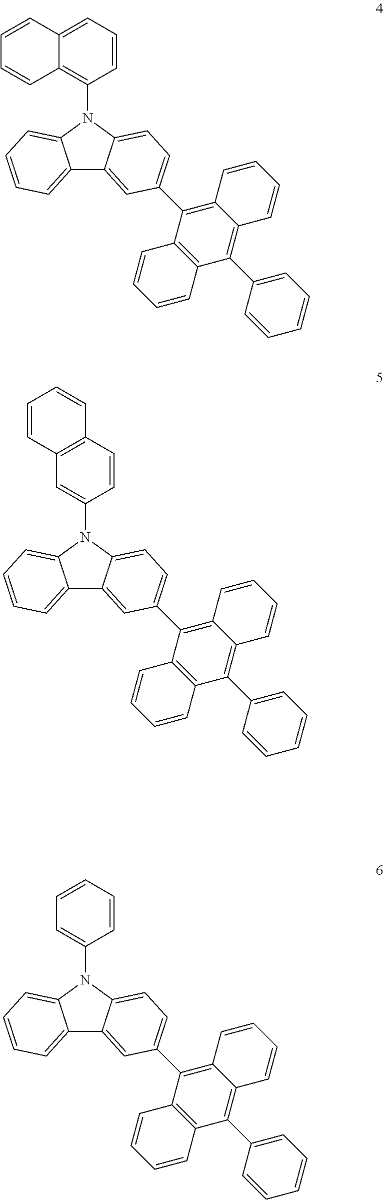 [SMILES: c1ccc(-c2c3ccccc3c(-c3ccc4c(c3)c3ccccc3n4-c3cccc4ccccc34)c3ccccc23)cc1 ; c1ccc(-c2c3ccccc3c(-c3ccc4c(c3)c3ccccc3n4-c3ccc4ccccc4c3)c3ccccc23)cc1 ; c1ccc(-c2c3ccccc3c(-c3ccc4c(c3)c3ccccc3n4-c3ccccc3)c3ccccc23)cc1]

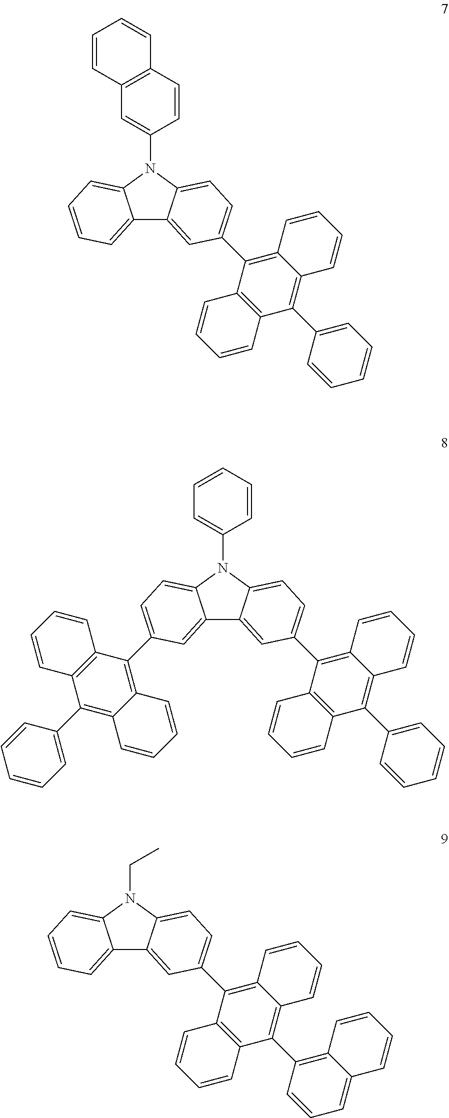 [SMILES: c1ccc(-c2c3ccccc3c(-c3ccc4c(c3)c3ccccc3n4-c3ccc4ccccc4c3)c3ccccc23)cc1 ; c1ccc(-c2c3ccccc3c(-c3ccc4c(c3)c3cc(-c5c6ccccc6c(-c6ccccc6)c6ccccc56)ccc3n4-c3ccccc3)c3ccccc23)cc1 ; CCn1c2ccccc2c2cc(-c3c4ccccc4c(-c4cccc5ccccc45)c4ccccc34)ccc21]

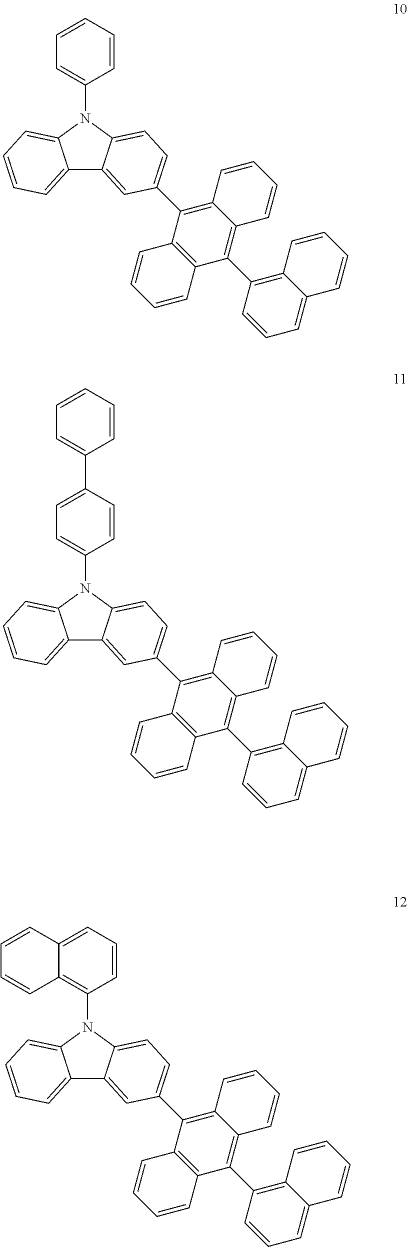 [SMILES: c1ccc(-n2c3ccccc3c3cc(-c4c5ccccc5c(-c5cccc6ccccc56)c5ccccc45)ccc32)cc1 ; c1ccc(-c2ccc(-n3c4ccccc4c4cc(-c5c6ccccc6c(-c6cccc7ccccc67)c6ccccc56)ccc43)cc2)cc1 ; c1ccc2c(-c3c4ccccc4c(-c4ccc5c(c4)c4ccccc4n5-c4cccc5ccccc45)c4ccccc34)cccc2c1]

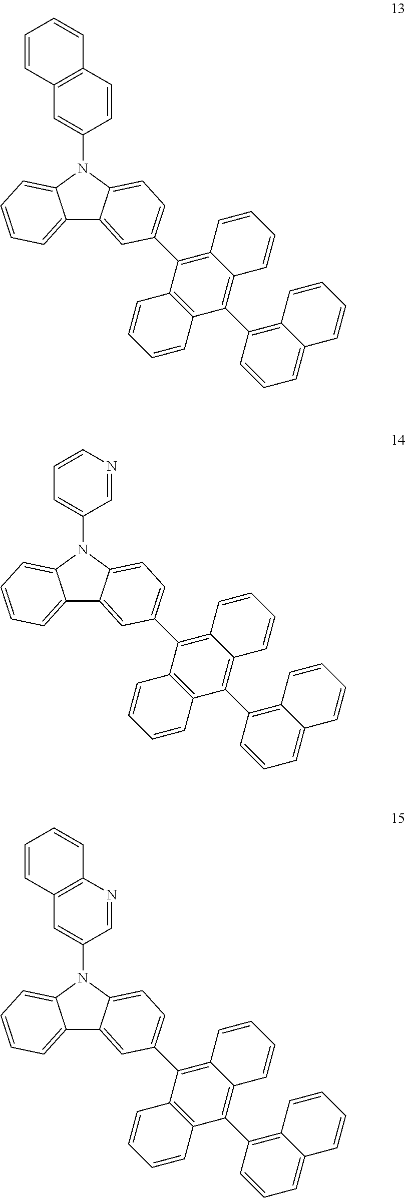 [SMILES: c1ccc2cc(-n3c4ccccc4c4cc(-c5c6ccccc6c(-c6cccc7ccccc67)c6ccccc56)ccc43)ccc2c1 ; c1cncc(-n2c3ccccc3c3cc(-c4c5ccccc5c(-c5cccc6ccccc56)c5ccccc45)ccc32)c1 ; c1ccc2ncc(-n3c4ccccc4c4cc(-c5c6ccccc6c(-c6cccc7ccccc67)c6ccccc56)ccc43)cc2c1]

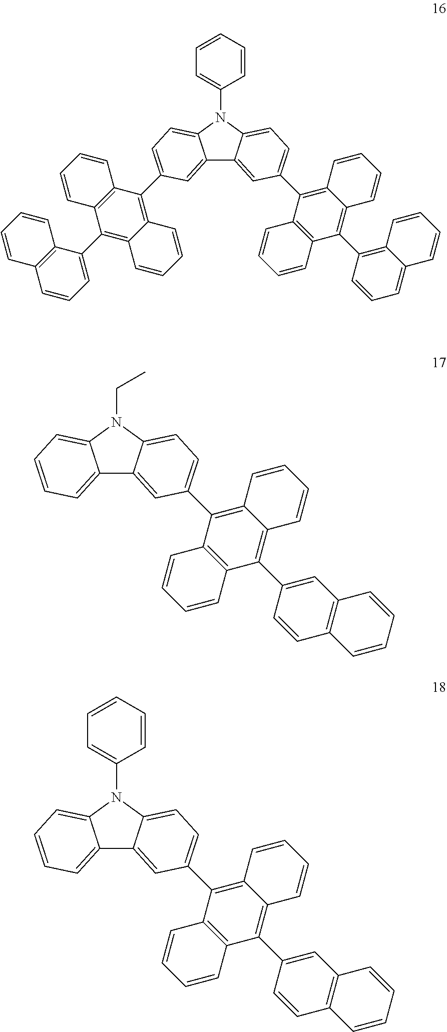 [SMILES: c1ccc(-n2c3ccc(-c4c5ccccc5c(-c5cccc6ccccc56)c5ccccc45)cc3c3cc(-c4c5ccccc5c(-c5cccc6ccccc56)c5ccccc45)ccc32)cc1 ; CCn1c2ccccc2c2cc(-c3c4ccccc4c(-c4ccc5ccccc5c4)c4ccccc34)ccc21 ; c1ccc(-n2c3ccccc3c3cc(-c4c5ccccc5c(-c5ccc6ccccc6c5)c5ccccc45)ccc32)cc1]

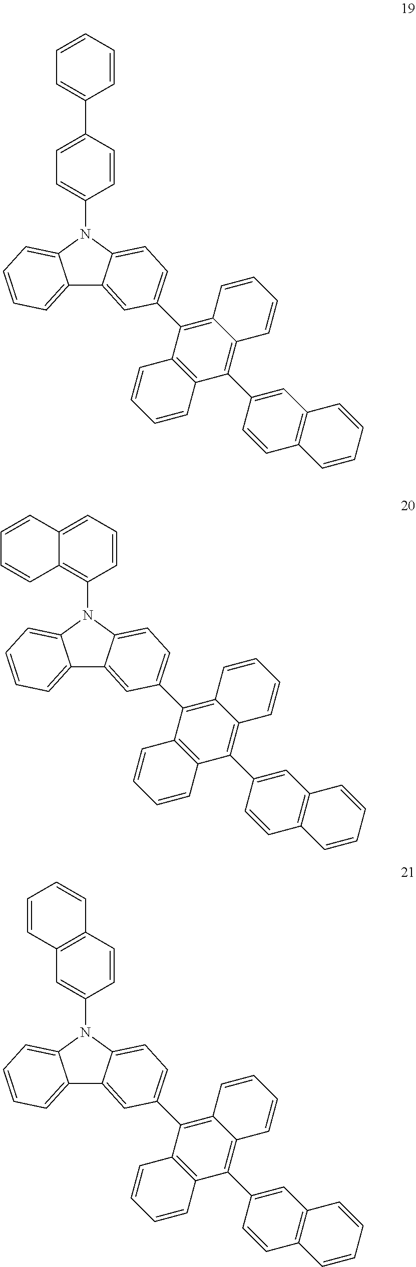 [SMILES: c1ccc(-c2ccc(-n3c4ccccc4c4cc(-c5c6ccccc6c(-c6ccc7ccccc7c6)c6ccccc56)ccc43)cc2)cc1 ; c1ccc2cc(-c3c4ccccc4c(-c4ccc5c(c4)c4ccccc4n5-c4cccc5ccccc45)c4ccccc34)ccc2c1 ; c1ccc2cc(-c3c4ccccc4c(-c4ccc5c(c4)c4ccccc4n5-c4ccc5ccccc5c4)c4ccccc34)ccc2c1]

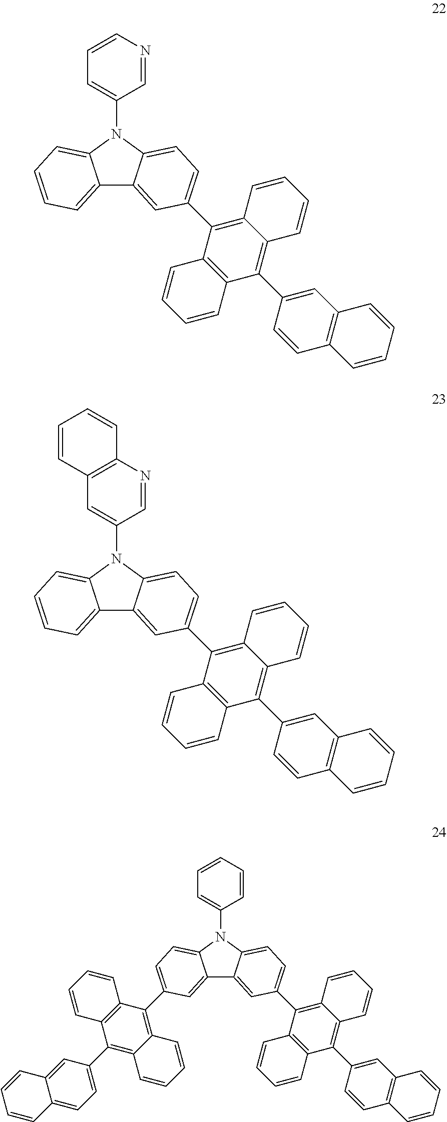 [SMILES: c1cncc(-n2c3ccccc3c3cc(-c4c5ccccc5c(-c5ccc6ccccc6c5)c5ccccc45)ccc32)c1 ; c1ccc2cc(-c3c4ccccc4c(-c4ccc5c(c4)c4ccccc4n5-c4cnc5ccccc5c4)c4ccccc34)ccc2c1 ; c1ccc(-n2c3ccc(-c4c5ccccc5c(-c5ccc6ccccc6c5)c5ccccc45)cc3c3cc(-c4c5ccccc5c(-c5ccc6ccccc6c5)c5ccccc45)ccc32)cc1]

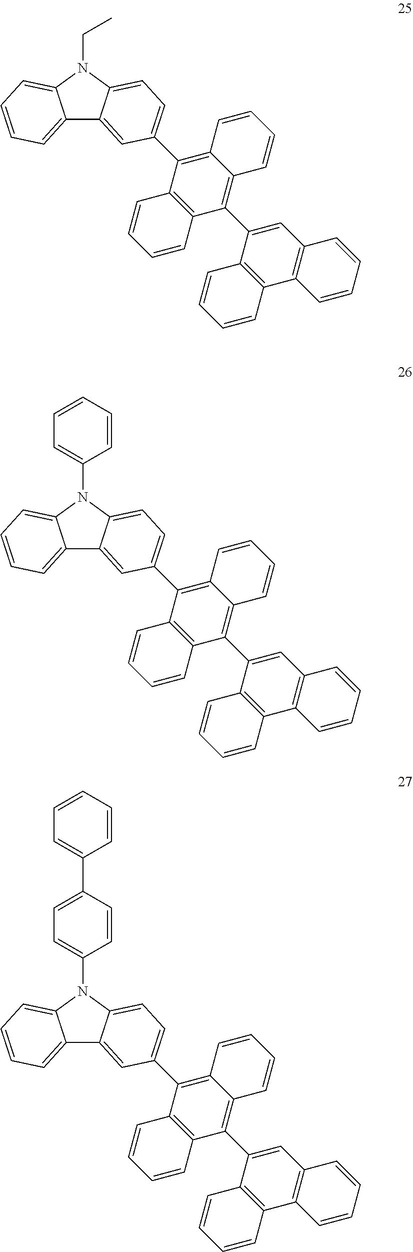 [SMILES: CCn1c2ccccc2c2cc(-c3c4ccccc4c(-c4cc5ccccc5c5ccccc45)c4ccccc34)ccc21 ; c1ccc(-n2c3ccccc3c3cc(-c4c5ccccc5c(-c5cc6ccccc6c6ccccc56)c5ccccc45)ccc32)cc1 ; c1ccc(-c2ccc(-n3c4ccccc4c4cc(-c5c6ccccc6c(-c6cc7ccccc7c7ccccc67)c6ccccc56)ccc43)cc2)cc1]

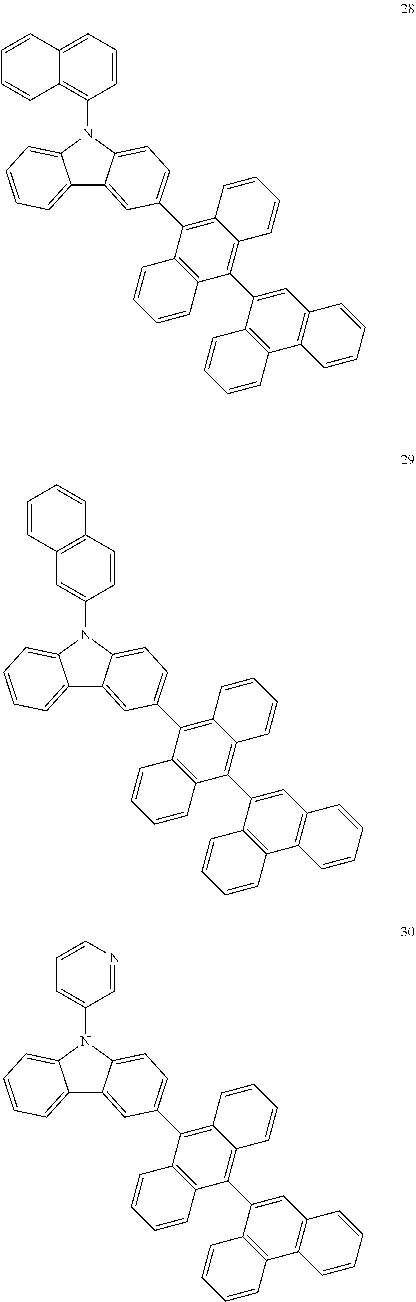 [SMILES: c1ccc2c(-n3c4ccccc4c4cc(-c5c6ccccc6c(-c6cc7ccccc7c7ccccc67)c6ccccc56)ccc43)cccc2c1 ; c1ccc2cc(-n3c4ccccc4c4cc(-c5c6ccccc6c(-c6cc7ccccc7c7ccccc67)c6ccccc56)ccc43)ccc2c1 ; c1cncc(-n2c3ccccc3c3cc(-c4c5ccccc5c(-c5cc6ccccc6c6ccccc56)c5ccccc45)ccc32)c1]

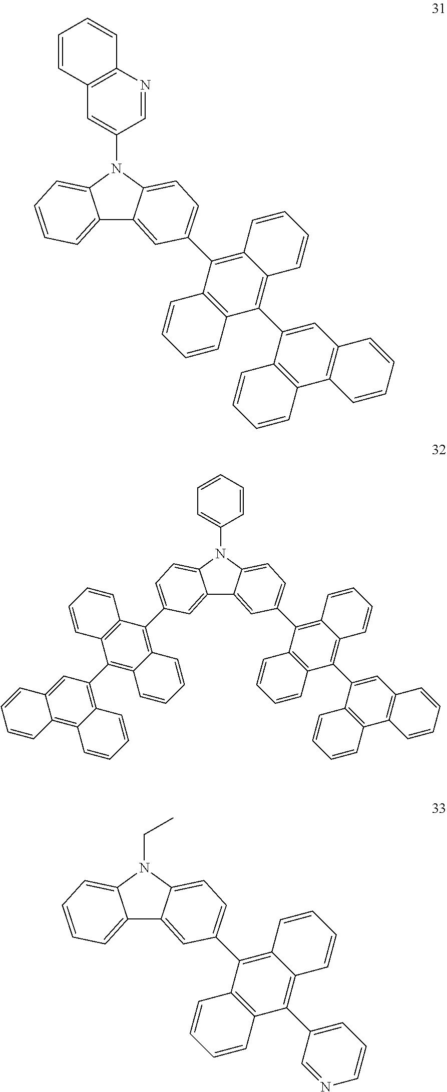 [SMILES: c1ccc2ncc(-n3c4ccccc4c4cc(-c5c6ccccc6c(-c6cc7ccccc7c7ccccc67)c6ccccc56)ccc43)cc2c1 ; c1ccc(-n2c3ccc(-c4c5ccccc5c(-c5cc6ccccc6c6ccccc56)c5ccccc45)cc3c3cc(-c4c5ccccc5c(-c5cc6ccccc6c6ccccc56)c5ccccc45)ccc32)cc1 ; CCn1c2ccccc2c2cc(-c3c4ccccc4c(-c4cccnc4)c4ccccc34)ccc21]

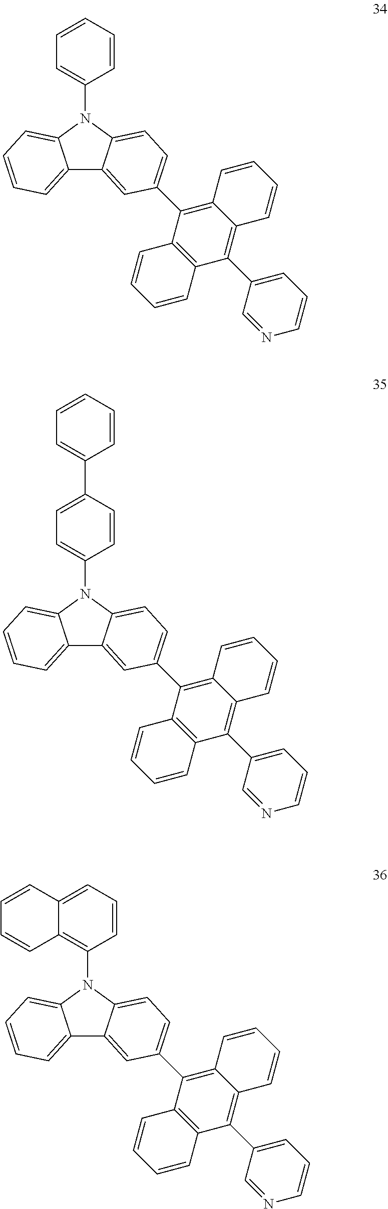 [SMILES: c1ccc(-n2c3ccccc3c3cc(-c4c5ccccc5c(-c5cccnc5)c5ccccc45)ccc32)cc1 ; c1ccc(-c2ccc(-n3c4ccccc4c4cc(-c5c6ccccc6c(-c6cccnc6)c6ccccc56)ccc43)cc2)cc1 ; c1cncc(-c2c3ccccc3c(-c3ccc4c(c3)c3ccccc3n4-c3cccc4ccccc34)c3ccccc23)c1]

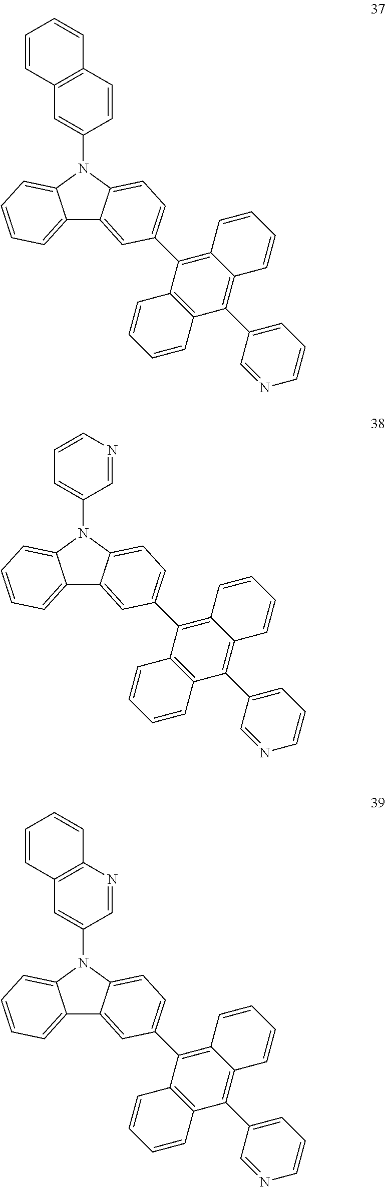 [SMILES: c1cncc(-c2c3ccccc3c(-c3ccc4c(c3)c3ccccc3n4-c3ccc4ccccc4c3)c3ccccc23)c1 ; c1cncc(-c2c3ccccc3c(-c3ccc4c(c3)c3ccccc3n4-c3cccnc3)c3ccccc23)c1 ; c1cncc(-c2c3ccccc3c(-c3ccc4c(c3)c3ccccc3n4-c3cnc4ccccc4c3)c3ccccc23)c1]

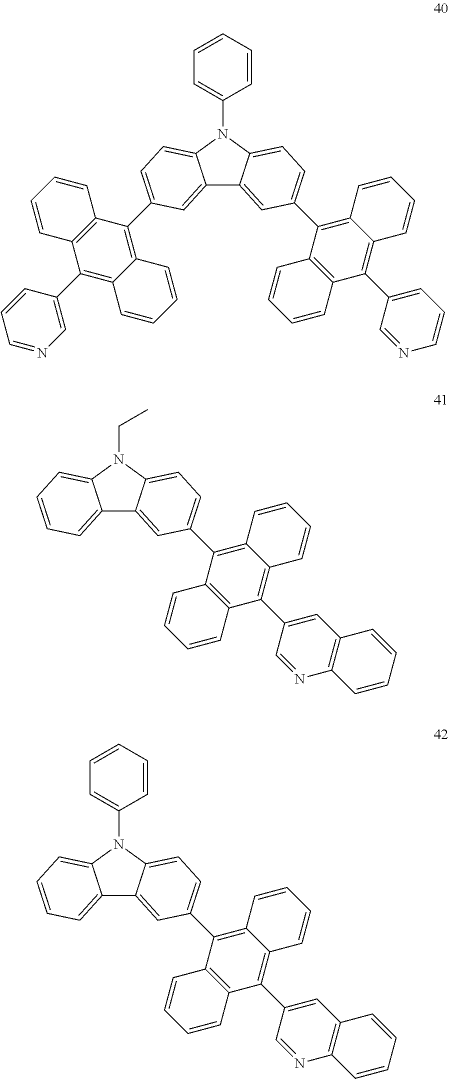 [SMILES: c1ccc(-n2c3ccc(-c4c5ccccc5c(-c5cccnc5)c5ccccc45)cc3c3cc(-c4c5ccccc5c(-c5cccnc5)c5ccccc45)ccc32)cc1 ; CCn1c2ccccc2c2cc(-c3c4ccccc4c(-c4cnc5ccccc5c4)c4ccccc34)ccc21 ; c1ccc(-n2c3ccccc3c3cc(-c4c5ccccc5c(-c5cnc6ccccc6c5)c5ccccc45)ccc32)cc1]

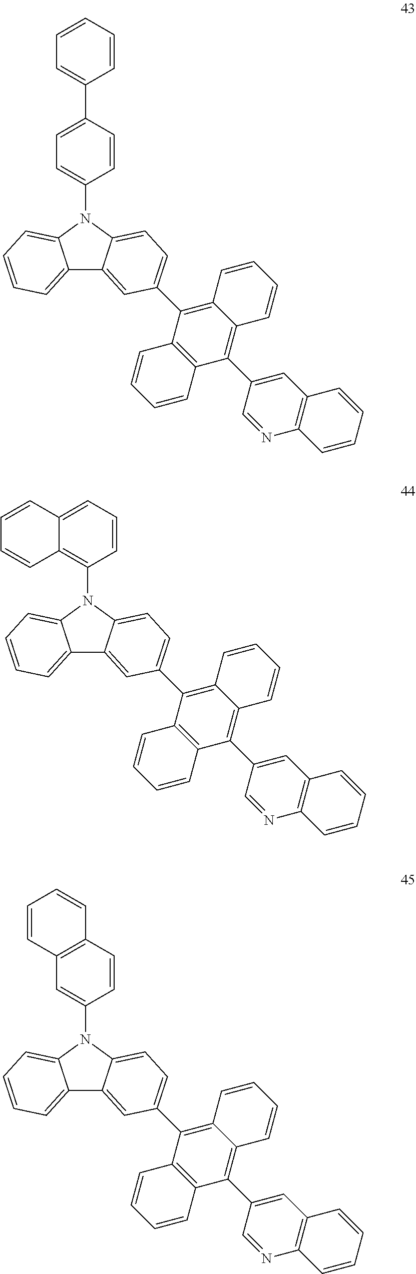 [SMILES: c1ccc(-c2ccc(-n3c4ccccc4c4cc(-c5c6ccccc6c(-c6cnc7ccccc7c6)c6ccccc56)ccc43)cc2)cc1 ; c1ccc2ncc(-c3c4ccccc4c(-c4ccc5c(c4)c4ccccc4n5-c4cccc5ccccc45)c4ccccc34)cc2c1 ; c1ccc2cc(-n3c4ccccc4c4cc(-c5c6ccccc6c(-c6cnc7ccccc7c6)c6ccccc56)ccc43)ccc2c1]

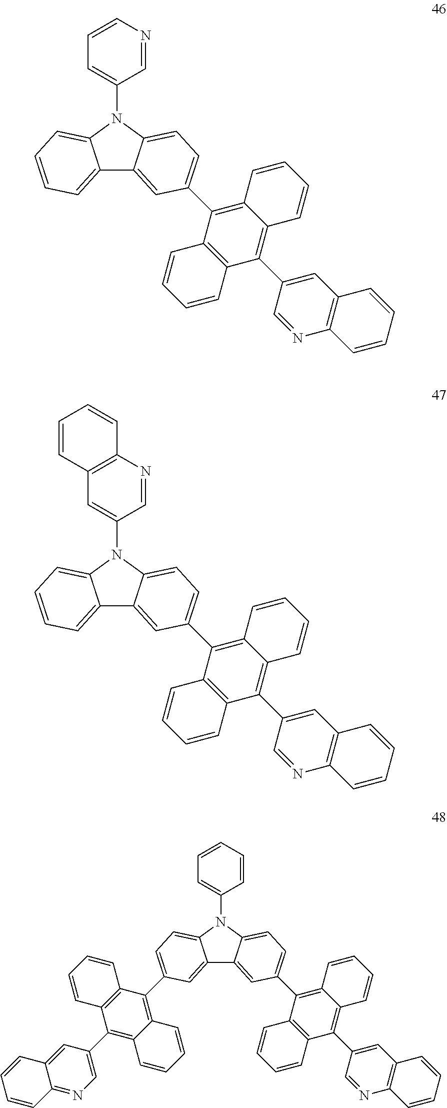 [SMILES: c1cncc(-n2c3ccccc3c3cc(-c4c5ccccc5c(-c5cnc6ccccc6c5)c5ccccc45)ccc32)c1 ; c1ccc2ncc(-c3c4ccccc4c(-c4ccc5c(c4)c4ccccc4n5-c4cnc5ccccc5c4)c4ccccc34)cc2c1 ; c1ccc(-n2c3ccc(-c4c5ccccc5c(-c5cnc6ccccc6c5)c5ccccc45)cc3c3cc(-c4c5ccccc5c(-c5cnc6ccccc6c5)c5ccccc45)ccc32)cc1]

Non-limiting examples of the compound represented by Formula 2 are Compounds 49 to 140 represented by the following formulae.

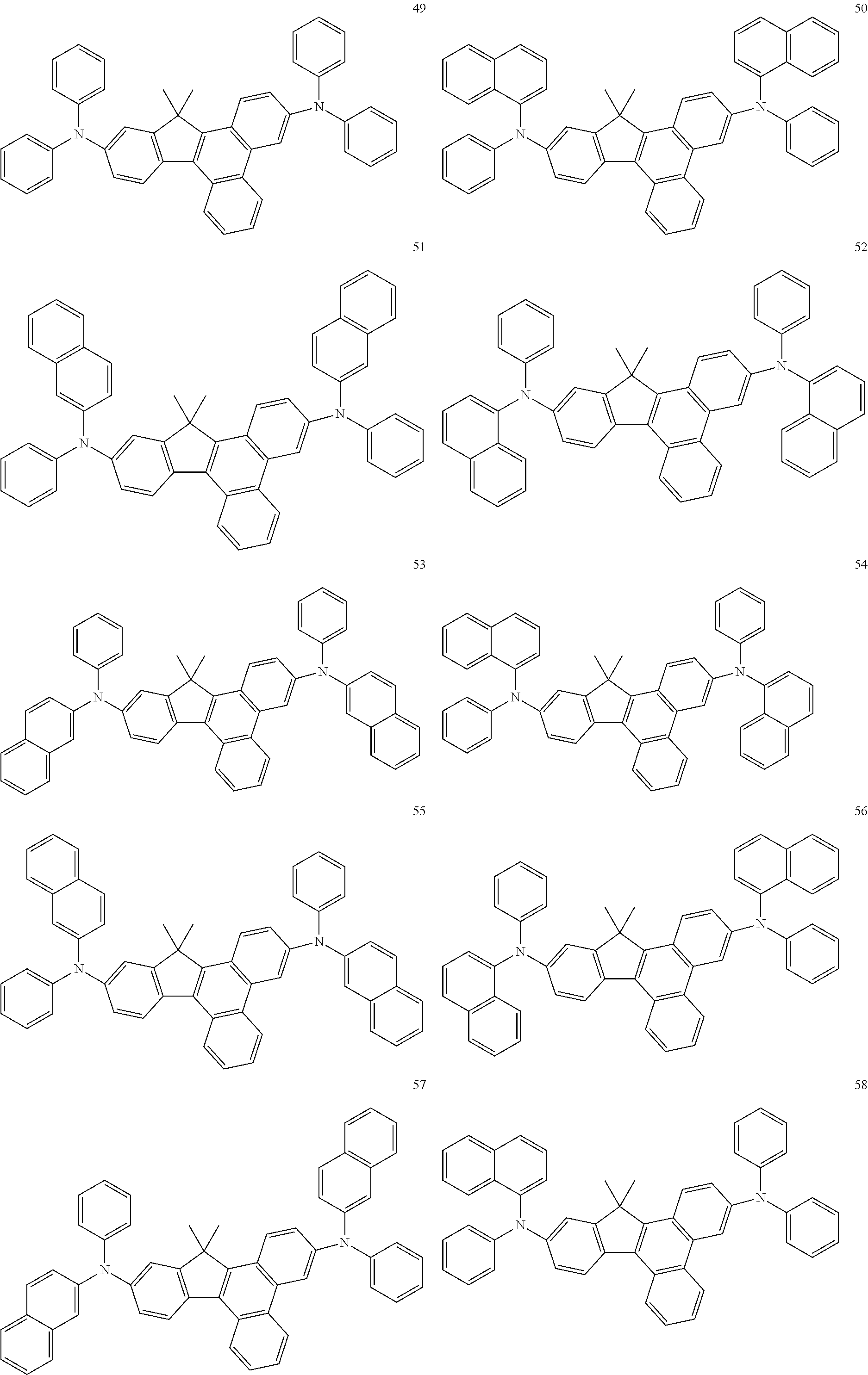

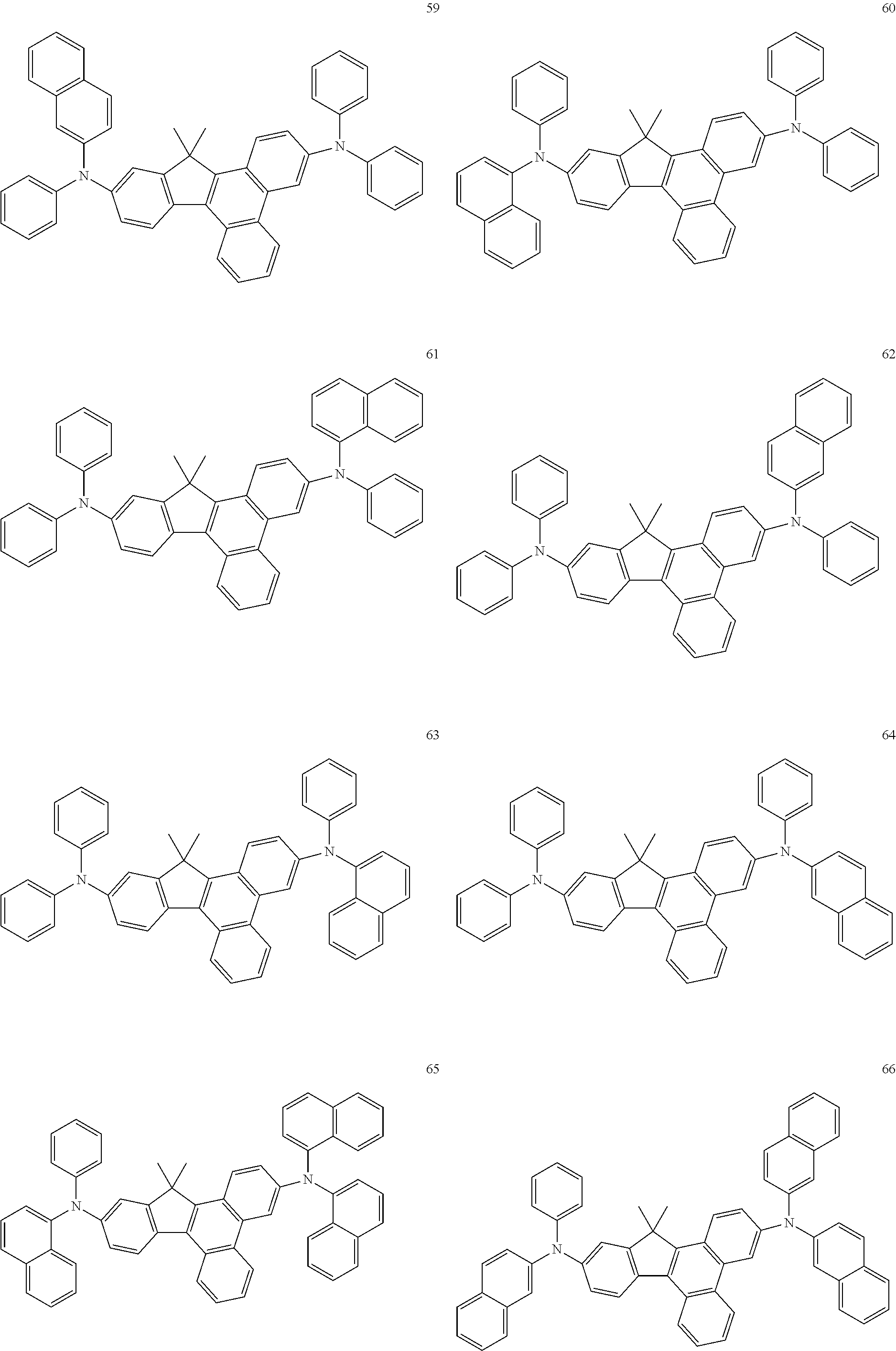

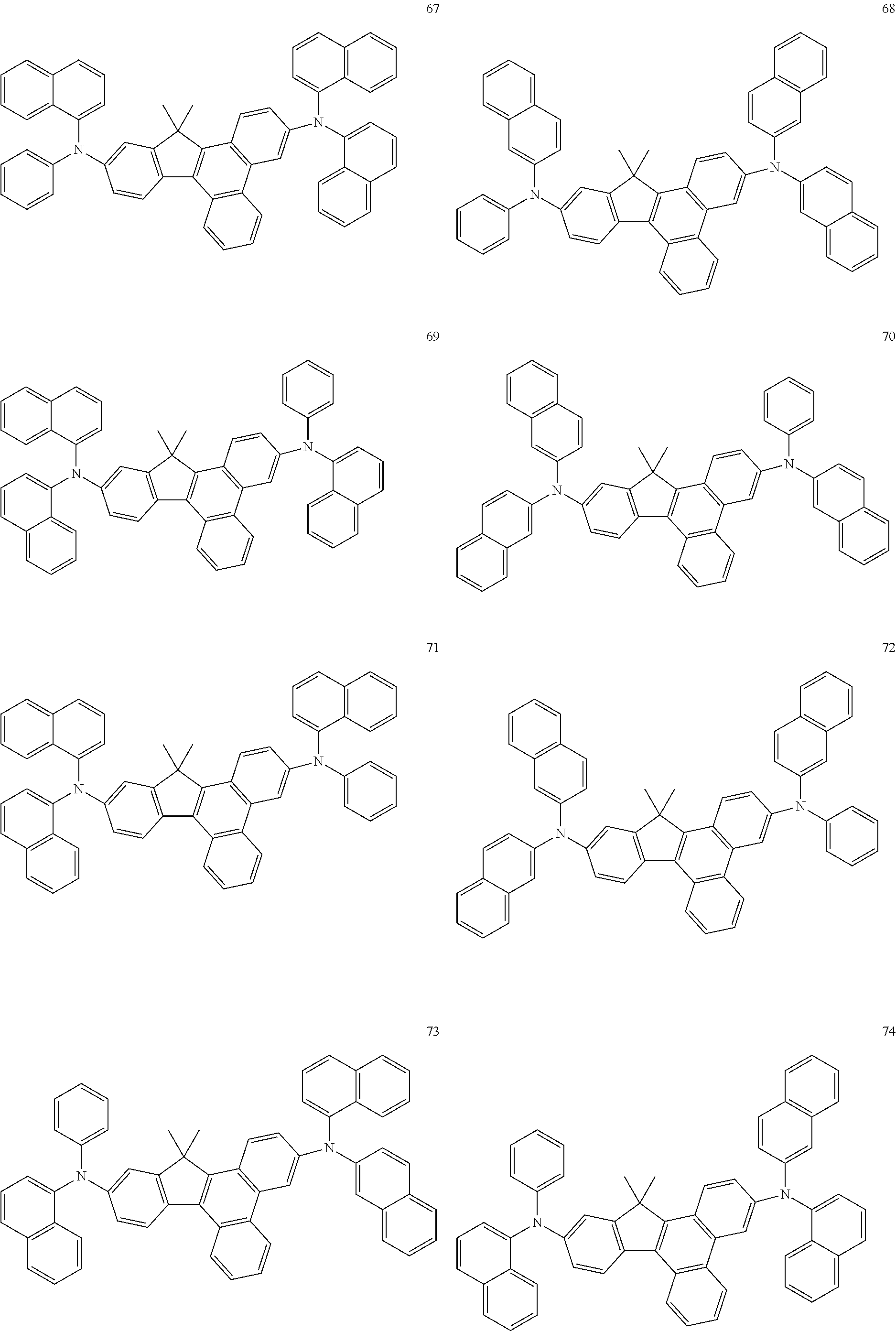

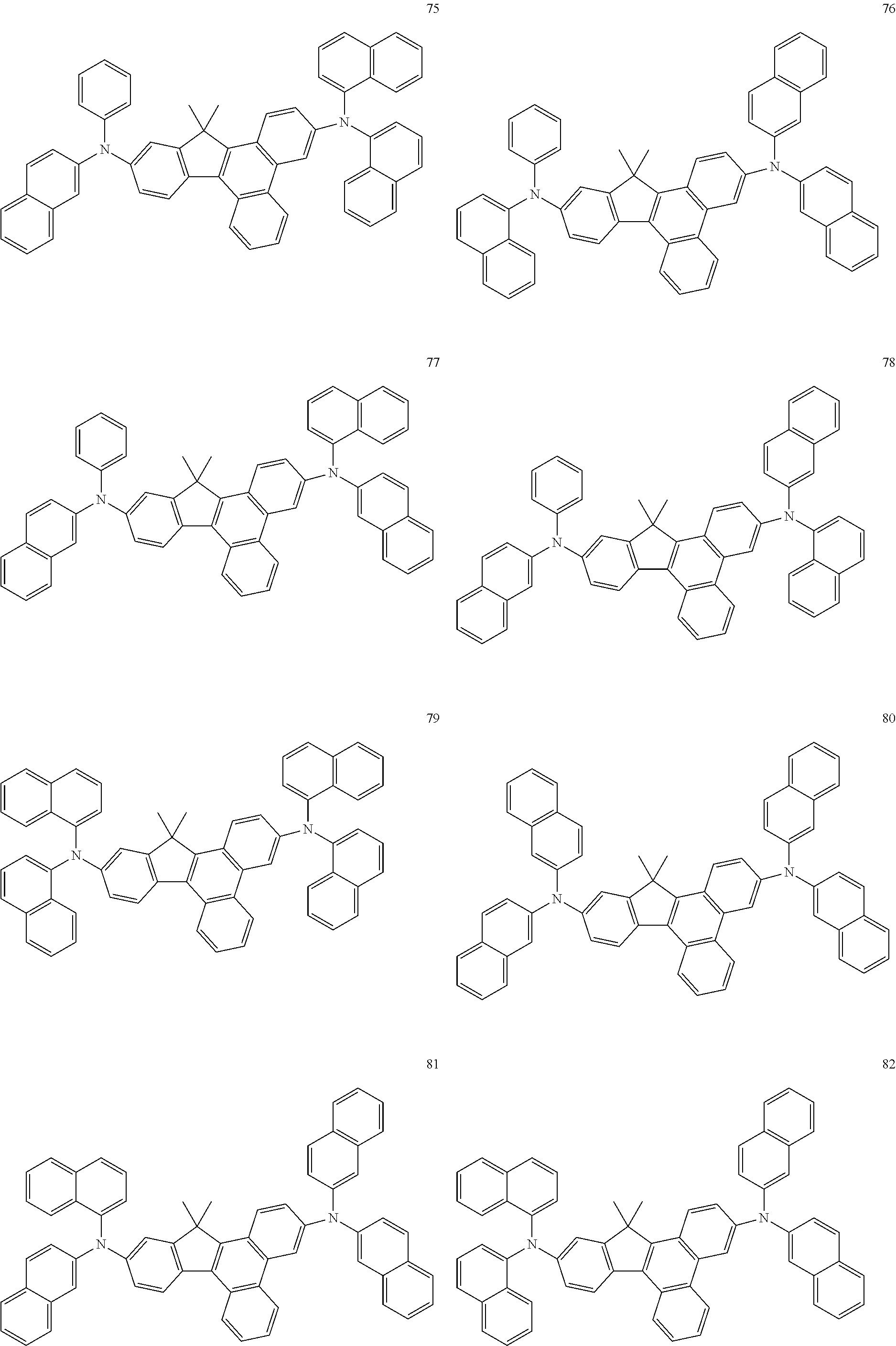

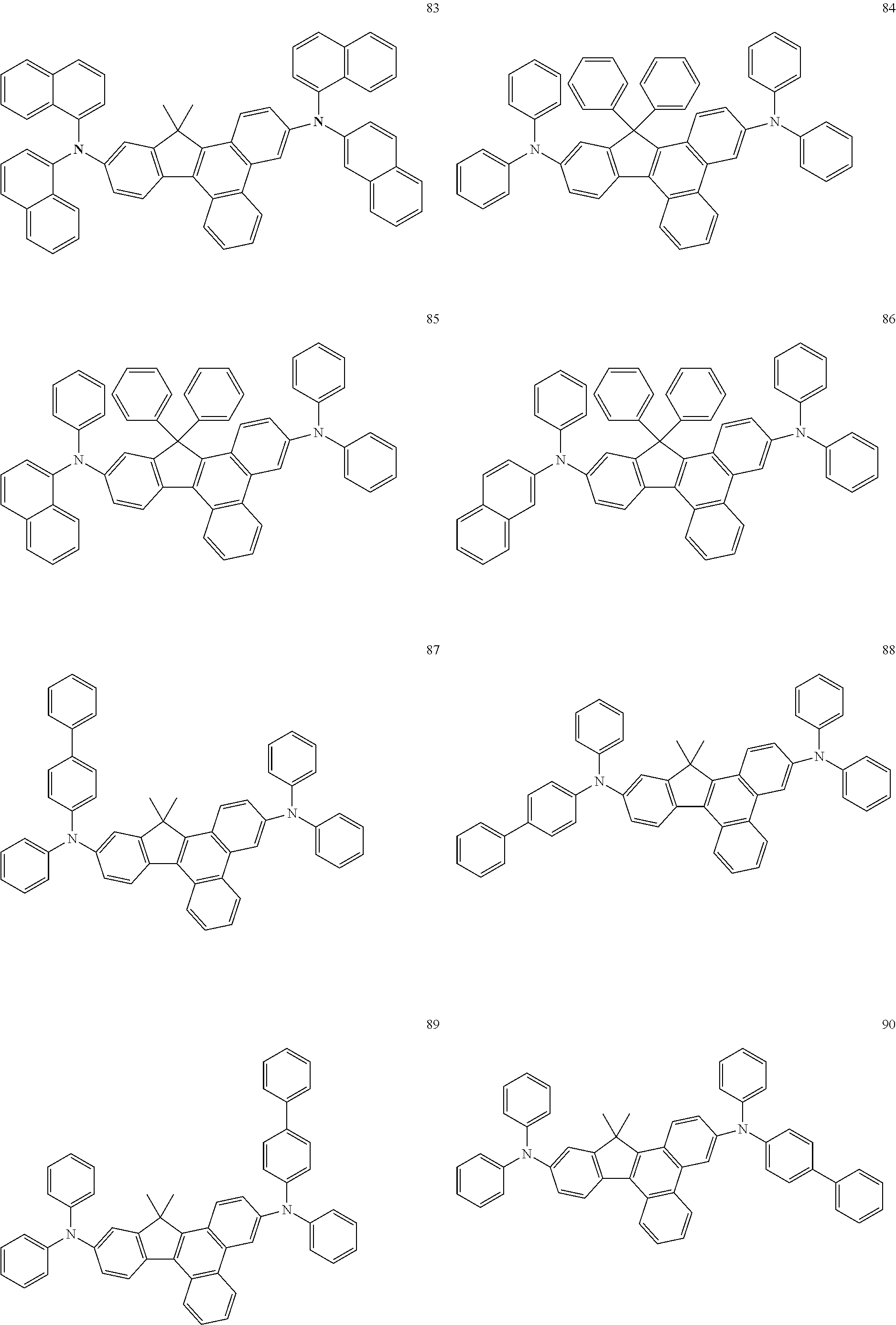

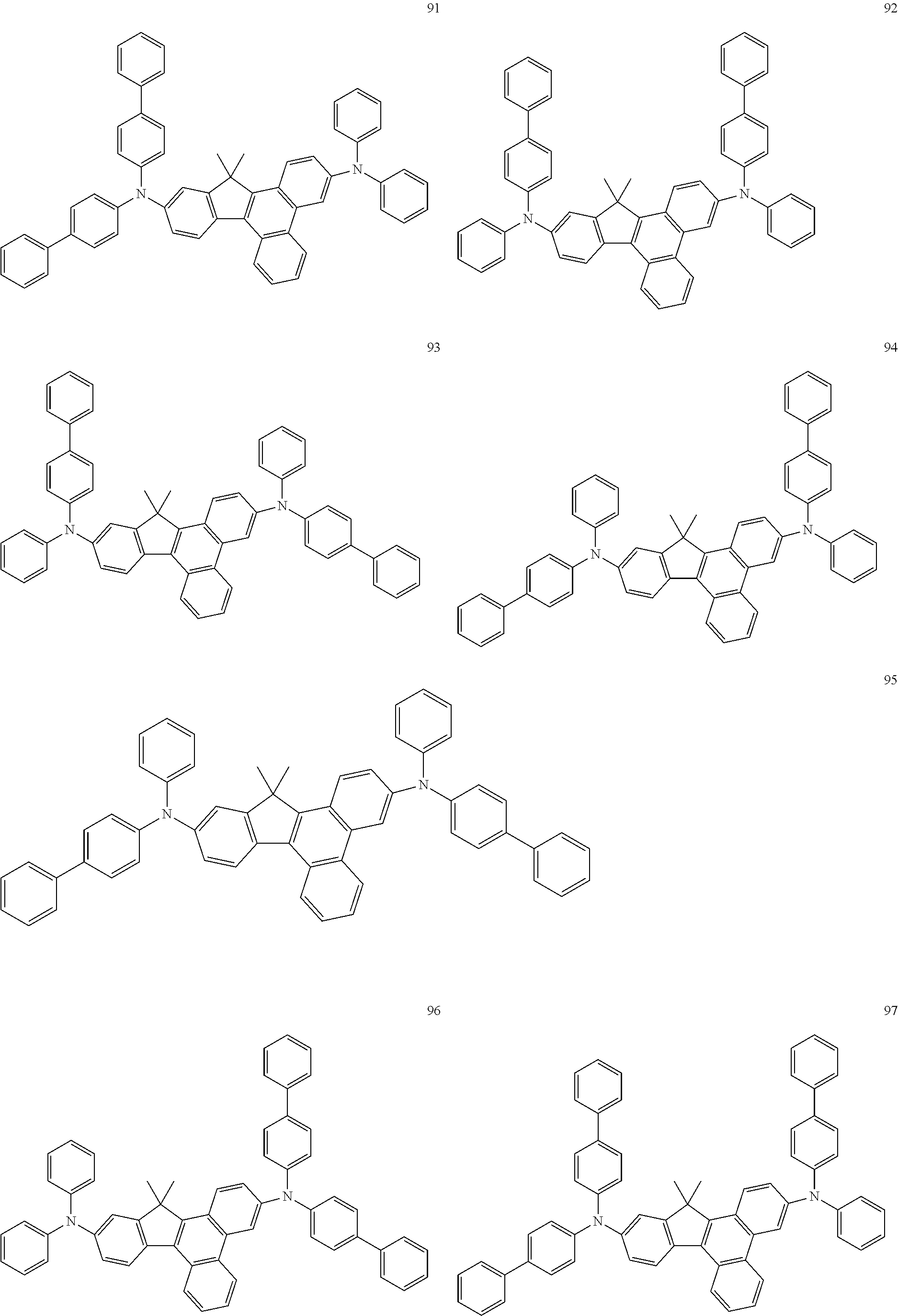

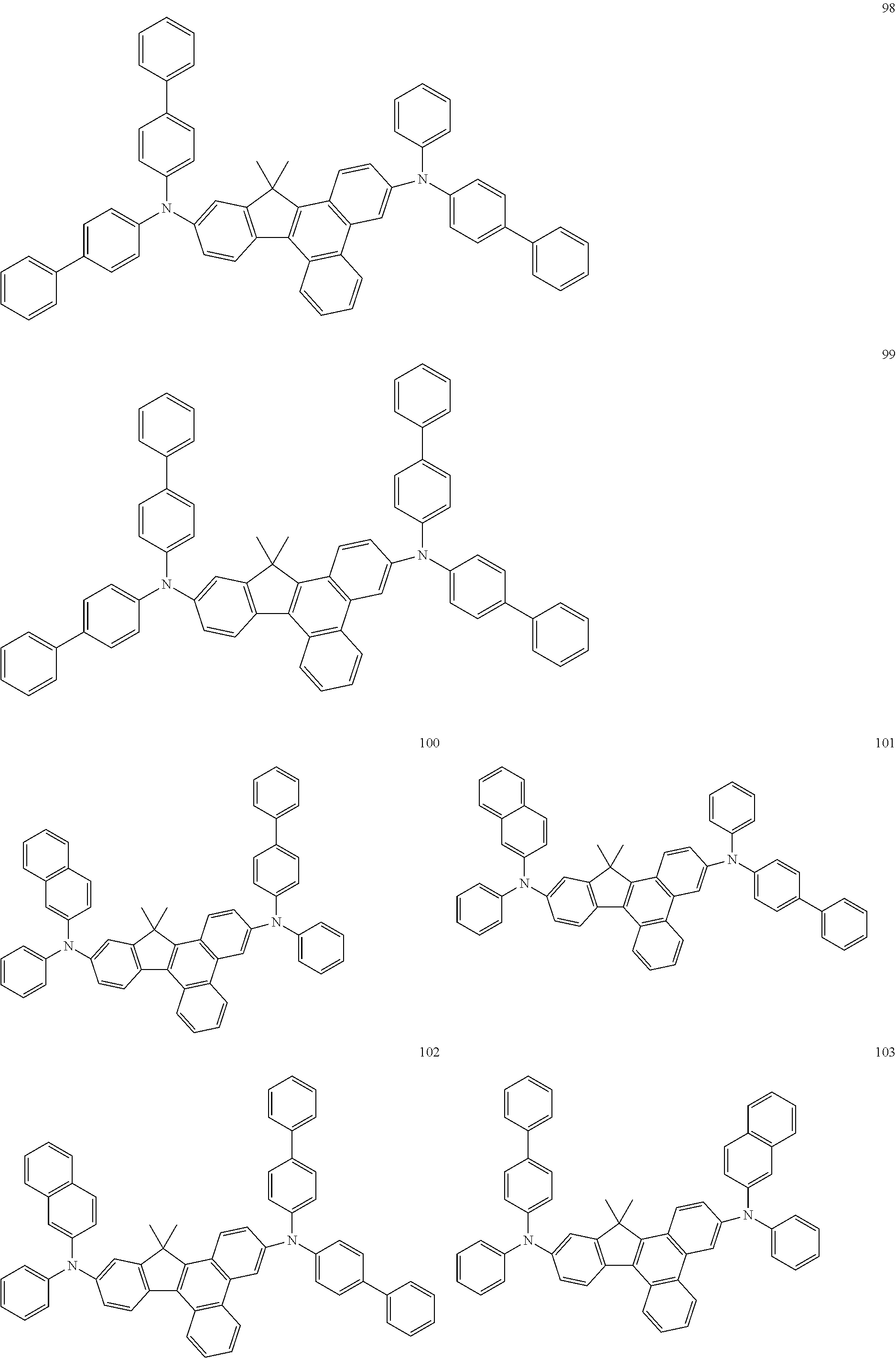

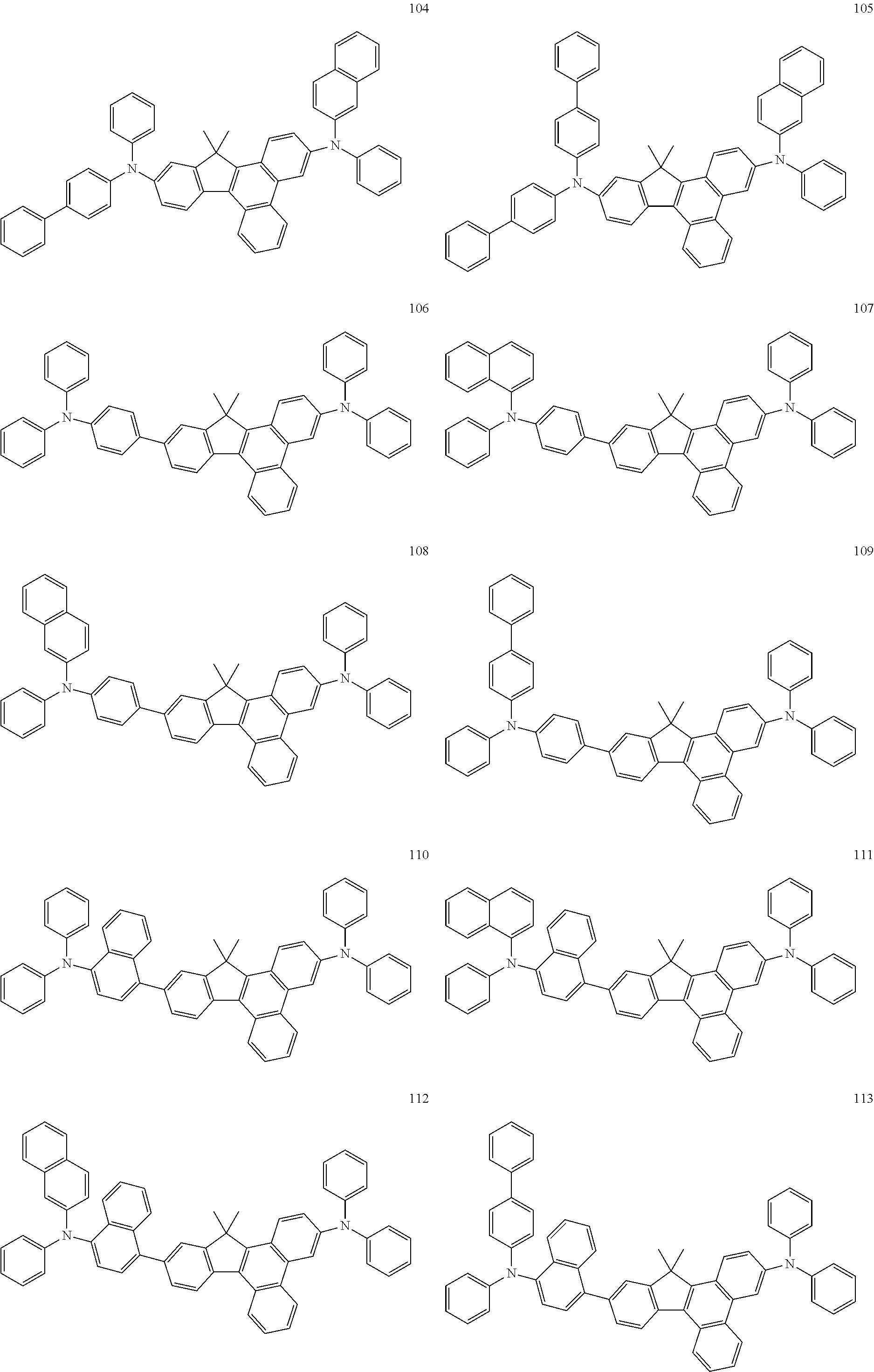

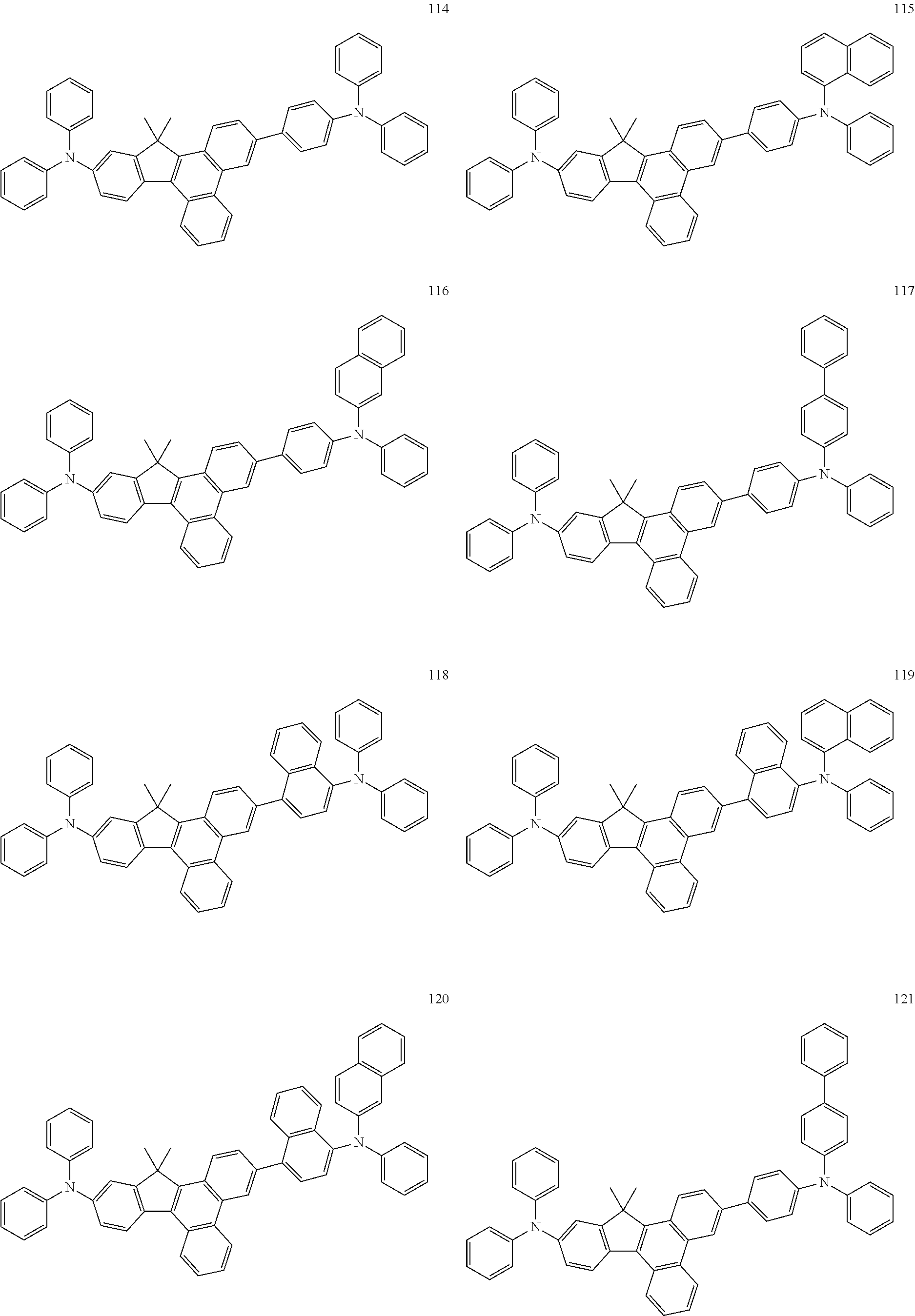

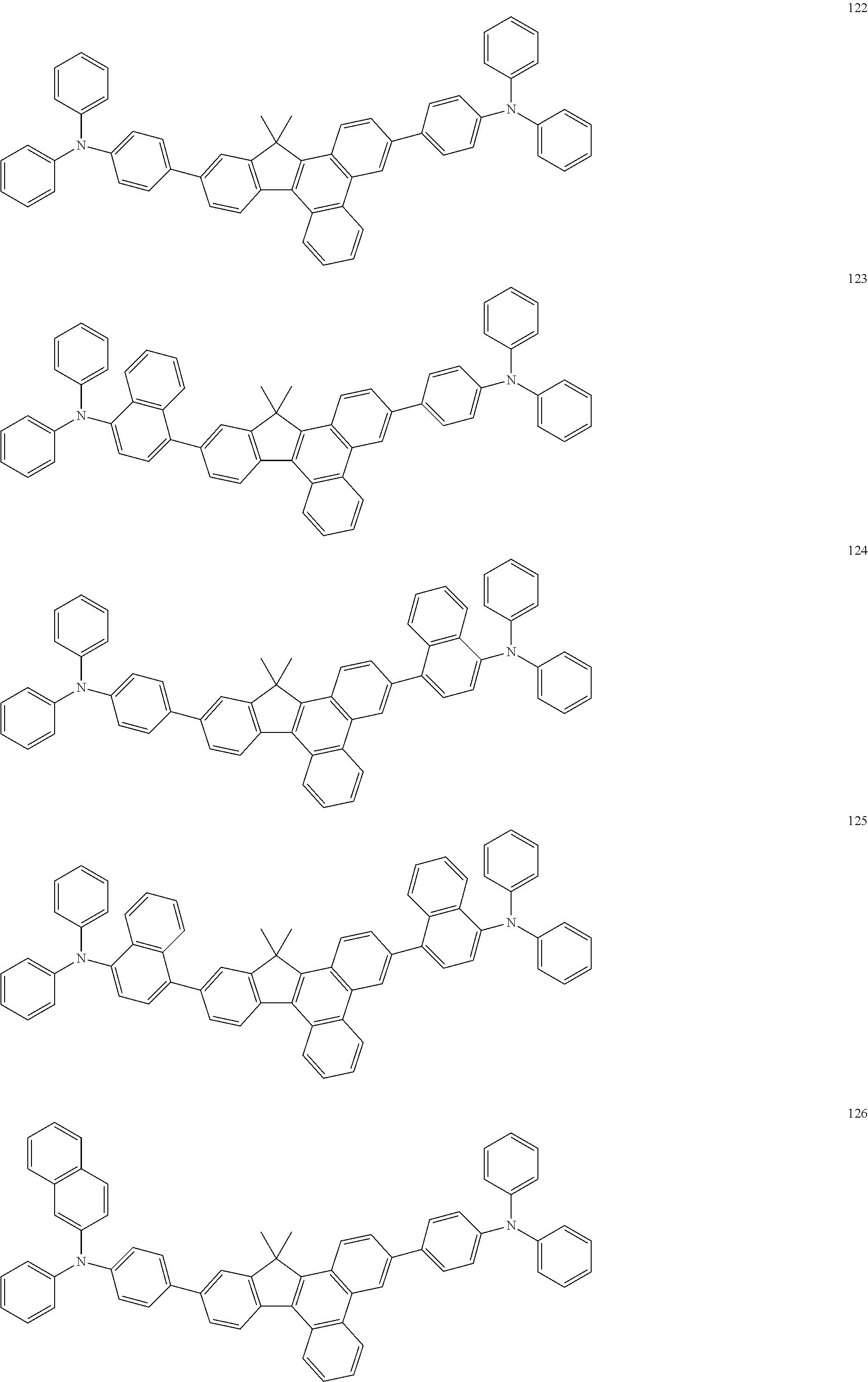

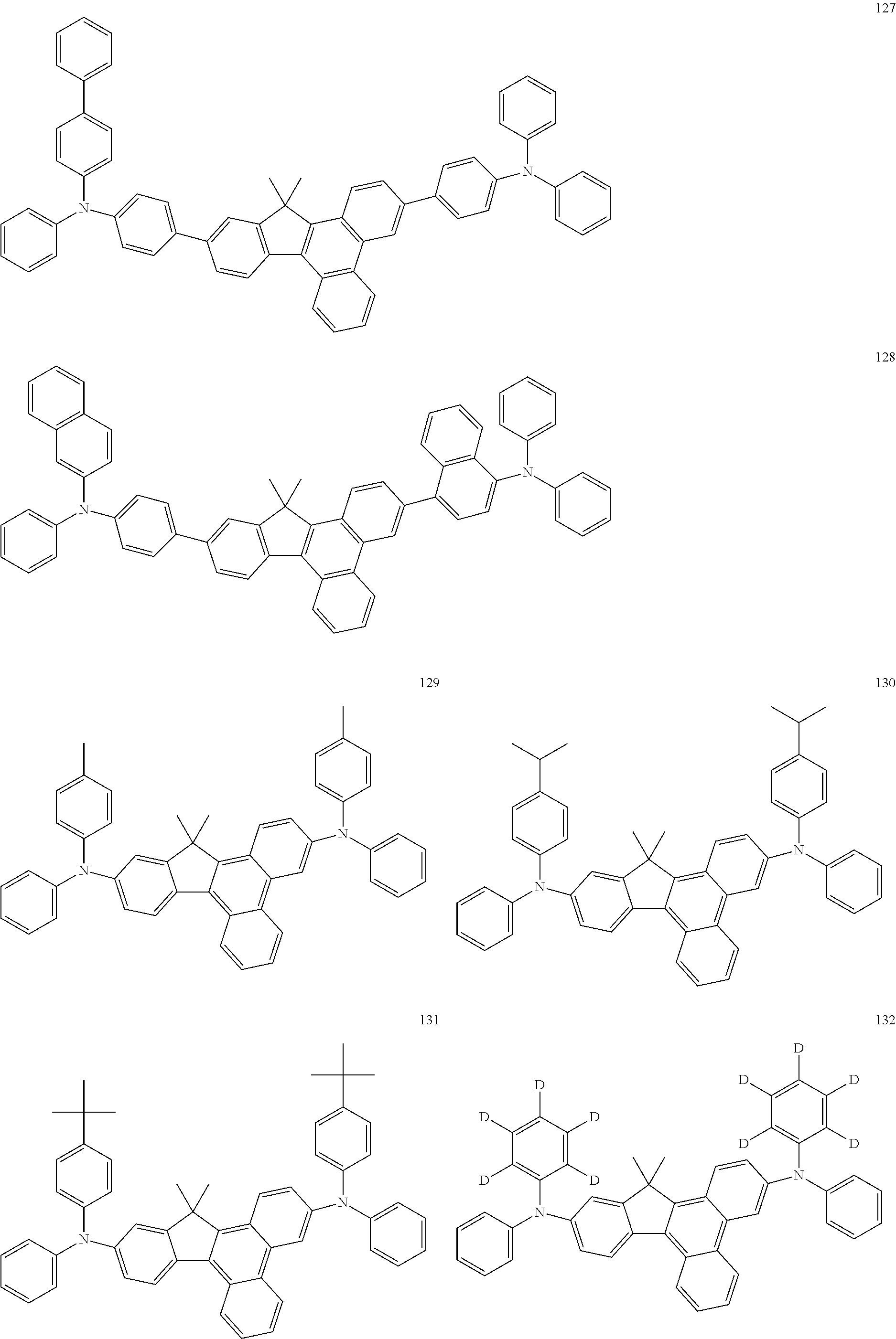

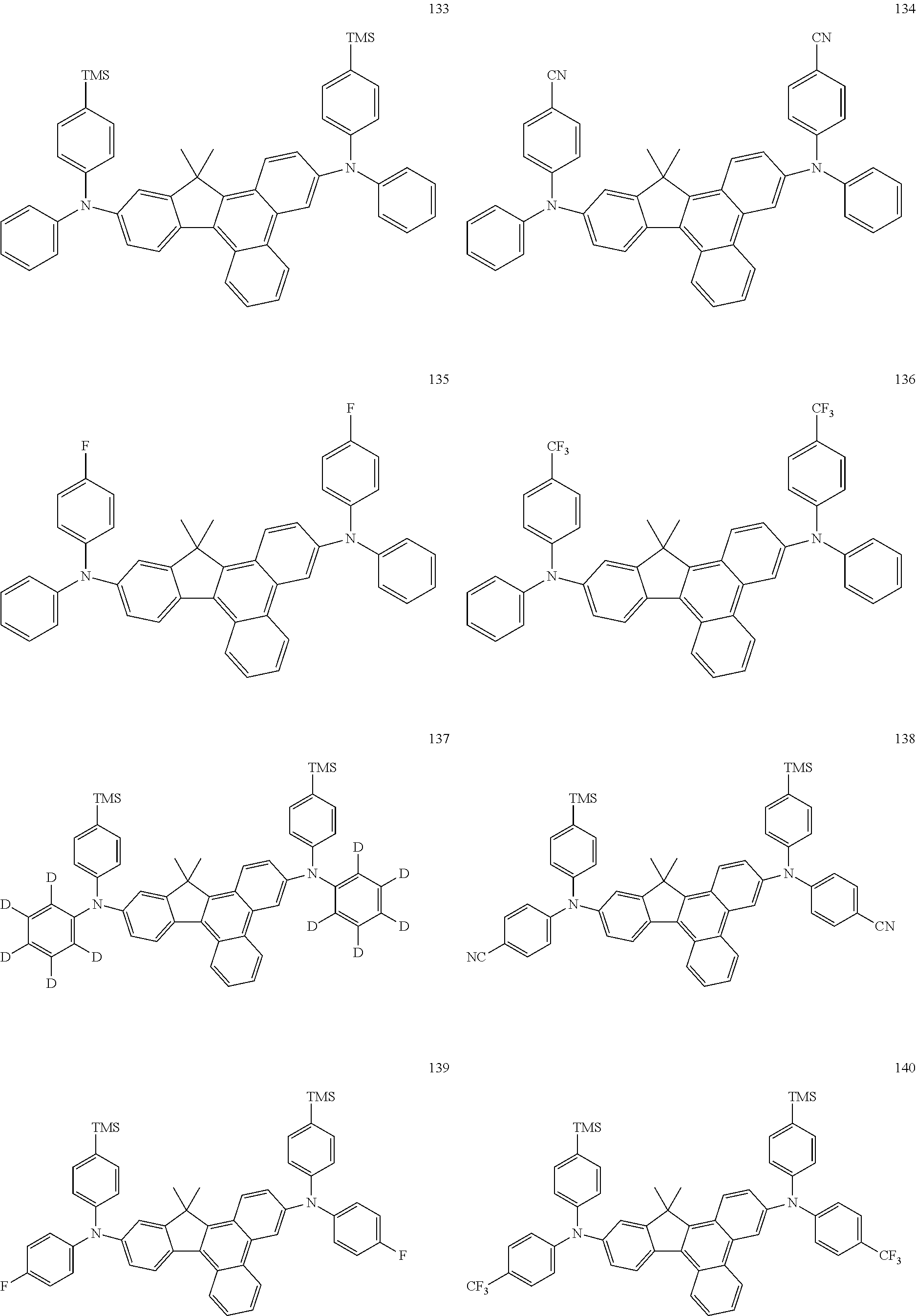

In some embodiments, the organic layer of the organic light-emitting device may include at least one layer selected from among a hole injection layer, a hole transport layer, a functional layer having both hole injection and hole transport capabilities (hereinafter, “H-functional layer”), a buffer layer, an electron blocking layer, an emission layer, a hole blocking layer, an electron transport layer, an electron injection layer, and a functional layer having both electron injection and electron transport capabilities (hereinafter, “E-functional layer”).

For example, the organic layer may be an emission layer. In some embodiments, the organic layer may be a blue emission layer.

In some embodiments, the organic light-emitting device may include an electron injection layer, an electron transport layer, an emission layer, a hole injection layer, a hole transport layer, or a functional layer having both hole injection and transport capabilities. The emission layer may include the compounds of Formulae 1 and 2 above, and an anthracene-based compound, an arylamine-based compound or a styryl-based compound.

In some other embodiments, the organic light-emitting device may include an electron injection layer, an electron transport layer, an emission layer, a hole injection layer, a hole transport layer, or a functional layer having both hole injection and transport capabilities; at least one of a red emission layer, a green emission layer, a blue emission layer, and a white emission layer of the emission layer may include a phosphorescent compound; and at least one of the hole injection layer, the hole transport layer, and the functional layer having both hole injection and hole transport capabilities may include a charge-generating material. In some embodiments, the charge-generating material may be a p-type dopant, and the p-type dopant may be a quinine derivative, a metal oxide or a cyano group-containing compound.

In some embodiments, the organic layer may include an electron transport layer, and the electron transport layer may include an electron-transporting organic compound and a metal complex. The metal complex may be a lithium (Li) complex.

The term “organic layer” as used herein refers to a single layer and/or a plurality of layers disposed between the first and second electrodes of the organic light-emitting device.

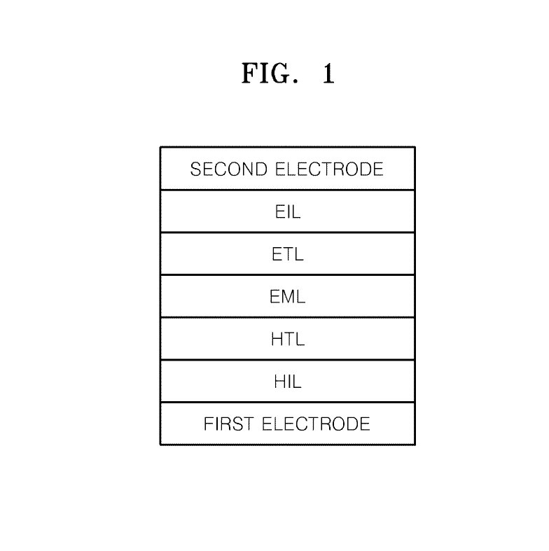

FIG. 1 is a schematic sectional view of an organic light-emitting device according to an aspect of the present embodiments. Hereinafter, a structure of an organic light-emitting device according to an aspect of the present embodiments and a method of manufacturing the same will now be described with reference to FIG. 1.

A substrate (not shown) may be any substrate that is used in existing organic light emitting devices. In some embodiments the substrate 11 may be a glass substrate or a transparent plastic substrate with strong mechanical strength, thermal stability, transparency, surface smoothness, ease of handling, and water resistance.

The first electrode may be formed by depositing or sputtering a first electrode-forming material on the substrate. When the first electrode constitutes an anode, a material having a high work function may be used as the first electrode-forming material to facilitate hole injection. The first electrode may be a reflective electrode or a transmission electrode. Suitable first electrode-forming materials include transparent and conductive materials such as ITO, IZO, SnO₂, and ZnO. The first electrode may be formed as a reflective electrode using magnesium (Mg), aluminum (Al), aluminum-lithium (Al—Li), calcium (Ca), magnesium-indium (Mg—In), magnesium-silver (Mg—Ag), or the like.

The first electrode may have a single-layer structure or a multi-layer structure including at least two layers. For example, the first electrode may have a three-layered structure of ITO/Ag/ITO, but is not limited thereto.

An organic layer(s) is formed on the first electrode.

The organic layer may include a hole injection layer (HIL), a hole transport layer (HTL), a buffer layer (not shown), an emission layer (EML), an electron transport layer (ETL), or an electron injection layer (EIL).

The HIL may be formed on the first electrode by vacuum deposition, spin coating, casting, Langmuir-Blodgett (LB) deposition, or the like.

When the HIL is formed using vacuum deposition, vacuum deposition conditions may vary according to the compound that is used to form the HIL, and the desired structure and thermal properties of the HIL to be formed. For example, vacuum deposition may be performed at a temperature of about 100° C. to about 500° C., a pressure of about 10⁻⁸ torr to about 10⁻³ torr, and a deposition rate of about 0.01 to about 100 Å/sec. However, the deposition conditions are not limited thereto.

When the HIL is formed using spin coating, the coating conditions may vary according to the compound that is used to form the HIL, and the desired structure and thermal properties of the HIL to be formed. For example, the coating rate may be in the range of about 2000 rpm to about 5000 rpm, and a temperature at which heat treatment is performed to remove a solvent after coating may be in the range of about 80° C. to about 200° C. However, the coating conditions are not limited thereto.

The HIL may be formed of any material that is commonly used to form a HIL. Non-limiting examples of the material that can be used to form the HIL are N,N′-diphenyl-N,N′-bis-[4-(phenyl-m-tolyl-amino)-phenyl]-biphenyl-4,4′-diamine, (DNTPD), a phthalocyanine compound such as copperphthalocyanine, 4,4′,4″-tris (3-methylphenylphenylamino)triphenylamine (m-MTDATA), N,N′-di(1-naphthyl)-N,N′-diphenylbenzidine (NPB), TDATA, 2-TNATA, polyaniline/dodecylbenzenesulfonic acid (Pani/DBSA), poly(3,4-ethylenedioxythiophene)/poly(4-styrenesulfonate) (PEDOT/PSS), polyaniline/camphor sulfonicacid (Pani/CSA), and polyaniline)/poly(4-styrenesulfonate (PANI/PSS).

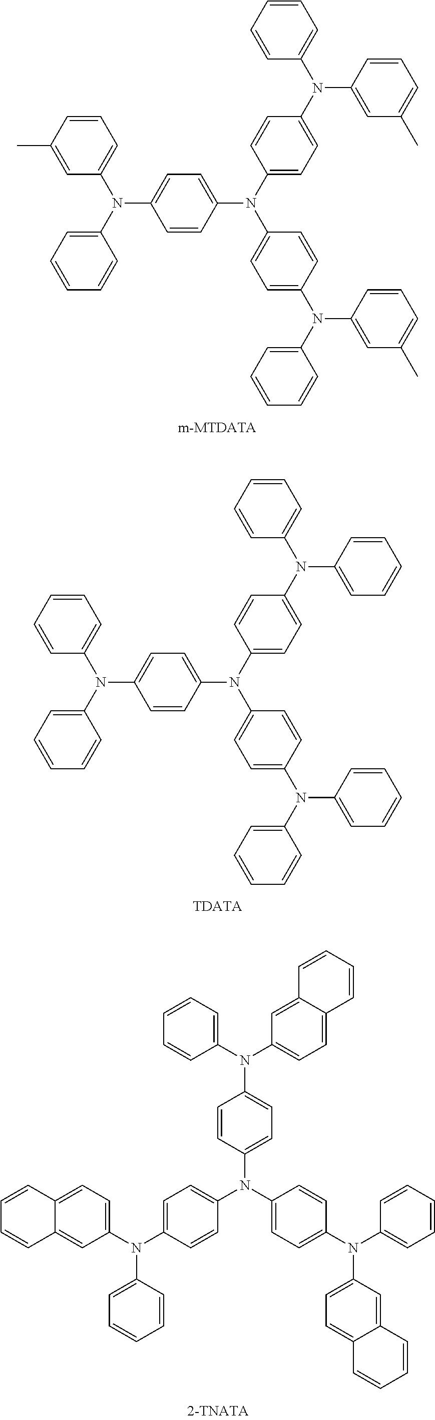

The thickness of the HIL may be about 100 Å to about 10000 Å, and in some embodiments, may be from about 100 Å to about 1000 Å. When the thickness of the HIL is within these ranges, the HIL may have good hole injecting ability without a substantial increase in driving voltage.

Then, a HTL may be formed on the HIL by using vacuum deposition, spin coating, casting, Langmuir-Blodgett (LB) deposition, or the like. When the HTL is formed using vacuum deposition or spin coating, the conditions for deposition and coating may be similar to those for the formation of the HIL, though the conditions for the deposition and coating may vary according to the material that is used to form the HTL.

The HTL may be formed of any known hole-transporting materials. Non-limiting examples of suitable known HTL forming materials are carbazole derivatives, such as N-phenylcarbazole or polyvinylcarbazole, N,N′-bis(3-methylphenyl)-N,N′-diphenyl-[1,1-biphenyl]-4,4′-diamine (TPD), 4,4′,4″-tris(N-carbazolyl)triphenylamine (TCTA), and N,N′-di(1-naphthyl)-N,N′-diphenylbenzidine) (NPB).

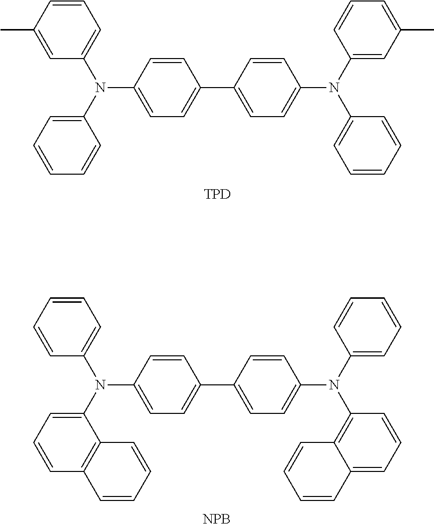

The thickness of the HTL may be from about 50 Å to about 2000 Å, and in some embodiments, may be from about 100 Å to about 1500 Å. When the thickness of the HTL is within these ranges, the HTL may have good hole transporting ability without a substantial increase in driving voltage.

The H-functional layer (having both hole injection and hole transport capabilities) may contain at least one material from each group of the hole injection layer materials and hole transport layer materials. The thickness of the H-functional layer may be from about 500 Å to about 10,000 Å, and in some embodiments, may be from about 100 Å to about 1,000 Å. When the thickness of the H-functional layer is within these ranges, the H-functional layer may have good hole injection and transport capabilities without a substantial increase in driving voltage.

In some embodiments, at least one of the HIL, HTL, and H-functional layer may include at least one of a compound of Formula 300 below and a compound of Formula 350 below:

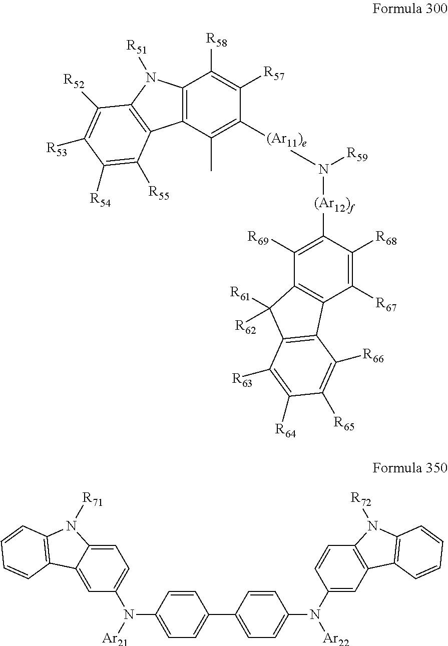

In Formulae 300 and 350, Ar₁₁, Ar₁₂, Ar₂₁ and Ar₂₂ may be each independently a substituted or unsubstituted C₅-C₆₀ arylene group.

In Formula 300, e and f may be each independently an integer from 0 to 5, for example, may be 0, 1, or 2. In a non-limiting embodiment, e may be 1, and f may be 0.

In Formulae 300 and 350, R₅₁ to R₅₈, R₆₁ to R₆₉, and R₇₁ to R₇₂ may be each independently one of a hydrogen atom, a deuterium atom, a halogen atom, a hydroxyl group, a cyano group, a nitro group, an amino group, an amidino group, hydrazine, hydrazone, a carboxyl group or a salt thereof, sulfonic acid or a salt thereof, phosphoric acid or a salt thereof, a substituted or unsubstituted C₁-C₆₀ alkyl group, a substituted or unsubstituted C₂-C₆₀ alkenyl group, a substituted or unsubstituted C₂-C₆₀ alkynyl group, a substituted or unsubstituted C₁-C₆₀ alkoxy group, a substituted or unsubstituted C₃-C₆₀ cycloalkyl group, a substituted or unsubstituted C₅-C₆₀ aryl group, a substituted or unsubstituted C₅-C₆₀ aryloxy group, and a substituted or unsubstituted C₅-C₆₀ arylthio group. In some non-limiting embodiments, R₅₁ to R₅₈, R₆₁ to R₆₉, R₇₁, and R₇₂ may be each independently one of a hydrogen atom; a deuterium atom; a halogen atom; a hydroxyl group; a cyano group; a nitro group; an amino group; an amidino group; hydrazine; hydrazone; a carboxyl group or a salt thereof; a sulfonic acid group or a salt thereof; a phosphoric acid or a salt thereof; a C₁-C₁₀ alkyl group (for example, a methyl group, an ethyl group, a propyl group, a butyl group, a pentyl group, a hexyl group, or the like); a C₁-C₁₀alkoxy group (for example, a methoxy group, an ethoxy group, a propoxy group, a butoxy group, a pentoxy group, or the like); a C₁-C₁₀ alkyl group and a C₁-C₁₀ alkoxy group that are substituted with at least one of a deuterium atom, a halogen atom, a hydroxyl group, a cyano group, a nitro group, an amino group, an amidino group, hydrazine, hydrazone, a carboxyl group or a salt thereof, a sulfonic acid group or a salt thereof, and a phosphoric acid or a salt thereof; a phenyl group; a naphthyl group; an anthryl group; a fluorenyl group; a pyrenyl group; and a phenyl group, a naphthyl group, an anthryl group, a fluorenyl group, and a pyrenyl group that are substituted with at least one of a deuterium atom, a halogen atom, a hydroxyl group, a cyano group, a nitro group, an amino group, an amidino group, hydrazine, hydrazone, a carboxyl group or a salt thereof, a sulfonic acid group or a salt thereof, a phosphoric acid or a salt thereof, a C₁-C₁₀alkyl group, and a C₁-C₁₀ alkoxy group.

In Formula 300, R₅₉ may be each independently a phenyl group, a naphthyl group, an anthryl group, a biphenyl group, or a pyridyl group; or a phenyl group, a naphthyl group, an anthryl group, a biphenyl group, or a pyridyl group that are substituted with at least one of a deuterium atom, a halogen atom, a hydroxyl group, a cyano group, a nitro group, an amino group, an amidino group, hydrazine, hydrazone, a carboxyl group or a salt thereof, sulfonic acid or a salt thereof, phosphoric acid or a salt thereof, a substituted or unsubstituted C₁-C₂₀ alkyl group, and a substituted or unsubstituted C₁-C₂₀ alkoxy group.

In an embodiment the compound of Formula 300 may be a compound represented by Formula 300A below:

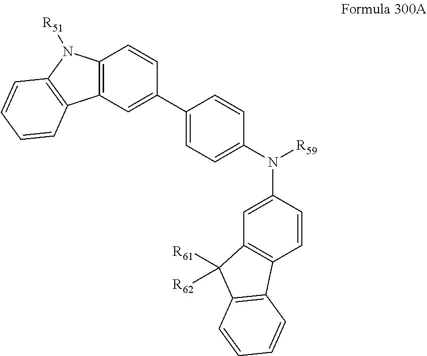

R₅₁, R₆₀, R₆₁ and R₅₉ in Formula 300A are as defined above, and thus a detailed description thereof will not be provided here.

In some non-limiting embodiments, at least one of the HIL, HTL, and H-functional layer may include at least one of compounds represented by Formulae 301 to 320 below:

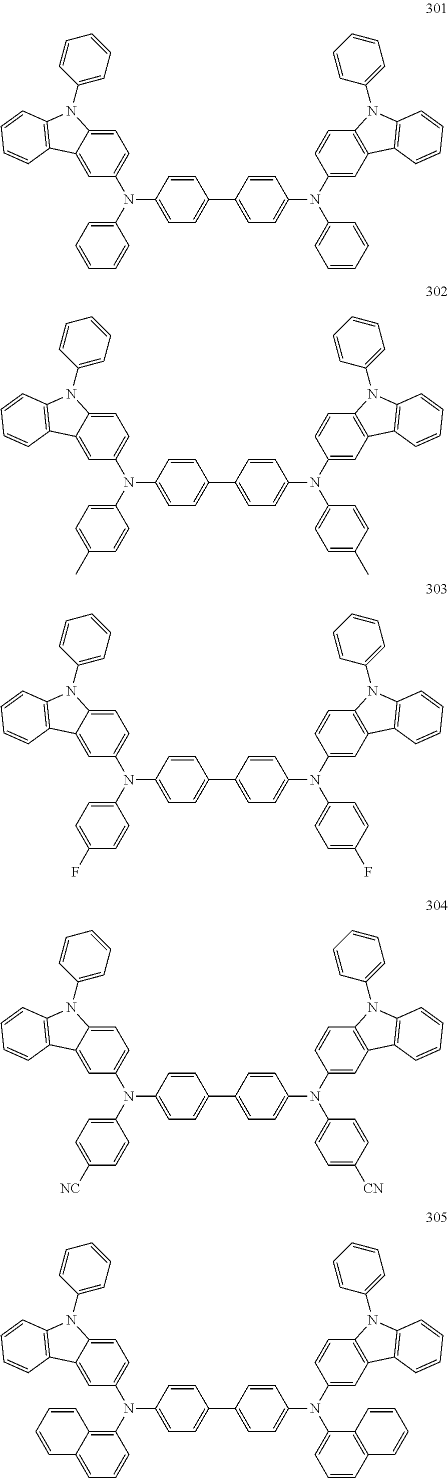

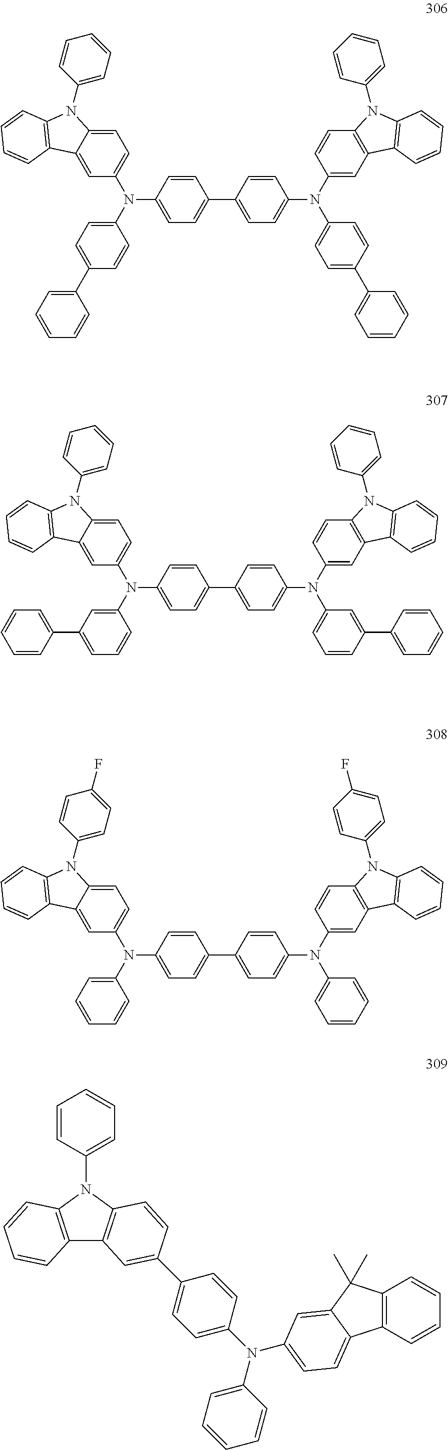 [SMILES: c1ccc(-c2ccc(N(c3ccc(-c4ccc(N(c5ccc(-c6ccccc6)cc5)c5ccc6c(c5)c5ccccc5n6-c5ccccc5)cc4)cc3)c3ccc4c(c3)c3ccccc3n4-c3ccccc3)cc2)cc1 ; c1ccc(-c2cccc(N(c3ccc(-c4ccc(N(c5cccc(-c6ccccc6)c5)c5ccc6c(c5)c5ccccc5n6-c5ccccc5)cc4)cc3)c3ccc4c(c3)c3ccccc3n4-c3ccccc3)c2)cc1 ; Fc1ccc(-n2c3ccccc3c3cc(N(c4ccccc4)c4ccc(-c5ccc(N(c6ccccc6)c6ccc7c(c6)c6ccccc6n7-c6ccc(F)cc6)cc5)cc4)ccc32)cc1 ; CC1(C)c2ccccc2-c2ccc(N(c3ccccc3)c3ccc(-c4ccc5c(c4)c4ccccc4n5-c4ccccc4)cc3)cc21]

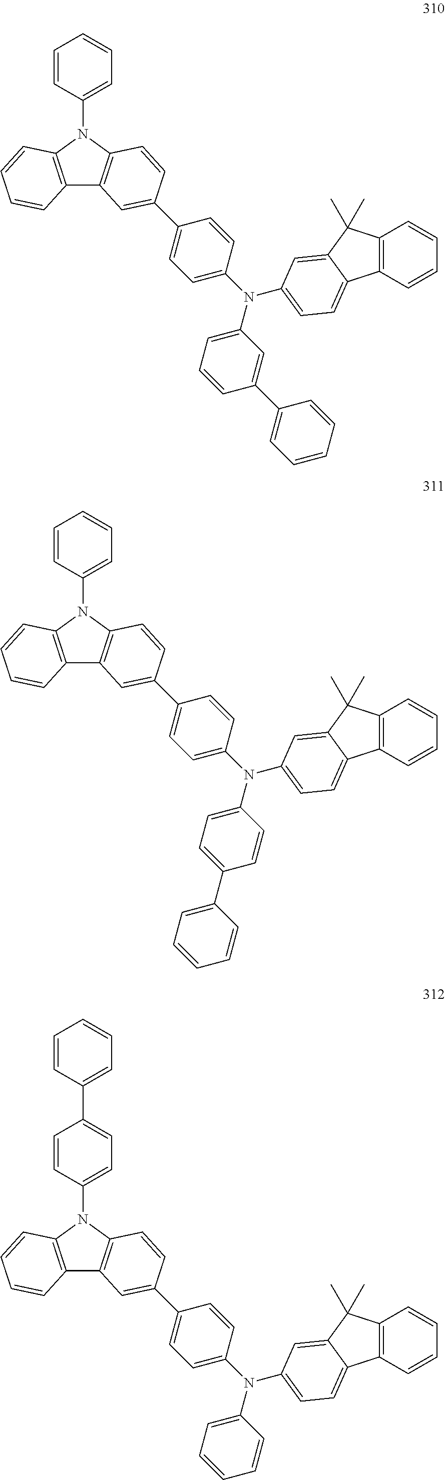 [SMILES: CC1(C)c2ccccc2-c2ccc(N(c3ccc(-c4ccc5c(c4)c4ccccc4n5-c4ccccc4)cc3)c3cccc(-c4ccccc4)c3)cc21 ; CC1(C)c2ccccc2-c2ccc(N(c3ccc(-c4ccccc4)cc3)c3ccc(-c4ccc5c(c4)c4ccccc4n5-c4ccccc4)cc3)cc21 ; CC1(C)c2ccccc2-c2ccc(N(c3ccccc3)c3ccc(-c4ccc5c(c4)c4ccccc4n5-c4ccc(-c5ccccc5)cc4)cc3)cc21]

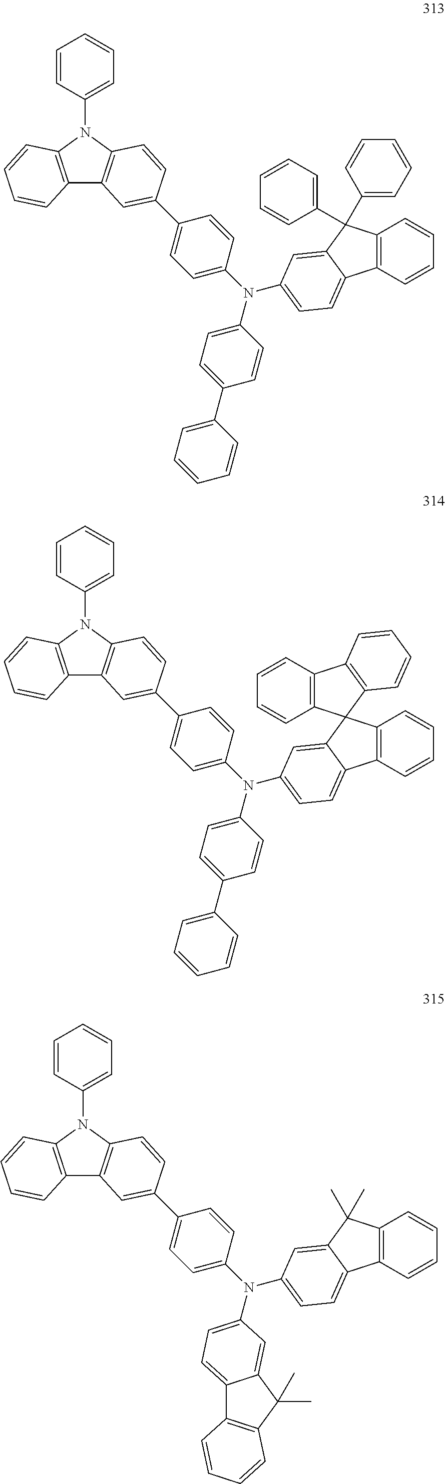 [SMILES: c1ccc(-c2ccc(N(c3ccc(-c4ccc5c(c4)c4ccccc4n5-c4ccccc4)cc3)c3ccc4c(c3)C(c3ccccc3)(c3ccccc3)c3ccccc3-4)cc2)cc1 ; c1ccc(-c2ccc(N(c3ccc(-c4ccc5c(c4)c4ccccc4n5-c4ccccc4)cc3)c3ccc4c(c3)C3(c5ccccc5-c5ccccc53)c3ccccc3-4)cc2)cc1 ; CC1(C)c2ccccc2-c2ccc(N(c3ccc(-c4ccc5c(c4)c4ccccc4n5-c4ccccc4)cc3)c3ccc4c(c3)C(C)(C)c3ccccc3-4)cc21]

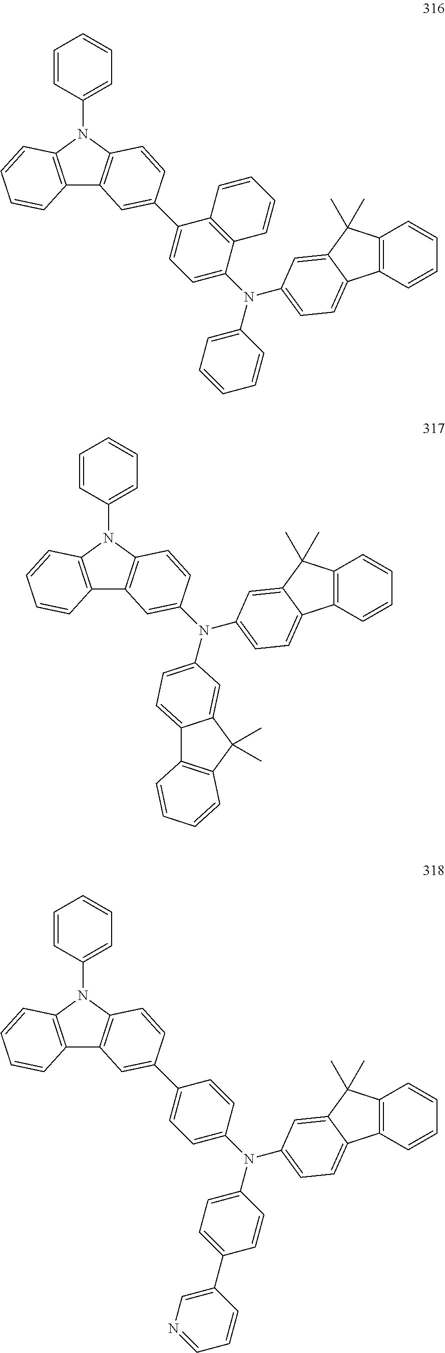 [SMILES: CC1(C)c2ccccc2-c2ccc(N(c3ccccc3)c3ccc(-c4ccc5c(c4)c4ccccc4n5-c4ccccc4)c4ccccc34)cc21 ; CC1(C)c2ccccc2-c2ccc(N(c3ccc4c(c3)C(C)(C)c3ccccc3-4)c3ccc4c(c3)c3ccccc3n4-c3ccccc3)cc21 ; CC1(C)c2ccccc2-c2ccc(N(c3ccc(-c4cccnc4)cc3)c3ccc(-c4ccc5c(c4)c4ccccc4n5-c4ccccc4)cc3)cc21]

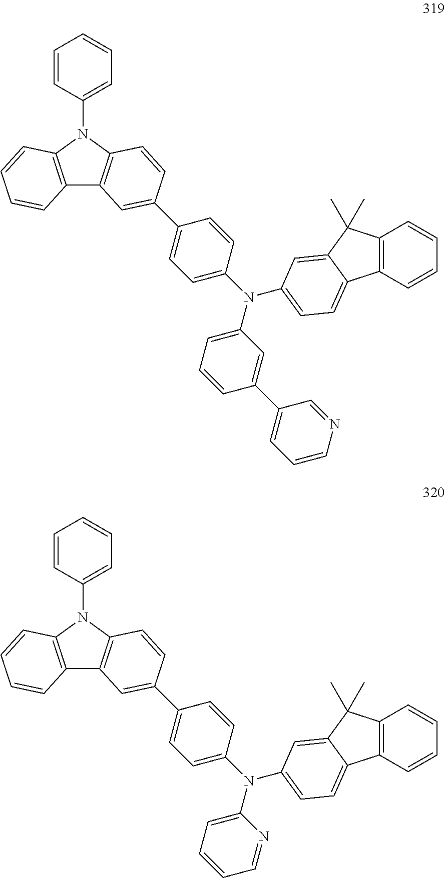 [SMILES: CC1(C)c2ccccc2-c2ccc(N(c3ccc(-c4ccc5c(c4)c4ccccc4n5-c4ccccc4)cc3)c3cccc(-c4cccnc4)c3)cc21 ; CC1(C)c2ccccc2-c2ccc(N(c3ccc(-c4ccc5c(c4)c4ccccc4n5-c4ccccc4)cc3)c3ccccn3)cc21]

At least one of the HIL, HTL, and H-functional layer may further include a charge-generating material for improved layer conductivity, in addition to a known hole injecting material, hole transport material, and/or material having both hole injection and hole transport capabilities as described above.

The charge-generating material may be, for example, a p-dopant. The p-dopant may be one of quinine derivatives, metal oxides, and compounds with a cyano group, but are not limited thereto. Non-limiting examples of the p-dopant are quinone derivatives such as tetracyanoquinonedimethane (TCNQ), 2,3,5,6-tetrafluoro-tetracyano-1,4-benzoquinonedimethane (F4-CTNQ), and the like; metal oxides such as tungsten oxide, molybdenum oxide, and the like; and cyano-containing compounds such as Compound 200 below.

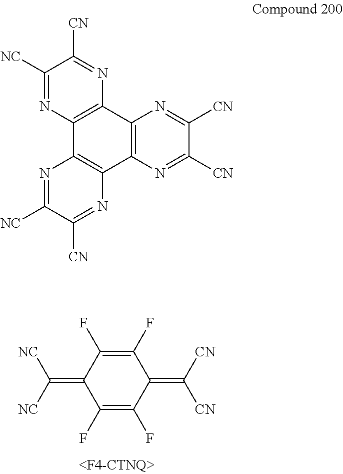 [SMILES: N#Cc1nc2c3nc(C#N)c(C#N)nc3c3nc(C#N)c(C#N)nc3c2nc1C#N ; N#CC(C#N)=c1c(F)c(F)c(=C(C#N)C#N)c(F)c1F]

When the hole injection layer, hole transport layer, or H-functional layer further includes a charge-generating material, the charge-generating material may be homogeneously dispersed or inhomogeneously distributed in the layer.

A buffer layer may be disposed between at least one of the HIL, HTL, and H-functional layer, and the EML. The buffer layer may compensate for an optical resonance distance of light according to a wavelength of the light emitted from the EML, and thus may increase efficiency. The butter layer may include any hole injecting material or hole transporting material that are widely known. In some other embodiments, the buffer layer may include the same material as one of the materials included in the HIL, HTL, and H-functional layer that underly the buffer layer.

Then, an EML may be formed on the HTL, H-functional layer, or buffer layer by vacuum deposition, spin coating, casting, Langmuir-Blodget (LB) deposition, or the like. When the EML is formed using vacuum deposition or spin coating, the deposition and coating conditions may be similar to those for the formation of the HIL, though the conditions for deposition and coating may vary according to the material that is used to form the EML.

The emission layer may include a host.

Non-limiting examples of the host are the compound of Formula 1 above, Alqₐ, 4,4′-N,N′-dicarbazole-biphenyl (CBP), poly(n-vinylcarbazole) (PVK), 9,10-di(naphthalene-2-yl)anthracene (ADN), TCTA, 1,3,5-tris(N-phenylbenzimidazole-2-yl)benzene (TPBI), 3-tert-butyl-9,10-di-2-naphthylanthracene (TBADN), E3, distyrylarylene (DSA), dmCBP (see a formula below), and Compounds 501 to 509 below.

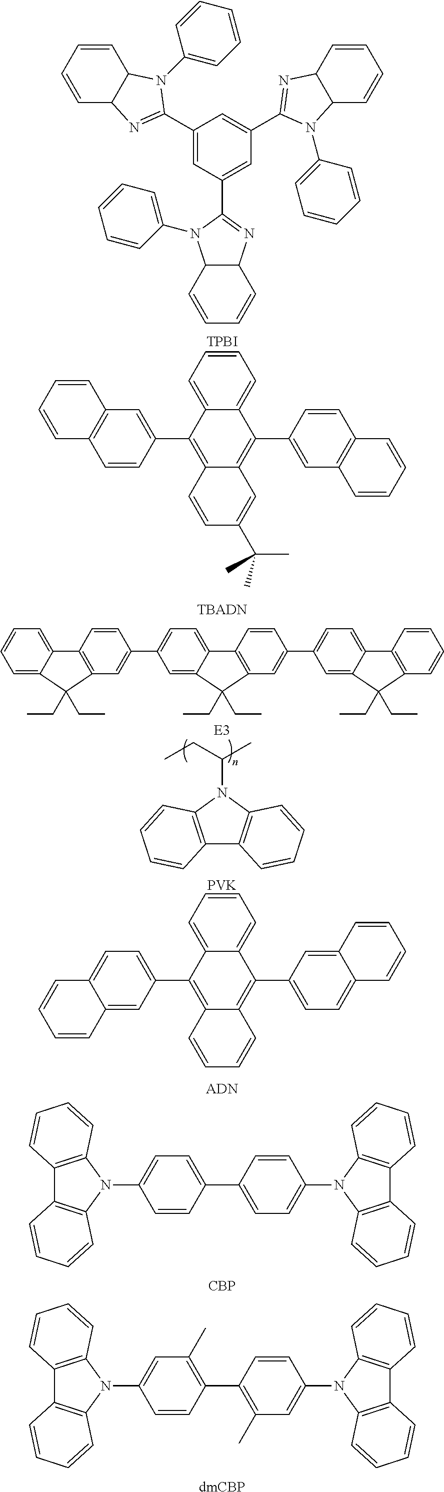

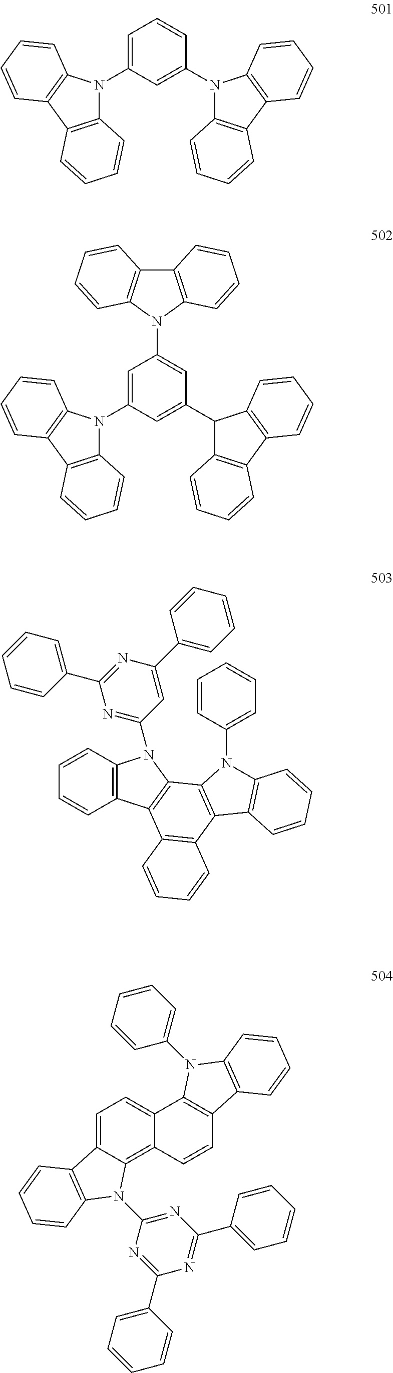 [SMILES: c1cc(-n2c3ccccc3c3ccccc32)cc(-n2c3ccccc3c3ccccc32)c1 ; c1ccc2c(c1)-c1ccccc1C2c1cc(-n2c3ccccc3c3ccccc32)cc(-n2c3ccccc3c3ccccc32)c1 ; c1ccc(-c2cc(-n3c4ccccc4c4c5ccccc5c5c6ccccc6n(-c6ccccc6)c5c43)nc(-c3ccccc3)n2)cc1 ; c1ccc(-c2nc(-c3ccccc3)nc(-n3c4ccccc4c4ccc5c(ccc6c7ccccc7n(-c7ccccc7)c65)c43)n2)cc1]

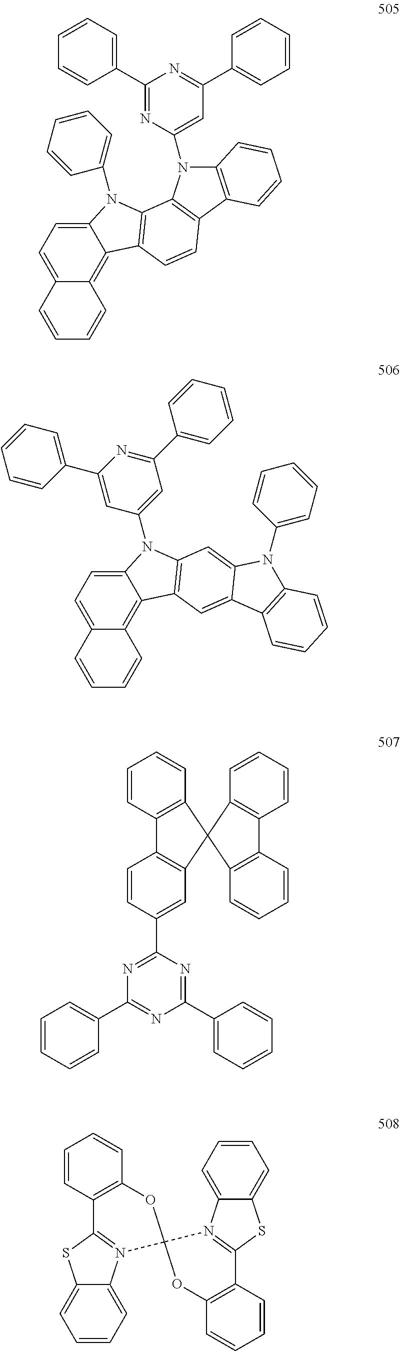

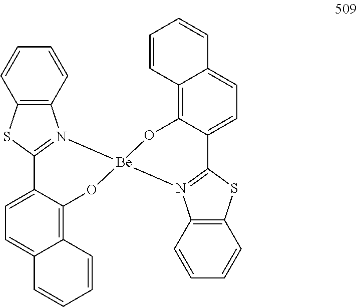

In some embodiments, an anthracene-based compound represented by Formula 400 below may be used as the host.

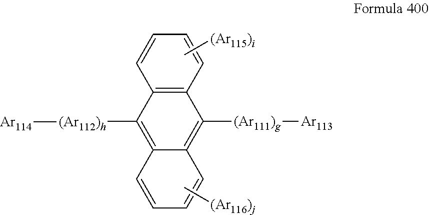

In Formula 400, Ar₁₁₁ and Ar₁₁₂ are each independently a substituted or unsubstituted C5-C₆₀ arylene group; Ar₁₁₃ to Ar₁₁₆ are each independently a substituted or unsubstituted C₁-C₁₀ alkyl group or a substituted or unsubstituted C₅-C₆₀ aryl group; and g, h, I, and j are each independently an integer from 0 to 4.

In some non-limiting embodiments, Ar₁₁₁ and Ar₁₁₂ in Formula 400 may be each independently a phenylene group, a naphthylene group, a phenanthrenylene group, or a pyrenylene group; or a phenylene group, a naphthylene group, a phenanthrenylene group, a fluorenyl group, or a pyrenylene group that are substituted with at least one of a phenyl group, a naphthyl group, and an anthryl group.

In Formula 400 above, g, h, I, and j may be each independently 0, 1, or 2.

In some non-limiting embodiments, Ar₁₁₃ to Ar₁₁₆ in Formula 400 may be each independently one of a C₁-C₁₀ alkyl group substituted with at least one of a phenyl group, a naphthyl group, and an anthryl group; a phenyl group; a naphthyl group; an anthryl group; a pyrenyl group; a phenanthrenyl group; a fluorenyl group; a phenyl group, a naphthyl group, an anthryl group, a pyrenyl group, a phenanthrenyl group, and a fluorenyl group that are substituted with at least one of a deuterium atom, a halogen atom, a hydroxyl group, a cyano group, a nitro group, an amino group, an amidino group, hydrazine, hydrazone, a carboxyl group or a salt thereof, a sulfonic acid group or a salt thereof, a phosphoric acid or a salt thereof, a C₁-C₆₀ alkyl group, a C₂-C₆₀ alkenyl group, a C₂-C₆₀ alkynyl group, a C₁-C₆₀ alkoxy group, a phenyl group, a naphthyl group, an anthryl group, a pyrenyl group, a phenanthrenyl group, and a fluorenyl group; and

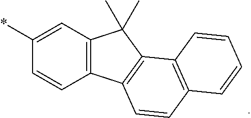 [SMILES: *c1ccc2c(c1)C(C)(C)c1c-2ccc2ccccc12]

For example, the anthracene compound of Formula 400 above may be one of the compounds represented by the following formulae, but is not limited thereto:

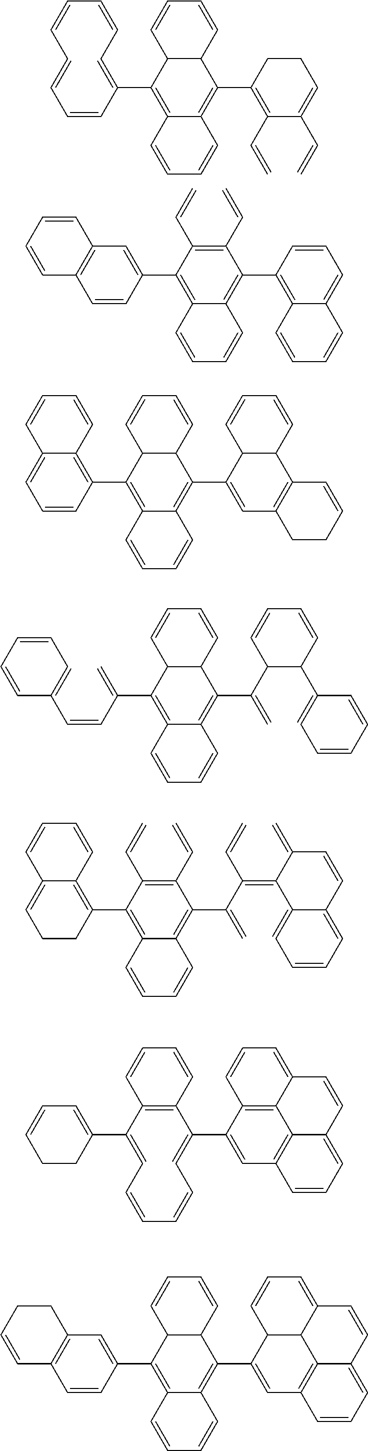

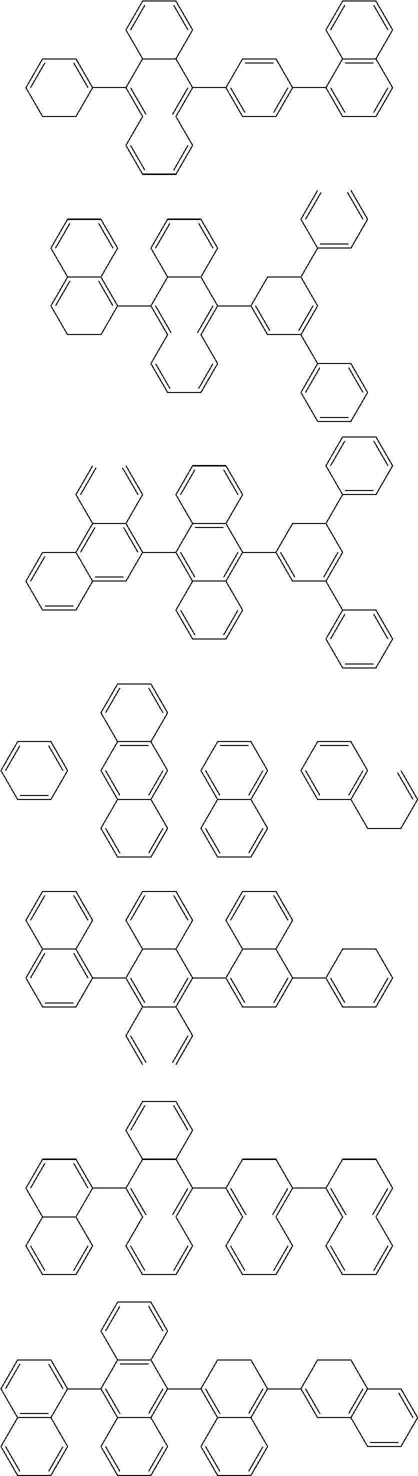

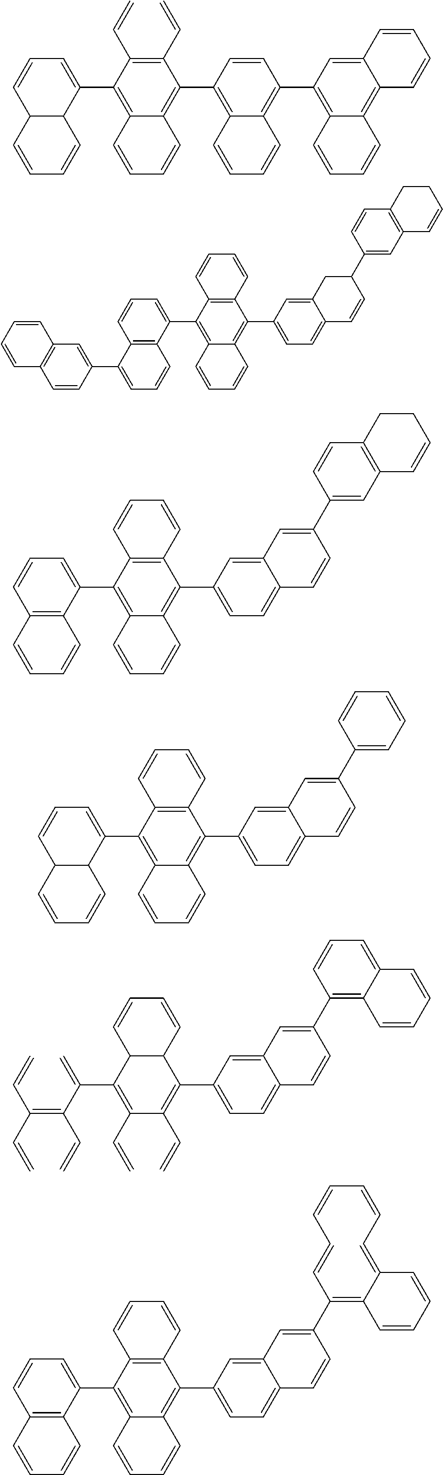

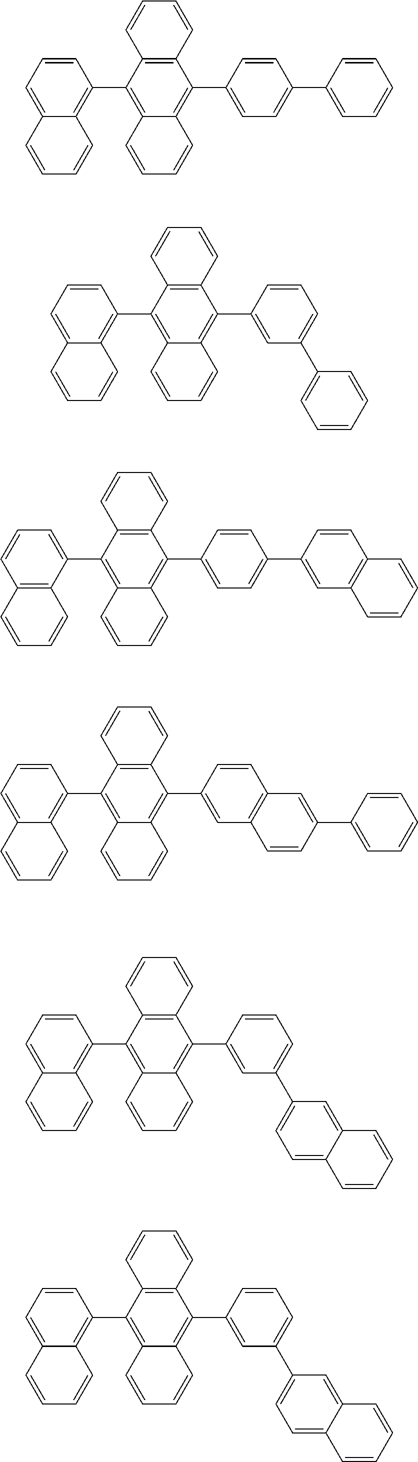

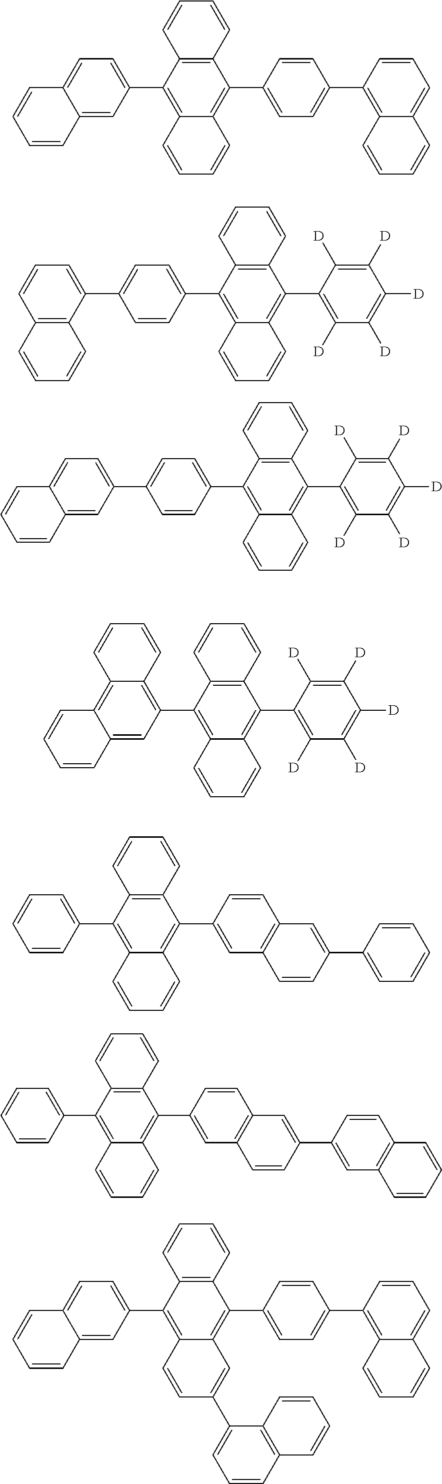

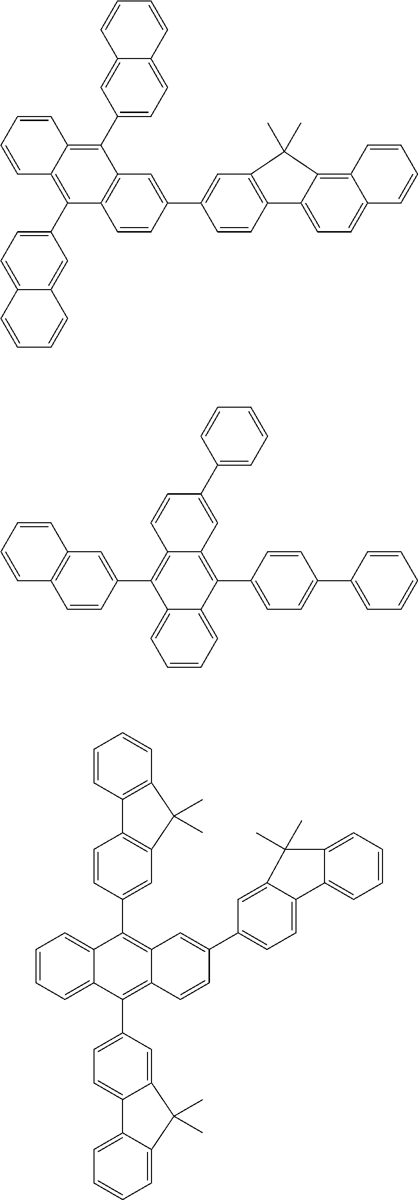

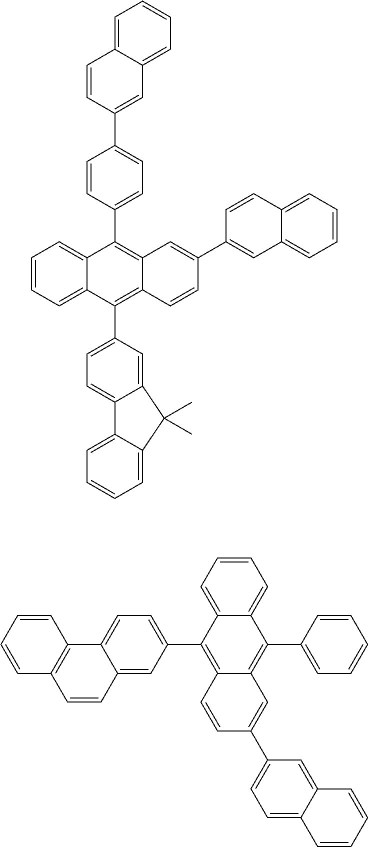

In some embodiments, an anthracene-based compound represented by Formula 401 below may be used as the host.

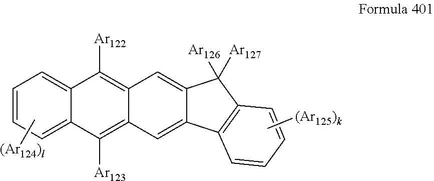

Ar₁₂₂ to Ar₁₂₅ in Formula 401 above may be defined as described above in conjunction with Ar₁₁₃ of Formula 400, and thus detailed descriptions thereof will not be provided here.

Ar₁₂₆ and Ar₁₂₇ in Formula 401 above may be each independently a C₁-C₁₀ alkyl group, for example, a methyl group, an ethyl group, or a propyl group.

In Formula 401, k and 1 may be each independently an integer from 0 to 4, for example, 0, 1, or 2.

For example, the anthracene compound of Formula 401 above may be one of the compounds represented by the following formulae, but is not limited thereto:

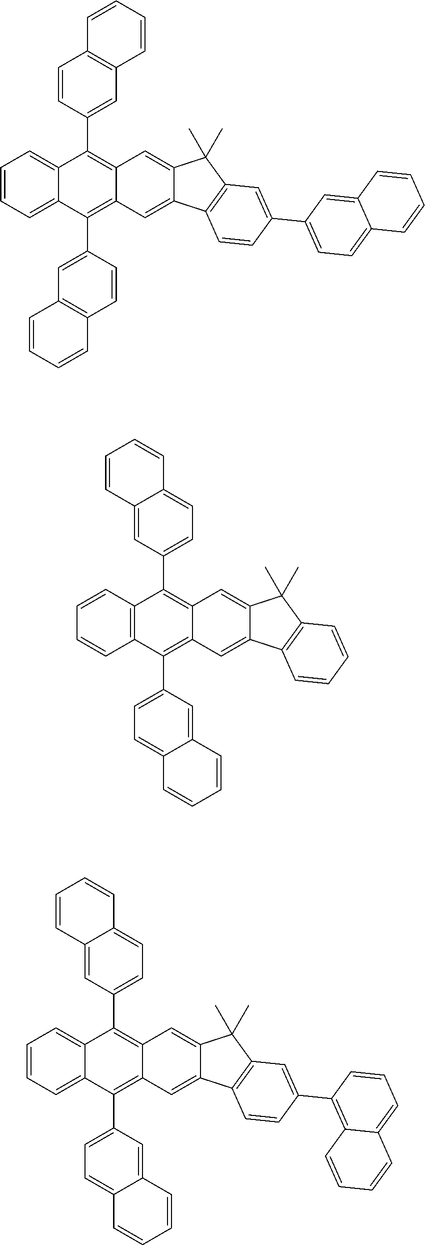

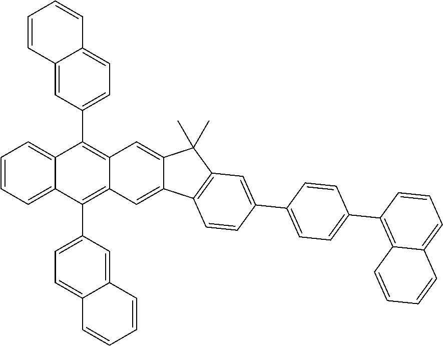 [SMILES: CC1(C)c2cc(-c3ccc(-c4cccc5ccccc45)cc3)ccc2-c2cc3c(-c4ccc5ccccc5c4)c4ccccc4c(-c4ccc5ccccc5c4)c3cc21]

When the organic light-emitting device is a full color organic light-emitting device, the emission layer may be patterned into a red emission layer, a green emission layer, and a blue emission layer.

A (stacked) white organic light-emitting device (for a LGD's TV structure, or a white illumination organic light-emitting device structure) may also be manufactured using the compound of Formula 1 above and the compound of Formula 2 above. A detailed description of the technology relating to the (stacked) white organic light-emitting device, which is widely known, will not be provided herein.

At least one of the red EML, the green EML, and the blue EML may include the compound of Formula 2 above, or a dopant below (ppy=phenylpyridine).

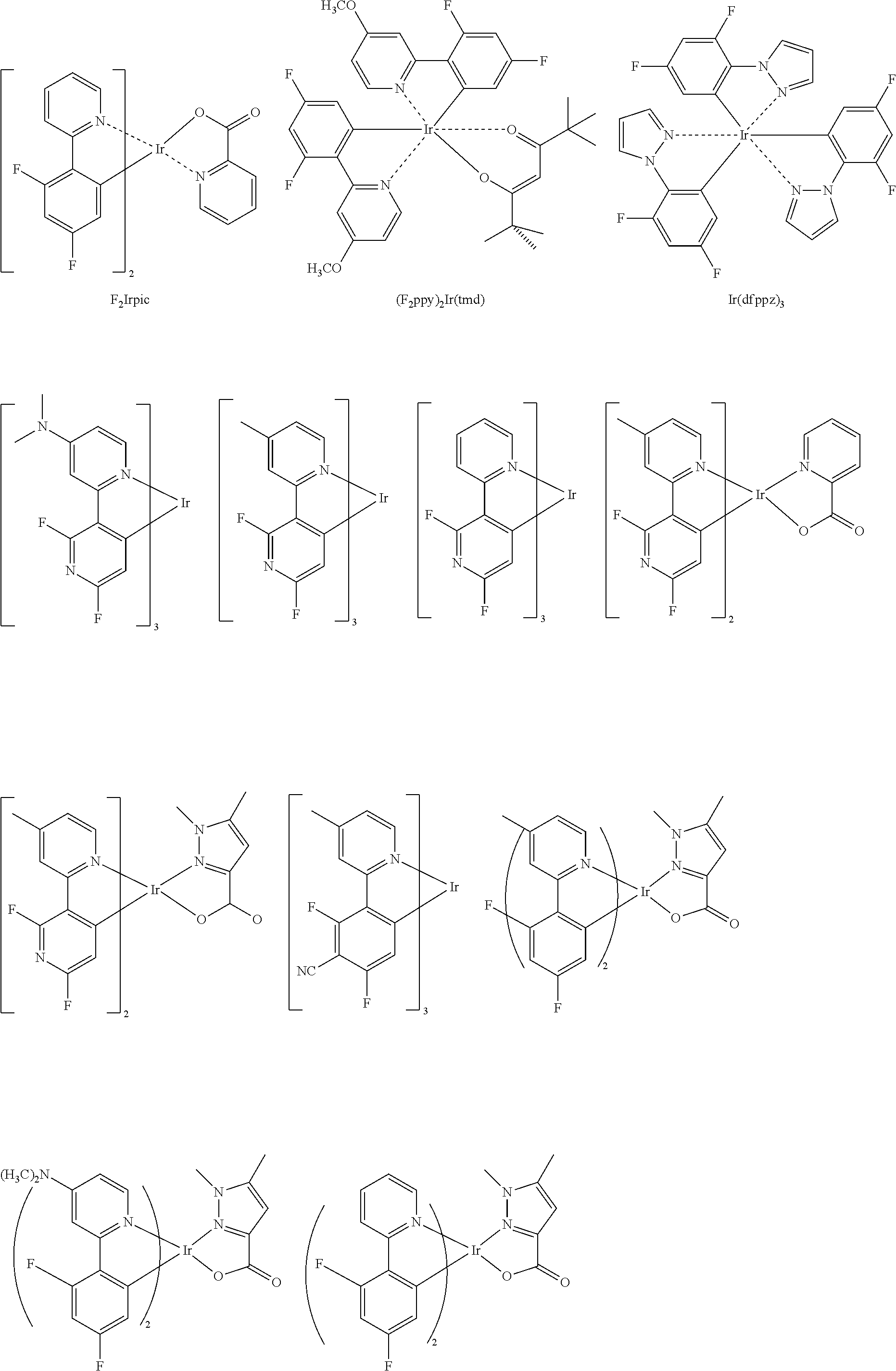

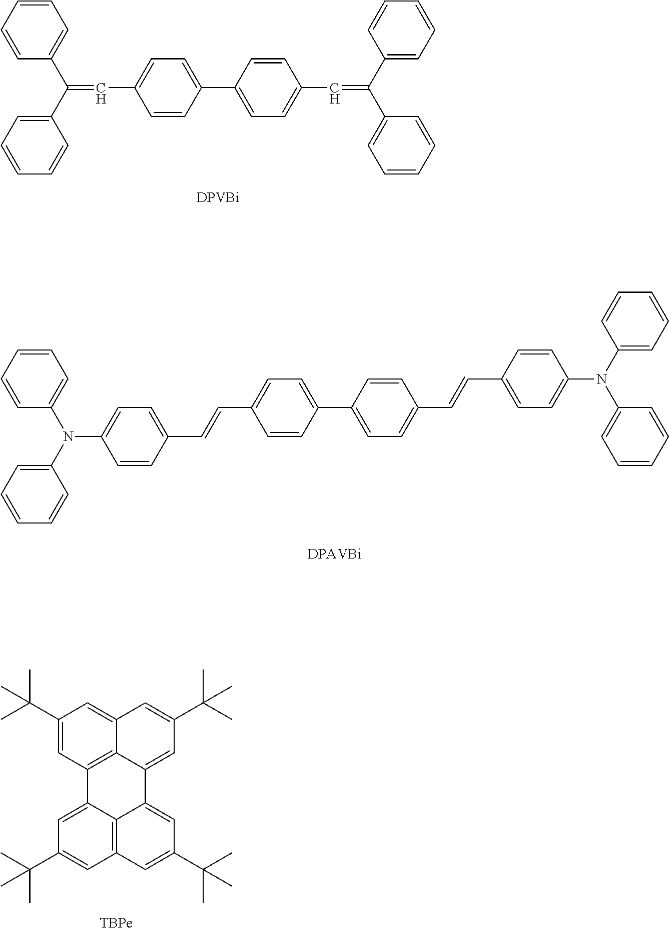

Non-limiting examples of the red dopant are compounds represented by the following formulae.

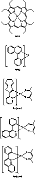

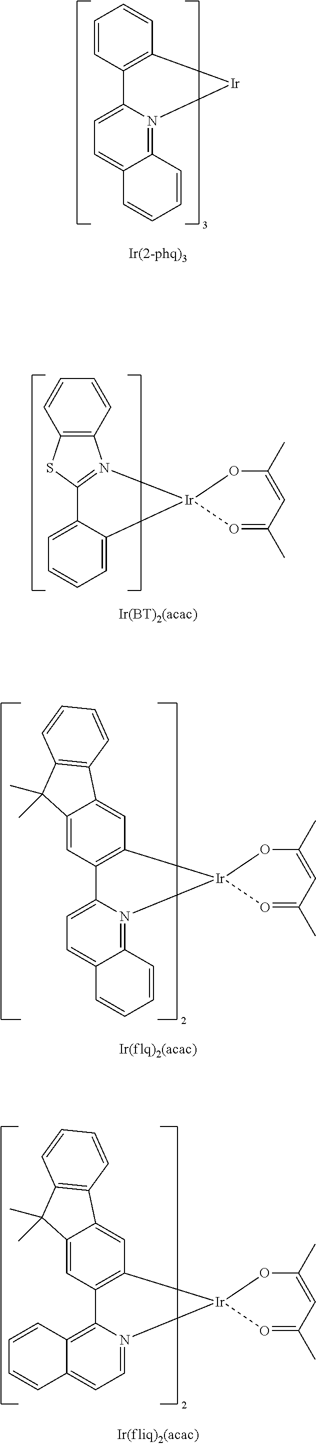

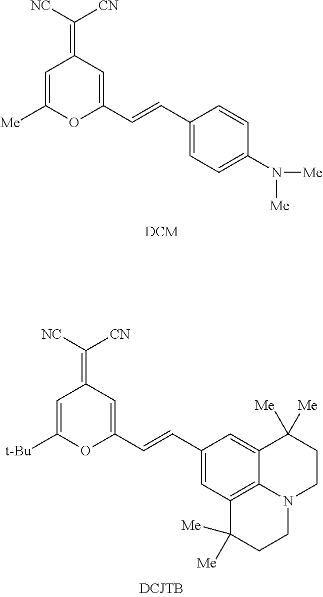 [SMILES: CC1=CC(=C(C#N)C#N)C=C(/C=C/c2ccc(N(C)C)cc2)O1 ; CC(C)(C)C1=CC(=C(C#N)C#N)C=C(/C=C/c2cc3c4c(c2)C(C)(C)CCN4CCC3(C)C)O1]

Non-limiting examples of the green dopant are compounds represented by the following formulae.

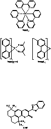

Non-limiting examples of the dopant that may be used in the EML are Pt complexes represented by the following formulae.

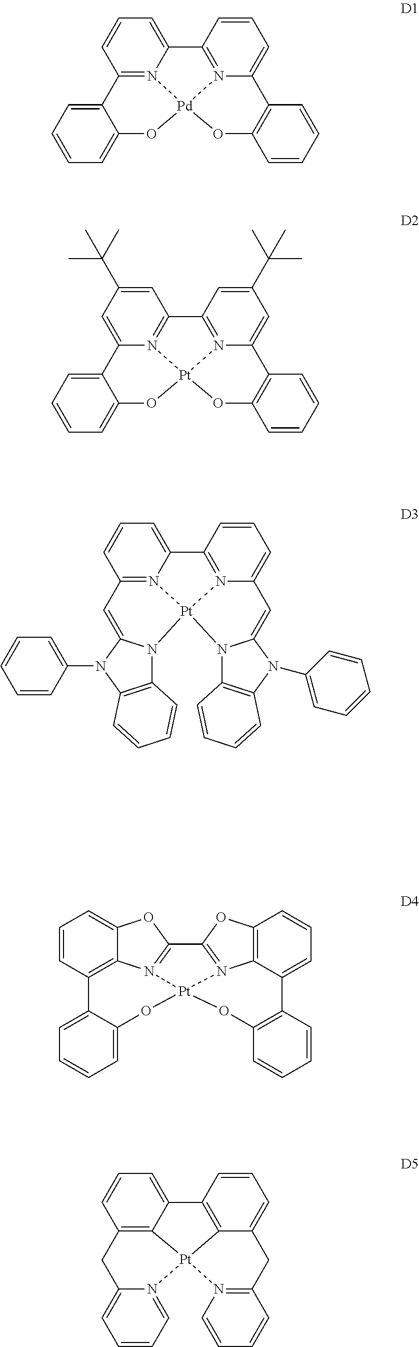

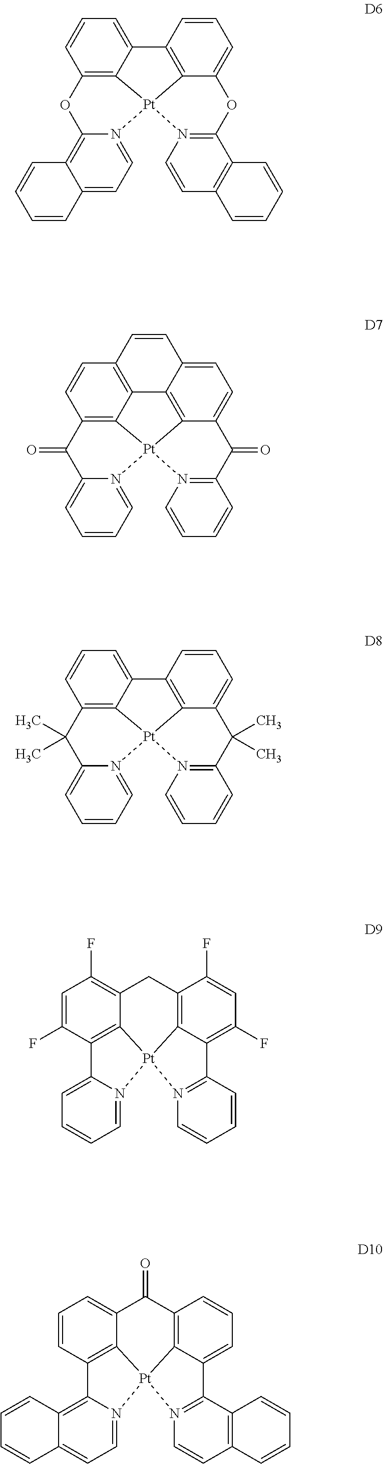

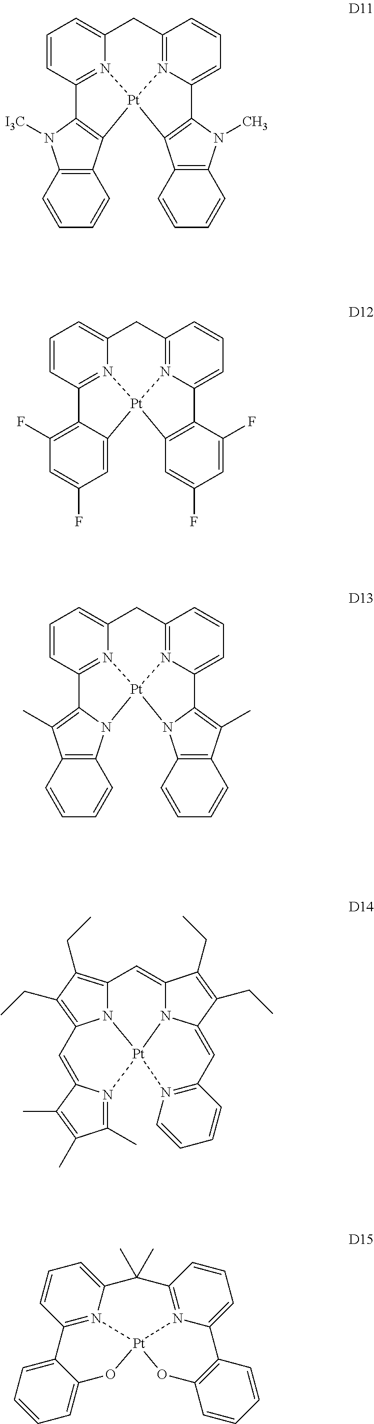

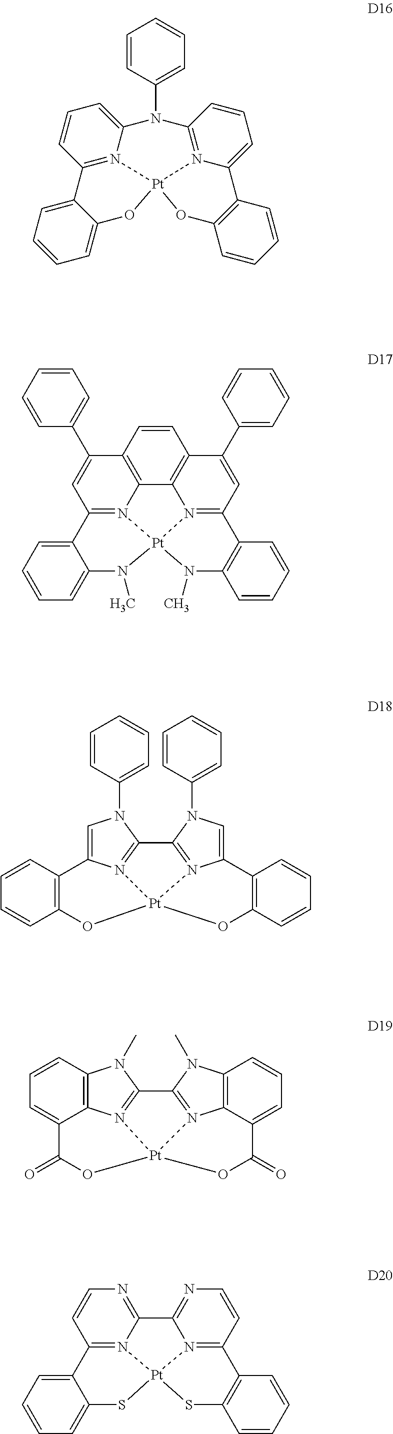

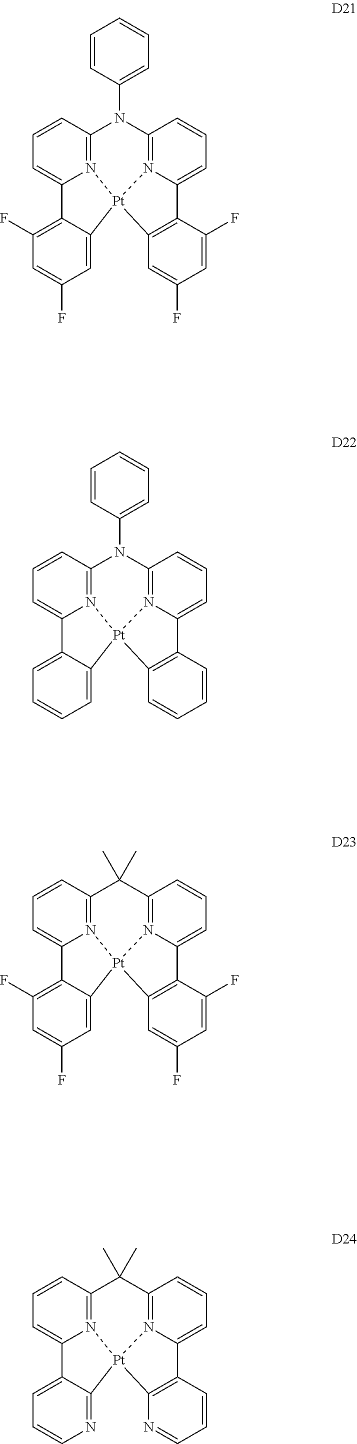

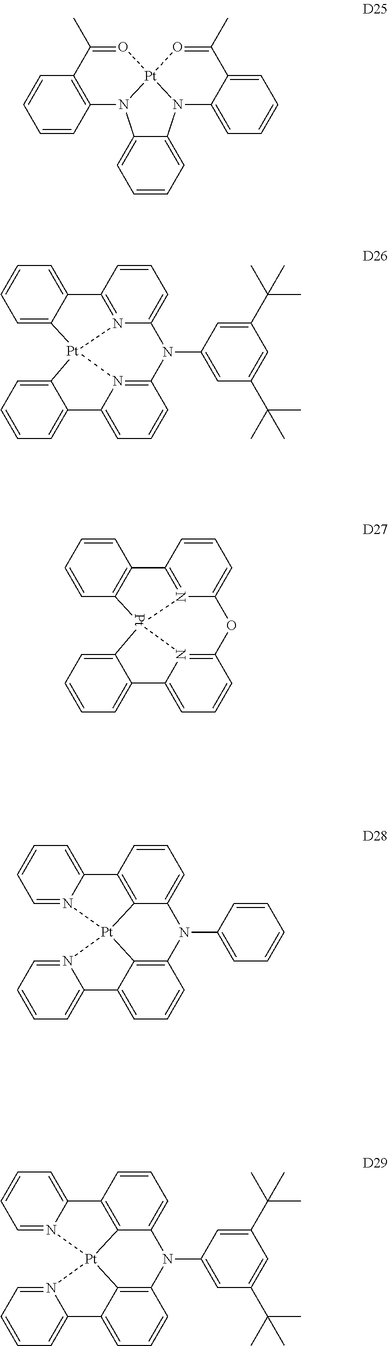

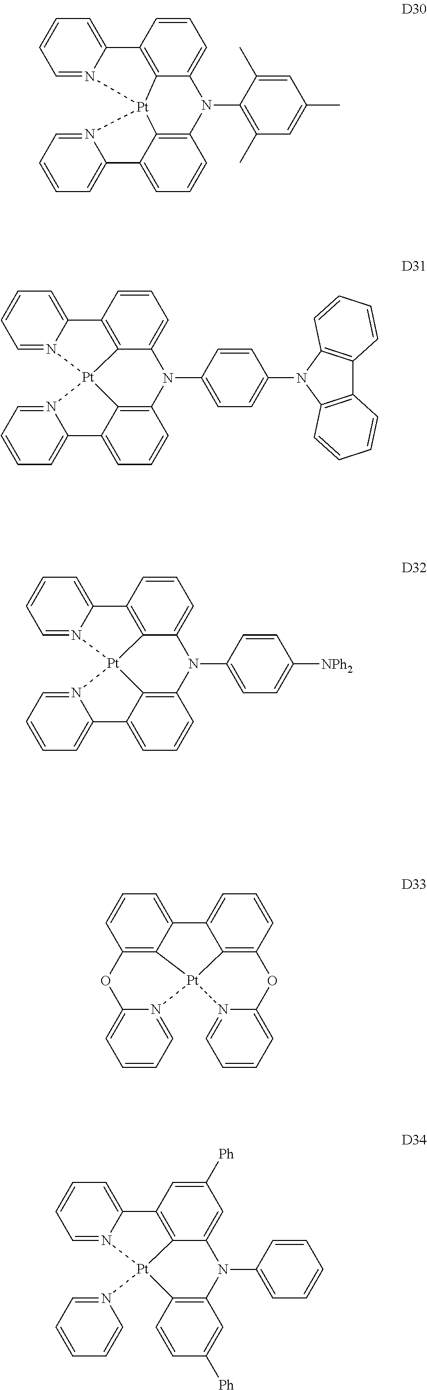

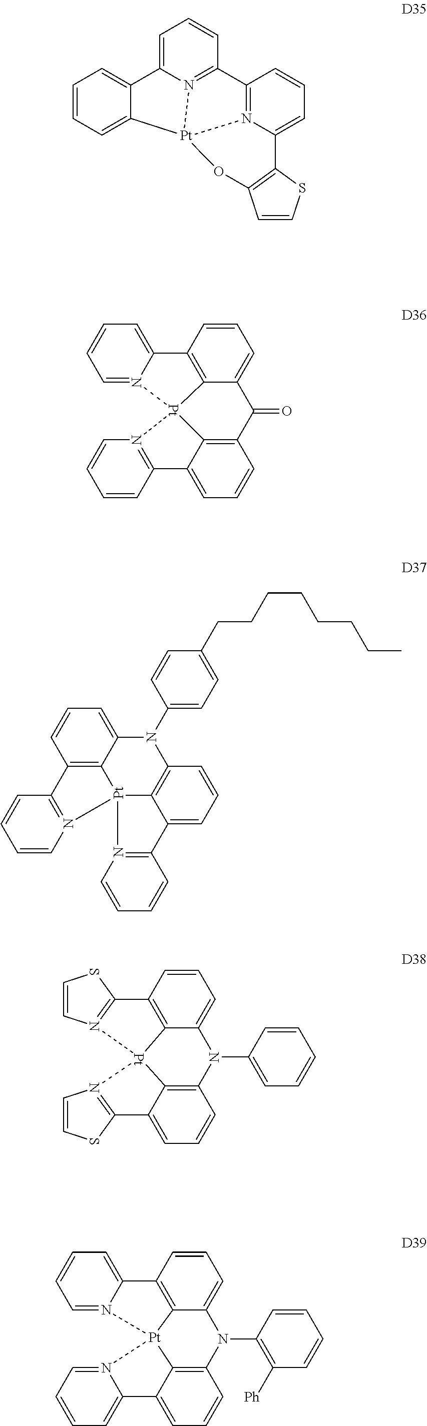

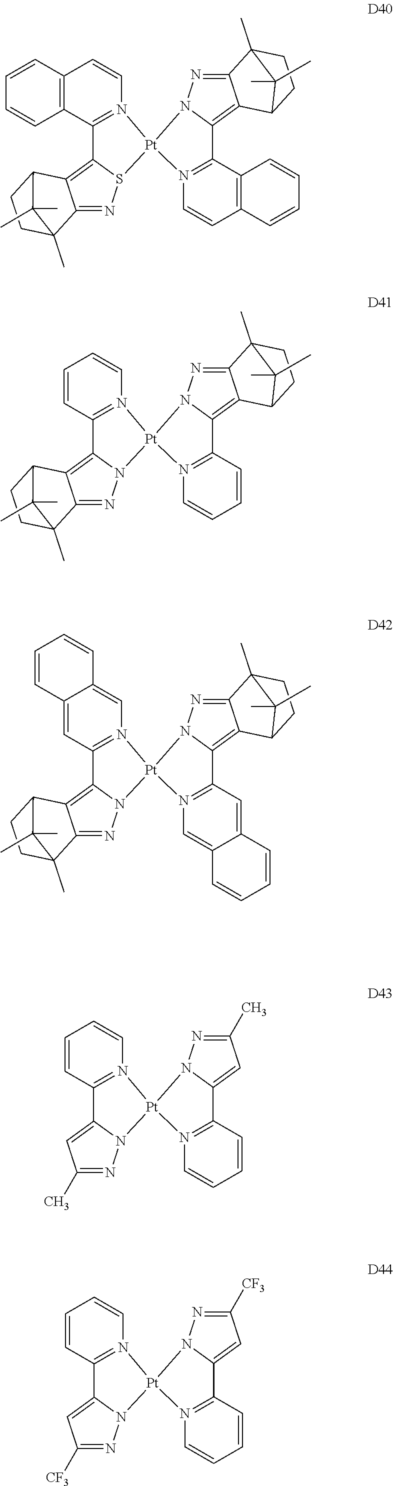

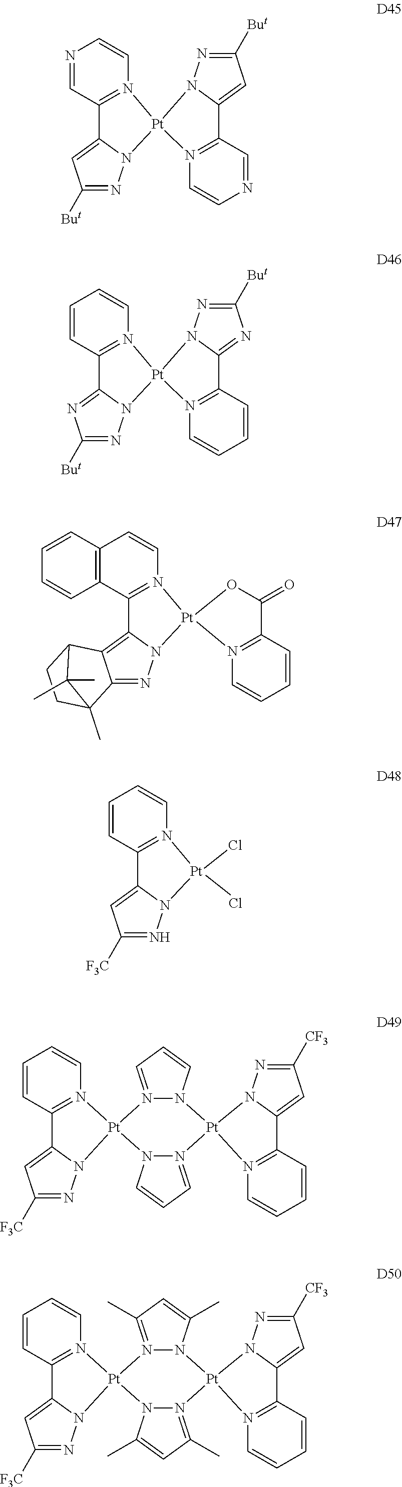

Non-limiting examples of the dopant that may be used in the EML are Os complexes represented by the following formulae.

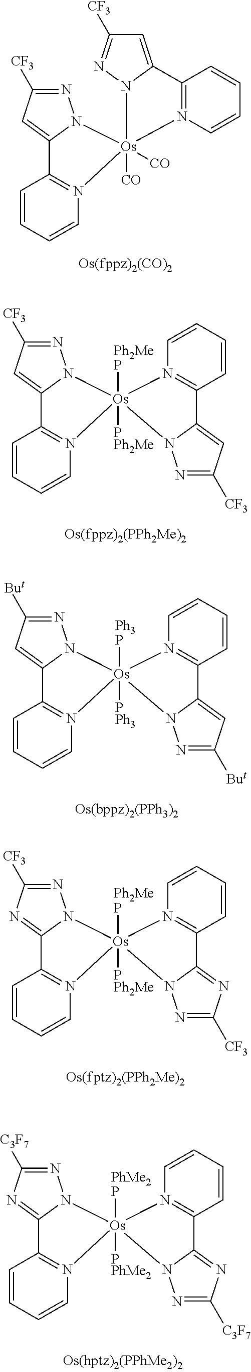

When the EML includes both a host and a dopant, the amount of the dopant may be from about 0.01 to about 15 parts by weight based on 100 parts by weight of the host. However, the amount of the dopant is not limited to this range.

The thickness of the EML may be about 100 Å to about 1000 Å, and in some embodiments, may be from about 200 Å to about 600 Å. When the thickness of the EML is within these ranges, the EML may have good light emitting ability without a substantial increase in driving voltage.

Then, an ETL may be formed on the EML by vacuum deposition, spin coating, casting, or the like. When the ETL is formed using vacuum deposition or spin coating, the deposition and coating conditions may be similar to those for the formation of the FEL, though the deposition and coating conditions may vary according to a compound that is used to form the ETL. A material for forming the ETL may be any known material that can stably transport electrons injected from an electron injecting electrode (cathode). Non-limiting examples of materials for forming the ETL are a quinoline derivative, such as tris(8-quinolinorate)aluminum (Alq3), TAZ, BAlq, beryllium bis(benzoquinolin-10-olate (Bebq₂), 9,10-di(naphth-2-yl)anthracene (ADN), Compound 201, and Compound 202, but are not limited thereto.

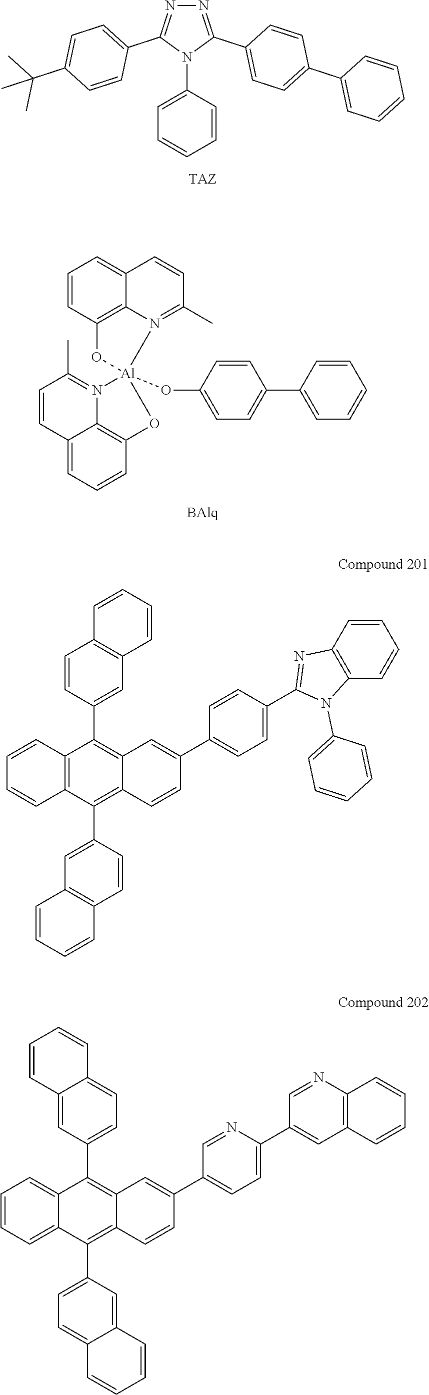

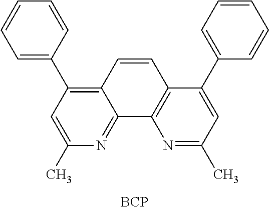 [SMILES: Cc1cc(-c2ccccc2)c2ccc3c(-c4ccccc4)cc(C)nc3c2n1 ; "BCP"]

The thickness of the ETL may be from about 100 Å to about 1,000 Å, and in some embodiments, may be from about 150 Å to about 500 Å. When the thickness of the ETL is within these ranges, the ETL may have satisfactory electron transporting ability without a substantial increase in driving voltage.

In some embodiments the ETL may further include a metal-containing material, in addition to any known electron-transporting organic compound.

The metal-containing material may include a lithium (Li) complex. Non-limiting examples of the Li complex are lithium quinolate (LiQ) and Compound 203 below:

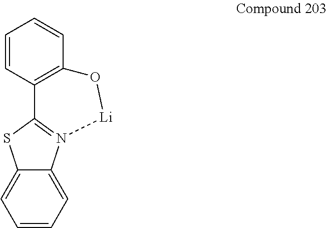

Then, an EIL, which facilitates injection of electrons from the cathode, may be formed on the ETL. Any suitable electron-injecting material may be used to form the EIL.

Non-limiting examples of materials for forming the EIL are LiF, NaCl, CsF, Li₂O, and BaO, which are known in the art. The deposition and coating conditions for forming the EIL may be similar to those for the formation of the HIL, though the deposition and coating conditions may vary according to the material that is used to form the EIL 18.

The thickness of the EIL may be from about lÅ to about 100 Å, and in some embodiments, may be from about 3 Å to about 90 Å. When the thickness of the EIL is within these ranges, the EIL may have satisfactory electron injection ability without a substantial increase in driving voltage.

Finally, the second electrode is disposed on the organic layer. The second electrode may be a cathode that is an electron injection electrode. A material for forming the second electrode 17 may be a metal, an alloy, an electro-conductive compound, which have a low work function, or a mixture thereof. In this regard, the second electrode may be formed of lithium (Li), magnesium (Mg), aluminum (Al), aluminum (Al)-lithium (Li), calcium (Ca), magnesium (Mg)-indium (In), magnesium (Mg)-silver (Ag), or the like, and may be formed as a thin film type transmission electrode. In some embodiments, to manufacture a top-emission light-emitting device, the transmission electrode may be formed of indium tin oxide (ITO) or indium zinc oxide (IZO).

Although the organic light-emitting device of FIG. 1 is described above, the present embodiments are not limited thereto.

When a phosphorescent dopant is used in the EML, a HBL may be formed between the HTL and the EML or between the H-functional layer and the EML by using vacuum deposition, spin coating, casting, Langmuir-Blodgett (LB) deposition, or the like, in order to prevent diffusion of triplet excitons or holes into the ETL. When the HBL is formed using vacuum deposition or spin coating, the conditions for deposition and coating may be similar to those for the formation of the HIL, although the conditions for deposition and coating may vary according to the material that is used to form the HBL. Any known hole-blocking material may be used. Non-limiting examples of hole-blocking materials are oxadiazole derivatives, triazole derivatives, and phenanthroline derivatives. For example, 2,9-dimethyl-4,7-diphenyl-1,10-phenanthroline (BCP) represented by the following formula may be used as a material for forming the HBL.

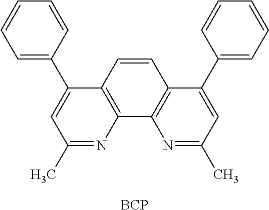 [SMILES: Cc1cc(-c2ccccc2)c2ccc3c(-c4ccccc4)cc(C)nc3c2n1 ; "BCP"]

The thickness of the HBL may be from about 20 Å to about 1000 Å, and in some embodiments, may be from about 30 Å to about 300 Å. When the thickness of the HBL is within these ranges, the HBL may have improved hole blocking ability without a substantial increase in driving voltage.

According to aspects of the present embodiments, the organic light-emitting device may be included in various types of flat panel display devices, such as in a passive matrix organic light-emitting display device or in an active matrix organic light-emitting display device. In particular, when the organic light-emitting device is included in an active matrix organic light-emitting display device including a thin-film transistor, the first electrode on the substrate may function as a pixel electrode, electrically connected to a source electrode or a drain electrode of the thin-film transistor. Moreover, the organic light-emitting device may also be included in flat panel display devices having double-sided screens.

In some embodiments the organic layer of the organic light-emitting device may be formed of the compounds of Formulae 1 and 2 by using a deposition method or may be formed using a wet method of coating a solution of the compounds of Formulas 1 and 2.

Hereinafter, the present embodiments will be described in detail with reference to the following synthesis examples and other examples. However, these examples are for illustrative purposes only and are not intended to limit the scope of the present embodiments.

### EXAMPLES

### Synthesis Example 1-1

### Synthesis of Intermediate 2-a

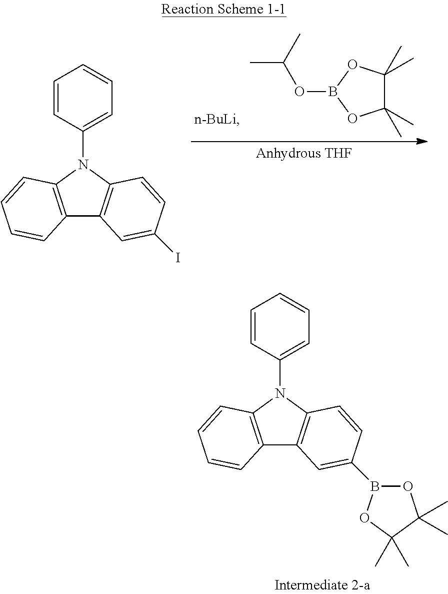 [SMILES: Ic1ccc2c(c1)c1ccccc1n2-c1ccccc1 ; CC(C)OB1OC(C)(C)C(C)(C)O1 ; CC1(C)OB(c2ccc3c(c2)c2ccccc2n3-c2ccccc2)OC1(C)C]

6 g (16.25 mmol) of 3-iodo-N-phenyl-carbazole was dissolved in 100 mL of tetrahydrofuran in an argon atmosphere to obtain a solution, followed by slowly adding 20.31 mL (32.50 mmol) of n-butyl)lithium (1.6M solution in n-hexane) at about −78° C. and stirring a resulting mixture for about 2 hours. 6.65 mL (32.50 mmol) of 2-isopropoxy-4,4,5,5-tetramethyl-1,3,2-dioxaborolane was slowly added to the mixture at the same temperature of −78° C., followed by slowly increasing the temperature to room temperature and stirring for about 15 hours. The resulting reaction mixture was extracted with 300 mL of a saturated NaCl solution and dichloromethane, then washed with saturated NaCl solution three times to separate an organic phase. Afterward, the residual humidity of the organic phase was removed with anhydrous magnesium sulfate. The resulting organic phase was dried under a reduced pressure to obtain an organic mixture, which was then purified by column chromatography to obtain 4.3 g (11.64 mmol) of N-phenyl-3-(4,4,5,5-tetramethyl-1,3,2-dioxaborolane-2-yl)-6H-carbazole).

### Synthesis Example 1

### Synthesis of Intermediate 2-b

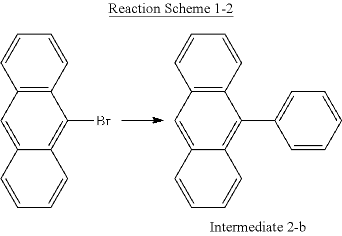

3.56 g (13.84 mmol) of 9-bromo-anthracene, 1.69 g (13.84 mmol) of phenyl boronic acid, 0.48 g (0.415 mmol) of tetrakis(triphenylphosphine)palladium(0)) were dissolved in a mixed solution of toluene (40 mL), ethanol (8 mL), and 2N sodium carbonate solution (20 mL) in an argon atmosphere, then stirred under reflux at about 100° C. After 12 hours, the resulting solution refluxed with stirring was cooled to room temperature, followed by adding the reaction solution to about 300 mL of water to terminate the reaction, neutralization, and extraction with dichloromethane. The residual moisture was removed from the extracted organic phase using anhydrous magnesium sulfate, dried in a reduced atmosphere, and then recrystallized using chloroform, thereby obtaining 2.29 g (9.035 mmol) of 9-phenyl-anthracene with an yield of about 65%.

### Synthesis Example 1

### Synthesis of Intermediate 2-c

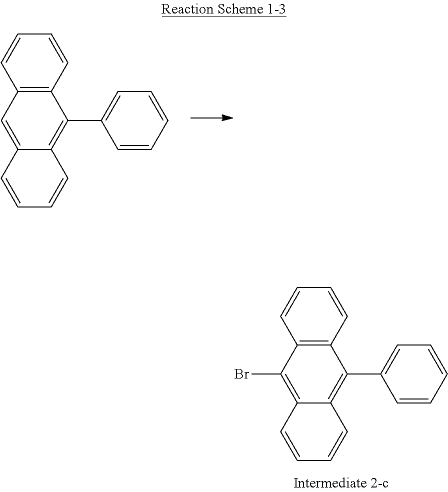

2.30 g (9.06 mmol) of 9-phenyl-anthracene, and 1.62 g (9.06 mmol) of N-bromosuccinimide (NBS) were dissolved in 100 mL of chloroform, and then stirred under reflux at about 60° C. for about 3 hours. Afterward, the resulting solution refluxed with stirring was cooled to room temperature, followed by adding 300 mL of water to the reaction solution to terminate the reaction, extraction with chloroform, reducing the residual moisture using anhydrous magnesium sulfate, and drying under a reduced pressure. The resulting mixture was refined by column chromatography using column chromatography using chloroform, followed by reprecipitation using dichloromethane/ethanol to obtain 2.95 g (8.87 mmol) of 9-bromo-10-phenyl-anthracene with a yield of about 98%.

### Synthesis Example 1-4

### Synthesis of Compound 2

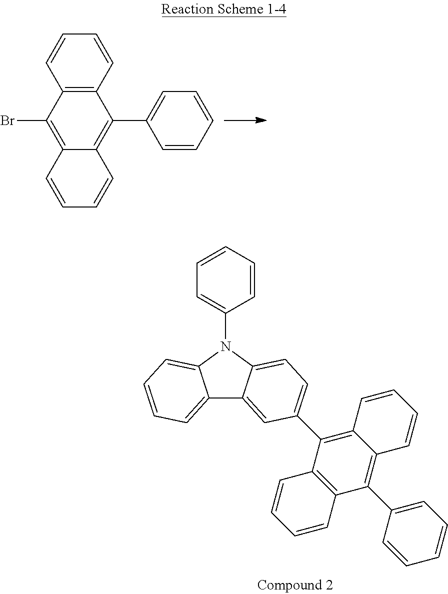 [SMILES: Brc1c2ccccc2c(-c2ccccc2)c2ccccc12 ; c1ccc(-c2c3ccccc3c(-c3ccc4c(c3)c3ccccc3n4-c3ccccc3)c3ccccc23)cc1]

3.28 g (8.87 mmol) of Intermediate 2-a, 2.95 g (8.87 mmol) of 9-bromo-10-phenyl-anthracene, and 0.61 g (0.53 mmol) of tetrakis(triphenylphosphine)palladium(0) were dissolved in a mixed solution of toluene (40 mL), ethanol (8 mL), and 2N sodium carbonate solution (20 mL) in an argon atmosphere, then stirred under reflux at about 100° C. After 12 hours, the resulting solution refluxed with stirring was cooled to room temperature, followed by adding the reaction solution to about 300 mL of water to terminate the reaction, neutralization, and extraction with dichloromethane. The residual moisture was removed from the extracted organic phase using anhydrous magnesium sulfate, and dried in a reduced atmosphere to obtain an organic mixture, which was then refined by column chromatography using chloroform/n-hexane (3:7 v/v), followed by reprecipitation using dichloromethane/methanol to obtain 1.77 g (5.31 mmol) of compound 2 with a yield of about 60%. MS (FAB, m/z): 495.20 (calculated), 495.20 (found)

### Synthesis Example 2

### Synthesis of Compound 10

Compound 10 was synthesized in the same manner as in Synthesis Example 1, except that naphthalene-1-boronic acid, instead of phenyl-boronic acid, was used. (Yield: 38%)

MS (FAB, m/z): 545.21 (calculated), 545.21 (found)

### Synthesis Example 3

### Synthesis of Compound 26

Compound 26 was synthesized in the same manner as in Synthesis Example 1, except that phenanthren-8-boronic acid, instead of phenyl-boronic acid, was used. (Yield: 41%). MS (FAB, m/z): 595.23 (calculated), 595.23 (found)

### Synthesis Example 4

### Synthesis of Compound 34

Compound 34 was synthesized in the same manner as in Synthesis Example 1, except that pyridine-3-boronic acid, instead of phenyl-boronic acid, was used. (Yield: 35%). MS (FAB, m/z): 496.19 (calculated), 496.19 (found)

### Synthesis Example 5

### Synthesis of Compound 42

Compound 42 was synthesized in the same manner as in Synthesis Example 1, except that quinoline-3-boronic acid, instead of phenyl-boronic acid, was used. (Yield: 46%). MS (FAB, m/z): 546.21 (calculated), 546.21 (found)

### Synthesis Example 6

### Synthesis of Compound 57

### Synthesis Example 6-1

### Synthesis of Intermediate 57-a

Intermediate 57-a was synthesized according to Reaction Scheme 6-1 below:

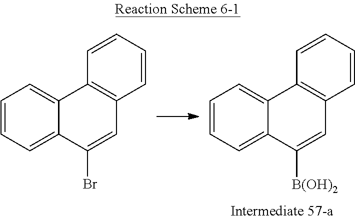 [SMILES: Brc1cc2ccccc2c2ccccc12 ; OB(O)c1cc2ccccc2c2ccccc12]

50 g (194 mmol) of 9-bromophenanthren was put into a round-bottomed flask containing 500 ml of tetrahydrofuran, and the temperature was adjusted to about −78° C. After 30 minutes, 146 ml (233 mmol) of normal butyllithium was slowly dropwise added thereto. After 1 hour, 28.3 g (274 mmol) of trimethyl borate was slowly dropwise added thereto, followed by increasing the temperature to room temperature. After the reaction solution was stirred at room temperature for about 12 hours, 2N hydrochloric acid (HCl) solution was dropwise added to the reaction solution until the reaction solution reached an acidic pH, followed by extracting an organic phase and the solvent was removed in a reduced pressure. The residue was recrystallized using n-hexane, filtered, and then dried to obtain 35 g of intermediate 57-a in white solid form with a yield of about 81%.

### Synthesis Example 6

### Synthesis of Intermediate 57-b

Intermediate 57-b was synthesized according to Reaction Scheme 6-2 below:

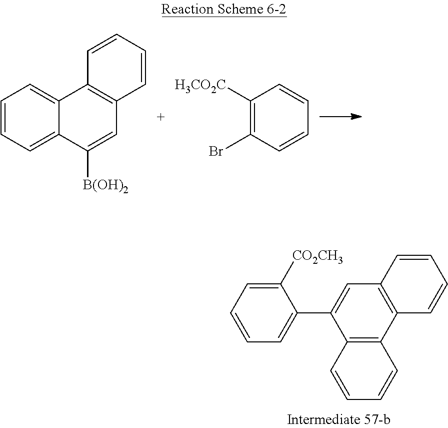 [SMILES: OB(O)c1cc2ccccc2c2ccccc12 ; COC(=O)c1ccccc1Br ; COC(=O)c1ccccc1-c1cc2ccccc2c2ccccc12]

24 g (112 mmol) of methyl 2-bromobenzoate, 34.7 g (0.156 mmol) of Intermediate 57-a, 2.6 g (2 mmol) of tetrakis(triphenylphospine)palladium (Pd(PPh₃)₄) (30.9 g, 223 mmol) of potassium carbonate, 50 mL of water, 125 ml of toluene, and 125 mL of tetrahydrofuran were put into a round-bottomed flask, and were then refluxed for about 12 hours. After termination of the reaction, an organic phase was extracted from the reaction product, concentrated in a reduced pressure, refined by column chromatography, and then dried to obtain 25 g of Intermediate 57-b in white solid form with a yield of about 72%.

### Synthesis Example 6

### Synthesis of Intermediate 57-c

Intermediate 57-c was synthesized according to Reaction Scheme 6-3 below:

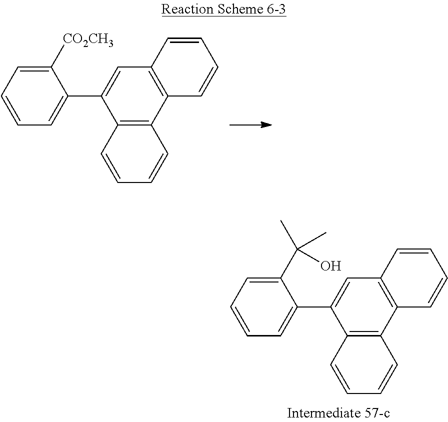 [SMILES: COC(=O)c1ccccc1-c1cc2ccccc2c2ccccc12 ; CC(C)(O)c1ccccc1-c1cc2ccccc2c2ccccc12]

25 g (80 mmol) of Intermediate 57-b was put into a round-bottomed flask containing 250 ml of tetrahydrofuran, and the temperature was reduced to about −78° C. in a nitrogen atmosphere. After 30 minutes, 210 ml (240 mmol) of 1.0M methyl magnesium bromide was slowly dropwise added. After 1 hour, the temperature was increased to room temperature. After the reaction solution was stirred at room temperature for about 2 hours, an aqueous ammonium chloride solution was dropwise added to the reaction solution, followed by extracting an organic phase and the solvent was removed in a reduced pressure. The residue was recrystallized using n-hexane, filtered, and then dried to obtain 27 g of intermediate 57-c in white solid form with a yield of about 82%.

### Synthesis Example 6-4

### Synthesis of Intermediate 57-d

Intermediate 57-d was synthesized according to Reaction Scheme 6-4 below:

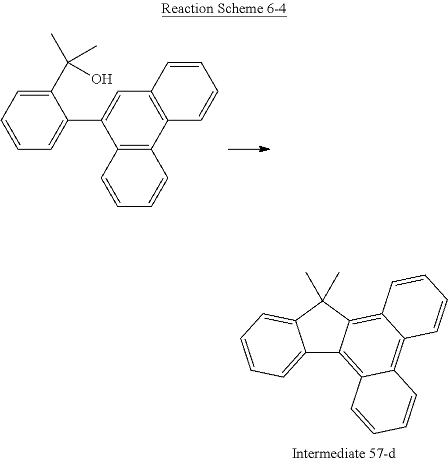

28 g (66 mmol) of Intermediate 57-c was put into a round-bottomed flask containing 290 ml of acetic acid, and the temperature was increased to about 80° C., followed by adding one to two droplets of an aqueous HCl solution, a reflux for about 2 hours, and temperature adjustment to room temperature. A resulting solid product was filtered and then dried to obtain 26 g of Intermediate 57-d in white solid form with a yield of about 93%.

### Synthesis Example 6-5

### Synthesis of Intermediate 57-e

Intermediate 57-e was synthesized according to Reaction Scheme 6-5 below:

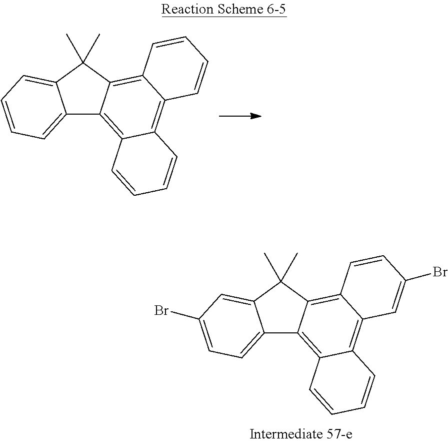

26 g (65 mmol) of Intermediate 57-d was put into a round-bottomed flask containing 216 ml of chloroform, and was then stirred. A dilution of 28.9 g (181 mmol) of bromine with 54 ml of chloroform was slowly dropwise added thereto, followed by stirring at room temperature for about 48 hours. A resulting solid product was filtered and then dried to obtain 26 g of Intermediate 57-e in white solid form with a yield of about 93%.

### Synthesis Example 6-6

### Synthesis of Compound 57

Compound 57 was synthesized according to Reaction Scheme 6-6 below:

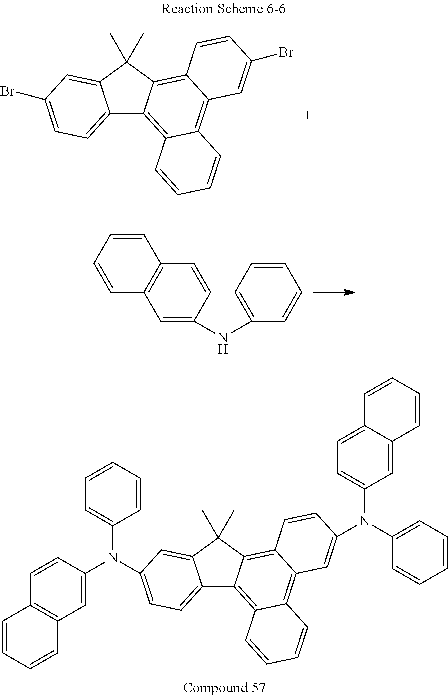 [SMILES: CC1(C)c2cc(Br)ccc2-c2c1c1ccc(Br)cc1c1ccccc21 ; c1ccc(Nc2ccc3ccccc3c2)cc1 ; CC1(C)c2cc(N(c3ccccc3)c3ccc4ccccc4c3)ccc2-c2c1c1ccc(N(c3ccccc3)c3ccc4ccccc4c3)cc1c1ccccc21]

9 g (17 mmol) of Intermediate 57-e, 8.4 g (45 mmol) of 2-naphthyl-phenylamine, 0.2 g (0.7 mmol) of palladium acetate (Pd(OAc)₂), (6.7 g, 69 mmol) of sodium tert-butoxide, 0.14 g (0.7 mmol) of tri-tert-butylphosphine, and 100 ml of toluene were put into a round-bottomed flask, and then reacted at a temperature of about 100° C. for about 2 hours. After termination of the reaction, the reaction product was filtered, followed by concentrating the filtrate, which was then refined using column chromatography. After recrystallization with toluene and methanol, the resulting solid was filtrated and then dried to obtain 5.2 g of Compound 57 in light-yellow solid form with a yield of about 40%. MS: m/z 729 [M]⁺.

### Synthesis Example 7

### Synthesis of Compound 84

### Synthesis Example 7-1

### Synthesis of Intermediate 84-a

Intermediate 84-a was synthesized according to Reaction Scheme 7-1 below:

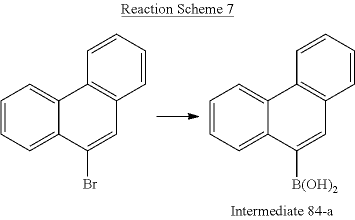 [SMILES: Brc1cc2ccccc2c2ccccc12 ; OB(O)c1cc2ccccc2c2ccccc12]

50 g (194 mmol) of 9-bromophenanthren was put into a round-bottomed flask containing 500 ml of tetrahydrofuran, and the temperature was adjusted to about −78° C. After 30 minutes, 146 ml (233 mmol) of n-butyl lithium was slowly dropwise added thereto. After 1 hour, 28.3 g (274 mmol) of trimethyl borate was slowly dropwise added thereto, followed by increasing the temperature to room temperature. After the reaction solution was stirred at room temperature for about 12 hours, 2N hydrochloric acid (HCl) solution was dropwise added to the reaction solution until the reaction solution reached an acidic pH, followed by extracting an organic phase and the solvent was removed in a reduced pressure. The residue was recrystallized using n-hexane, filtered, and then dried to obtain 35 g of intermediate 84-a in white solid form with a yield of about 81%.

### Synthesis Example 7

### Synthesis of Intermediate 84-b

Intermediate 84-b was synthesized according to Reaction Scheme 7-2 below:

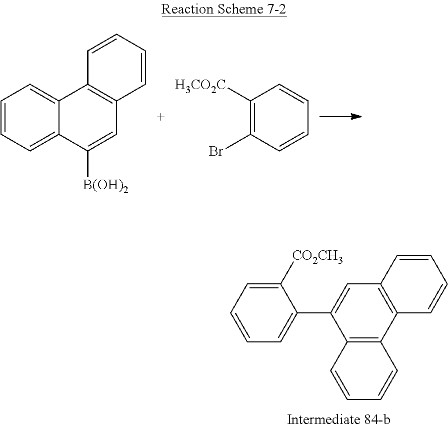 [SMILES: OB(O)c1cc2ccccc2c2ccccc12 ; COC(=O)c1ccccc1Br ; COC(=O)c1ccccc1-c1cc2ccccc2c2ccccc12]

24 g (112 mmol) of methyl 2-bromobenzoate, 34.7 g (0.156 mmol) of Intermediate 84-a, 2.6 g (2 mmol) of tetrakis(triphenylphospine)palladium (Pd(PPh₃)₄) 30.9 g (223 mmol) of potassium carbonate, 50 mL of water, 125 ml of toluene, and 125 mL of tetrahydrofuran were put into a round-bottomed flask, and were then refluxed for about 12 hours. After termination of the reaction, an organic phase was extracted from the reaction product, concentrated in a reduced pressure, refined by column chromatography, and then dried to obtain 25 g of Intermediate 84-b in white solid form with a yield of about 72%.

### Synthesis Example 7

### Synthesis of Intermediate 84-c

Intermediate 84-c was synthesized according to Reaction Scheme 7-3 below:

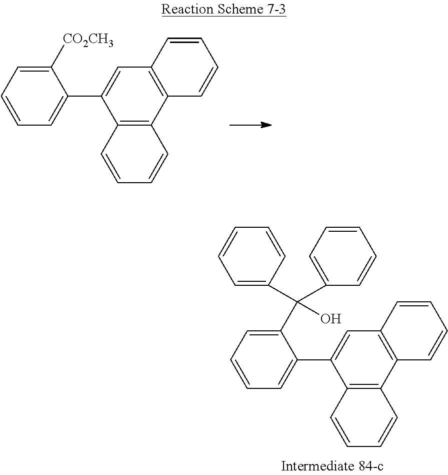 [SMILES: COC(=O)c1ccccc1-c1cc2ccccc2c2ccccc12 ; OC(c1ccccc1)(c1ccccc1)c1ccccc1-c1cc2ccccc2c2ccccc12]

25 g (80 mmol) of Intermediate 84-b was put into a round-bottomed flask containing 250 ml of tetrahydrofuran, and the temperature was reduced to about −78° C. in a nitrogen atmosphere. After 30 minutes, 150 ml (240 mmol) of 1.0M phenyl lithium was slowly dropwise added. After 1 hour, the temperature was increased to room temperature. After the reaction solution was stirred at room temperature for about 2 hours, an aqueous ammonium chloride solution was dropwise added to the reaction solution, followed by extracting an organic phase and the solvent was removed in a reduced pressure. The residue was recrystallized using n-hexane, filtered, and then dried to obtain 29 g of intermediate 84-c in white solid form with a yield of about 83%.

### Synthesis Example 7-4

### Synthesis of Intermediate 84-d

Intermediate 84-d was synthesized according to Reaction Scheme 7-4 below:

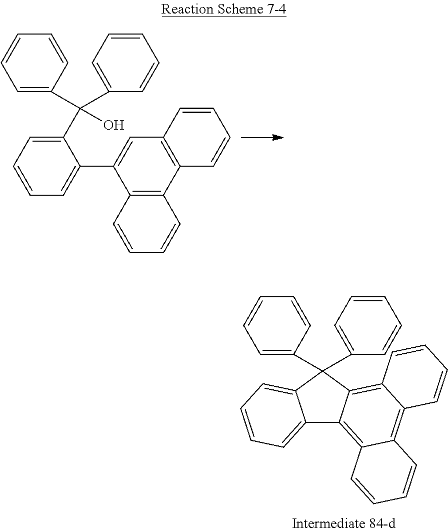

29 g (66 mmol) of Intermediate 84-c was put into a round-bottomed flask containing 290 ml of acetic acid, and the temperature was increased to about 80° C., followed by adding one to two droplets of an aqueous HCl solution, a reflux for about 2 hours, and temperature adjustment to room temperature. A resulting solid product was filtered and then dried to obtain 27 g of Intermediate 84-d in white solid form with a yield of about 93%.

### Synthesis Example 7-5

### Synthesis of Intermediate 84-e

Intermediate 84-e was synthesized according to Reaction Scheme 7-5 below:

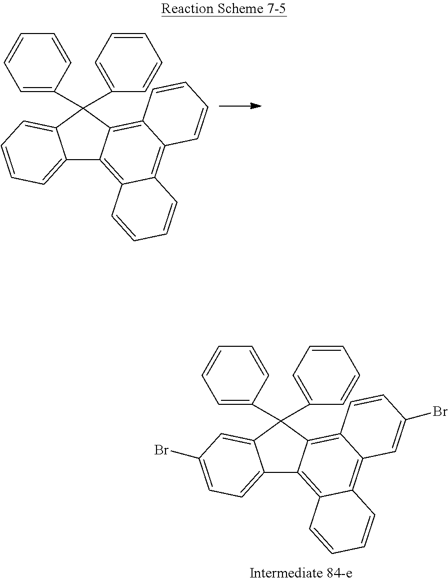

27 g (65 mmol) of Intermediate 84-d was put into a round-bottomed flask containing 216 ml of chloroform, and was then stirred. A dilution of 28.9 g (181 mmol) of bromine with 54 ml of chloroform was slowly dropwise added thereto, followed by stirring at room temperature for about 48 hours. A resulting solid product was filtered and then dried to obtain 27 g of Intermediate 84-e in white solid form with a yield of about 93%.

### Synthesis Example 7-6

### Synthesis of Compound 84

Compound 84 was synthesized according to Reaction Scheme 7-6 below:

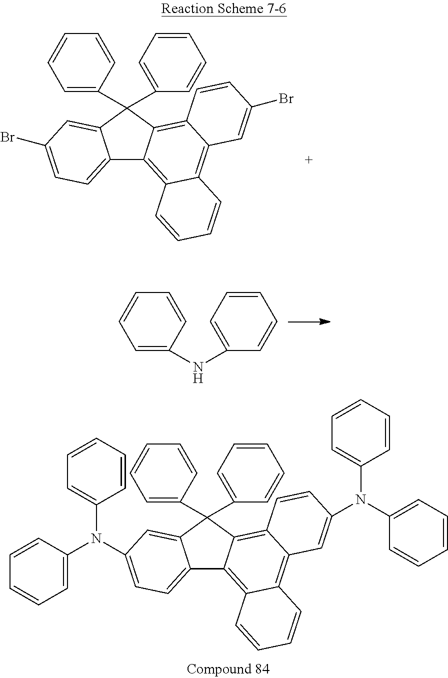 [SMILES: Brc1ccc2c(c1)C(c1ccccc1)(c1ccccc1)c1c-2c2ccccc2c2cc(Br)ccc12 ; c1ccc(Nc2ccccc2)cc1 ; c1ccc(N(c2ccccc2)c2ccc3c(c2)C(c2ccccc2)(c2ccccc2)c2c-3c3ccccc3c3cc(N(c4ccccc4)c4ccccc4)ccc23)cc1]

10 g (17 mmol) of Intermediate 84-e, 7.6 g (45 mmol) of diphenylamine, 0.2 g (0.7 mmol) of palladium acetate (Pd(OAc)₂), 6.7 g (69 mmol) of sodium tert-butoxide, 0.14 g (0.7 mmol) of tri-tert-butylphosphine, and 100 ml of toluene were put into a round-bottomed flask, and then reacted at a temperature of about 100° C. for about 2 hours. After termination of the reaction, the reaction product was filtered, followed by concentrating the filtrate, which was then refined using column chromatography. After recrystallization with toluene and methanol, the resulting solid was filtrated and then dried to obtain 5.7 g of Compound 84 in light-yellow solid form with a yield of about 40%. MS: m/z 752 [M]⁺. ¹H NMR (CDCl₃) δ 8.89 (d, 1H), 8.47 (d, 1H), 8.40 (s, 1H), 8.24 (d, 1H), 7.73 (t, 1H), 7.63 (m, 2H), 7.27 (m, 23H), 7.01 (m, 10H).

### Example 1

To manufacture an anode, a corning 15 Ω/cm² (1200 Δ) ITO glass substrate was cut to a size of 50 mm×50 mm×0.7 mm and then sonicated in isopropyl alcohol and pure water each for five minutes, and then cleaned by irradiation of ultraviolet rays for 30 minutes and exposure to ozone. The resulting glass substrate was loaded into a vacuum deposition device.

Then, 2-TNATA, which is a HIL material, was vacuum-deposited on the glass substrate to form a HIL having a thickness of about 600 Å. Then, 4,4′-bis[N-(1-naphthyl)-N-phenylamino]biphenyl (NPB), which is a hole transporting compound, was vacuum-deposited on the HIL to form a HTL having a thickness of about 300 Å.

Then, the Compound 2 as a blue phosphorescent host and the compound 57 as a blue phosphorescent dopant were simultaneously deposited on the HTL in a weight ratio of 95:5 to form an EML having a thickness of about 40 nm.

Then, Compound 201 was deposited on the EML to form an ETL having a thickness of 300Δ, and then LiF, which is a halogenated alkali metal, was deposited on the ETL to form an EIL having a thickness of 10 Å. Then, Al was vacuum-deposited on the EIL to form a cathode having a thickness of 3000 Å, thereby forming an LiF/Al electrode. As a result, an organic light-emitting device was completely manufactured.

The organic light-emitting device had a driving voltage of 3.9V at a current density of 10 mA/cm², a high luminosity of 412 cd/m², and a luminescent efficiency of 4.12 cd/A.

### Example 2

An organic light-emitting device was manufactured in the same manner as in Example 1, except that Compound 10 instead of Compound 2 was used as the host.

The organic light-emitting device had a driving voltage of 3.5 V at a current density of 10 mA/cm², a high luminosity of 393 cd/m², and a luminescent efficiency of 3.93 cd/A.

### Example 3

An organic light-emitting device was manufactured in the same manner as in Example 1, except that Compound 26 instead of Compound 2 was used as the host.

The organic light-emitting device had a driving voltage of 3.8 V at a current density of 10 mA/cm², a high luminosity of 423 cd/m², and a luminescent efficiency of 4.23 cd/A.

### Example 4

An organic light-emitting device was manufactured in the same manner as in Example 1, except that Compound 34 instead of Compound 2 was used as the host.

The organic light-emitting device had a driving voltage of 3.8 V at a current density of 10 mA/cm², a high luminosity of 382 cd/m², and a luminescent efficiency of 3.82 cd/A.

### Example 5

An organic light-emitting device was manufactured in the same manner as in Example 1, except that Compound 42 instead of Compound 2 was used as the host.

The organic light-emitting device had a driving voltage of 3.9 V at a current density of 10 mA/cm², a high luminosity of 370 cd/m², and a luminescent efficiency of 3.70 cd/A.

### Example 6

An organic light-emitting device was manufactured in the same manner as in Example 1, except that Compound 84 instead of Compound 57 was used as the dopant.

The organic light-emitting device had a driving voltage of 4.1 V at a current density of 10 mA/cm², a high luminosity of 311 cd/m², and a luminescent efficiency of 3.11 cd/A.

### Example 7

An organic light-emitting device was manufactured in the same manner as in Example 1, except that Compound 10 instead of Compound 2 was used as the host, and Compound 84 instead of Compound 57 was used as the dopant.

The organic light-emitting device had a driving voltage of 3.9 V at a current density of 10 mA/cm², a high luminosity of 399 cd/m², and a luminescent efficiency of 3.99 cd/A.

### Example 8

An organic light-emitting device was manufactured in the same manner as in Example 1, except that Compound 26 instead of Compound 2 was used as the host, and Compound 84 instead of Compound 57 was used as the dopant.

The organic light-emitting device had a driving voltage of 3.9 V at a current density of 10 mA/cm², a high luminosity of 378 cd/m², and a luminescent efficiency of 3.78 cd/A.

### Example 9

An organic light-emitting device was manufactured in the same manner as in Example 1, except that Compound 34 instead of Compound 2 was used as the host, and Compound 84 instead of Compound 57 was used as the dopant.

The organic light-emitting device had a driving voltage of 4.1 V at a current density of 10 mA/cm², a high luminosity of 352 cd/m², and a luminescent efficiency of 3.52 cd/A.

### Example 10

An organic light-emitting device was manufactured in the same manner as in Example 1, except that Compound 42 instead of Compound 2 was used as the host, and Compound 84 instead of Compound 57 was used as the dopant.

The organic light-emitting device had a driving voltage of 3.9 V at a current density of 10 mA/cm², a high luminosity of 312 cd/m², and a luminescent efficiency of 3.12 cd/A.

### Comparative Example 1

An organic light-emitting device was manufactured in the same manner as in Example 1, except that Compound 141 instead of Compound 2 was used as the host.

The organic light-emitting device had a driving voltage of 4.4 V at a current density of 10 mA/cm², a high luminosity of 327 cd/m², and a luminescent efficiency of 3.27 cd/A.

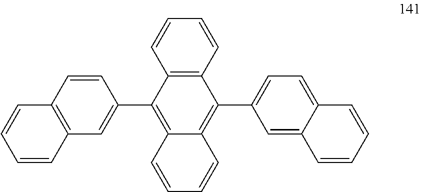 [SMILES: c1ccc2cc(-c3c4ccccc4c(-c4ccc5ccccc5c4)c4ccccc34)ccc2c1]

### Comparative Example 2

An organic light-emitting device was manufactured in the same manner as in Example 6, except that Compound 141 instead of Compound 2 was used as the host.

The organic light-emitting device had a driving voltage of 4.6 V at a current density of 10 mA/cd, a high luminosity of 285 cd/m², and a luminescent efficiency of 2.85 cd/A.

### Comparative Example 3

An organic light-emitting device was manufactured in the same manner as in Example 2, except that Compound 142 instead of Compound 57 was used as the dopant.

The organic light-emitting device had a driving voltage of 4.3 V at a current density of 10 mA/cm², a high luminosity of 348 cd/m², and a luminescent efficiency of 3.48 cd/A.

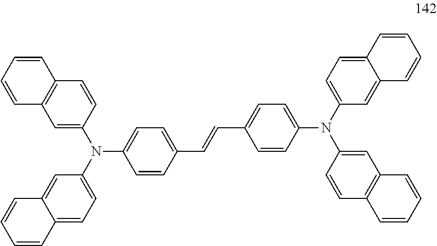 [SMILES: C(=C\c1ccc(N(c2ccc3ccccc3c2)c2ccc3ccccc3c2)cc1)/c1ccc(N(c2ccc3ccccc3c2)c2ccc3ccccc3c2)cc1]

### Comparative Example 4

An organic light-emitting device was manufactured in the same manner as in Example 2, except that Compound 143 instead of Compound 57 was used as the dopant.

The organic light-emitting device had a driving voltage of 4.2 V at a current density of 10 mA/cm², a high luminosity of 359 cd/m², and a luminescent efficiency of 3.59 cd/A.

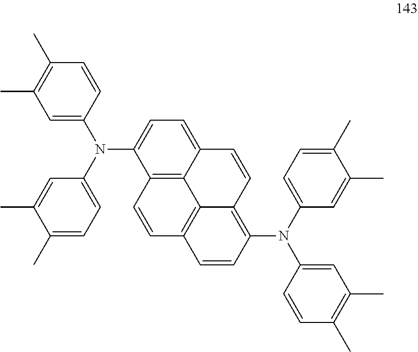

The characteristics ad lifetimes of the organic light-emitting devices of Examples 1-10 and Comparative Examples 1-4 are shown in Table 1 below.

TABLE 1

| Organic light-emitting | Driving | Current | | Luminescent | | |
|---|---|---|---|---|---|---|
| device | voltage | density | Luminance | efficiency | | |
| (Compound No.) | (V) | [mA/cm2] | (cd/m²) | (cd/A) | CIE x | CIE y |
| Example 1 (2, 57) | 3.9 | 10 | 412 | 4.12 | 0.139 | 0.047 |
| Example 2 (10, 57) | 3.5 | 10 | 393 | 3.93 | 0.140 | 0.046 |
| Example 3 (26, 57) | 3.8 | 10 | 423 | 4.23 | 0.137 | 0.051 |
| Example 4 (34, 57) | 3.8 | 10 | 382 | 3.82 | 0.140 | 0.045 |
| Example 5 (42, 57) | 3.9 | 10 | 370 | 3.70 | 0.142 | 0.042 |
| Example 6 (2, 84) | 4.1 | 10 | 311 | 3.11 | 0.149 | 0.036 |
| Example 7 (10, 57) | 3.9 | 10 | 399 | 3.99 | 0.144 | 0.047 |
| Example 8 (26, 84) | 3.9 | 10 | 378 | 3.78 | 0.142 | 0.045 |
| Example 9 (34, 84) | 4.1 | 10 | 352 | 3.52 | 0.145 | 0.040 |
| Example 10 (42,84) | 3.9 | 10 | 312 | 3.12 | 0.147 | 0.037 |
| Comparative Example 1 | 4.4 | 10 | 327 | 3.27 | 0.138 | 0.047 |
| Comparative Example 2 | 4.6 | 10 | 285 | 2.85 | 0.141 | 0.043 |
| Comparative Example 3 | 4.3 | 10 | 348 | 3.48 | 0.136 | 0.057 |
| Comparative Example 4 | 4.2 | 10 | 359 | 3.59 | 0.145 | 0.060 |

In the organic light-emitting devices manufactured using the compounds of Formulae 1 and 2 are blue light-emitting materials, the driving voltage was lower, and the efficiency, I-V-L characteristics and lifetime improvement were better, as compared to when the known compounds 141, 142 and 143 were used.

An organic light-emitting device including the compound of Formula 1 and Formula 2 may have high color purity, high efficiency, and relatively long lifetime.

While the present embodiments has been particularly shown and described with reference to exemplary embodiments thereof, it will be understood by those of ordinary skill in the art that various changes in form and details may be made therein without departing from the spirit and scope of the present embodiments as defined by the following claims.

What is claimed is:

1. An organic light-emitting device comprising:
a first electrode;
a second electrode; and
an organic layer disposed between the first electrode and the second electrode,
wherein the organic layer comprises a compound represented by Formula 1 below and a compound represented by Formula 2: 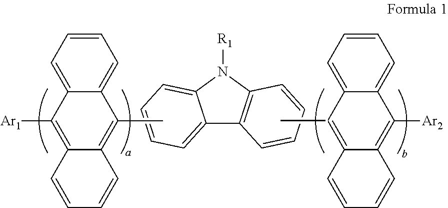
wherein, in Formula 1,
R₁ is a hydrogen atom, a deuterium atom, a substituted or unsubstituted C₁-C₆₀ alkyl group, a substituted unsubstituted C₂-C₆₀ alkenyl group, a substituted unsubstituted C₂-C₆₀ alkynyl group, a substituted or unsubstituted C₆-C₆₀ aryl group, a substituted or unsubstituted C₃-C₆₀ heteroaryl group, a substituted or unsubstituted C₁-C₆₀ alkoxy group, a substituted or unsubstituted C₆-C₆₀ aralkyl group, a substituted or unsubstituted C₆-C₆₀ aryloxy group, a substituted or unsubstituted C₆-C₆₀ arylthio group, a substituted or unsubstituted C₁-C₆₀ alkoxycarbonyl group, a carboxyl group, a halogen group, a cyano group, a nitro group, or a hydroxyl group;
Ar₁ and Ar₂ are each independently a hydrogen atom, a deuterium atom, a substituted or unsubstituted C₆-C₆₀ aryl group, or a substituted or unsubstituted C₃-C₆₀ heteroaryl group;
a is an integer of 1 or 2; and
b is an integer from 0 to 2, 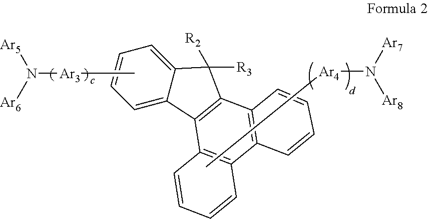
wherein, in Formula 2,
R₂ to R₃ are each independently a hydrogen atom, a deuterium atom, a substituted or unsubstituted C₁-C₆₀ alkyl group, a substituted or unsubstituted C₃-C₆₀ cycloalkyl group, a substituted or unsubstituted C₁-C₂₀ alkoxy group, or a substituted or unsubstituted C₆-C₁₂ aryl group, and R₂ and R₃ are optionally linked to form a ring;
Ar₃ and Ar₄ are each independently a substituted or unsubstituted C₆-C₅₀ arylene group;
Ar₅ and Ar₈ are each independently a substituted or unsubstituted C₆-C₆₀ aryl group, or a substituted or unsubstituted C₃-C₆₀ heteroaryl group; and
c and d are each independently an integer of 0 or 1.

2. The organic light-emitting device of claim 1, wherein the compound of Formula 1 is a compound represented by Formula 3 below:

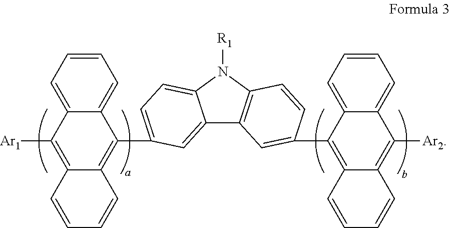

3. The organic light-emitting device of claim 1, wherein the compound of Formula 2 is a compound represented by Formula 4 below:

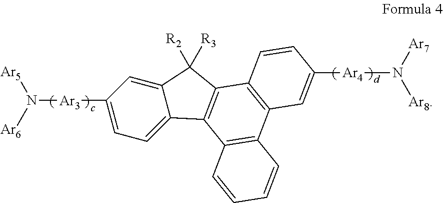

4. The organic light-emitting device of claim 1, wherein R₂ and R₃ in Formula 2 are linked to form a ring.

5. The organic light-emitting device of claim 1, wherein R₁ in Formula 1 is a substituted or unsubstituted C₁-C₆₀ alkyl group, a substituted or unsubstituted C₆-C₆₀ aryl group, or a substituted or unsubstituted C₃-C₆₀ heteroaryl group.

6. The organic light-emitting device of claim 1, wherein Ar₁ and Ar₂ in Formula 1 are each independently a hydrogen atom, a deuterium atom, a substituted or unsubstituted C₆-C₆₀ aryl group, or a substituted or unsubstituted C₃-C₆₀ heteroaryl group.

7. The organic light-emitting device of claim 1, wherein R₁ in Formula 1 is a substituted or unsubstituted ethenyl group, a substituted or unsubstituted phenyl group, a substituted or unsubstituted naphthyl group, a substituted or unsubstituted pyridyl group, or a substituted or unsubstituted quinoline group.

8. The organic light-emitting device of claim 1, wherein Ar₁ and Ar₂ in Formula 1 are each independently a substituted or unsubstituted phenyl group, a substituted or unsubstituted naphthyl group, a substituted or unsubstituted pyridyl group, or a substituted or unsubstituted quinoline group.

9. The organic light-emitting device of claim 1, wherein R₂ and R₃ in Formula 2 are each independently a methyl group or a phenyl group.

10. The organic light-emitting device of claim 1, wherein Ar₃ and Ar₄ in Formula 2 are each independently one of the groups represented by Formulae 5 to 9 below: 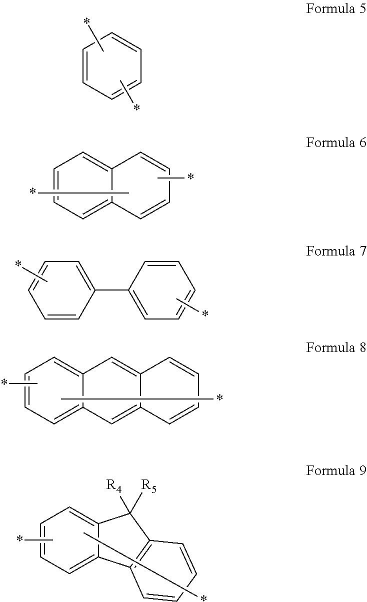
wherein, in Formula 9, R₄ and R₅ are each independently a hydrogen atom, a deuterium atom, a substituted or unsubstituted C₁-C₂₀ alkyl group, a substituted or unsubstituted C₆-C₂₀ cycloalkyl group, a substituted or unsubstituted C₁-C₂₀ alkoxy group, or a substituted or unsubstituted C₆-C₁₂ aryl group; and R₄ and R₅ are optionally linked to form a ring; and
at least one hydrogen atom in Formulae 5 to 9 is optionally replaced with a deuterium atom, a halogen atom, a hydroxyl group, a nitro group, a cyano group, an amino group, an amidino group, hydrazine, hydrazone, a carboxyl group or a salt thereof, a sulfonic acid group or a salt thereof, a phosphoric acid or a salt thereof, a C₁-C₁₀ alkyl group, a C₁-C₁₀ alkoxy group, a C₂-C₁₀ alkenyl group, a C₂-C₁₀ alkynyl group, a C₆-C₁₆ aryl group, or a C₄-C₁₆ heteroaryl group, wherein * indicates the respective attachment point to the parent molecule.

11. The organic light-emitting device of claim 1, wherein Ar₅ to Ar₈ in Formula 2 are each independently one of the groups represented by Formulae 10 to 19 below: 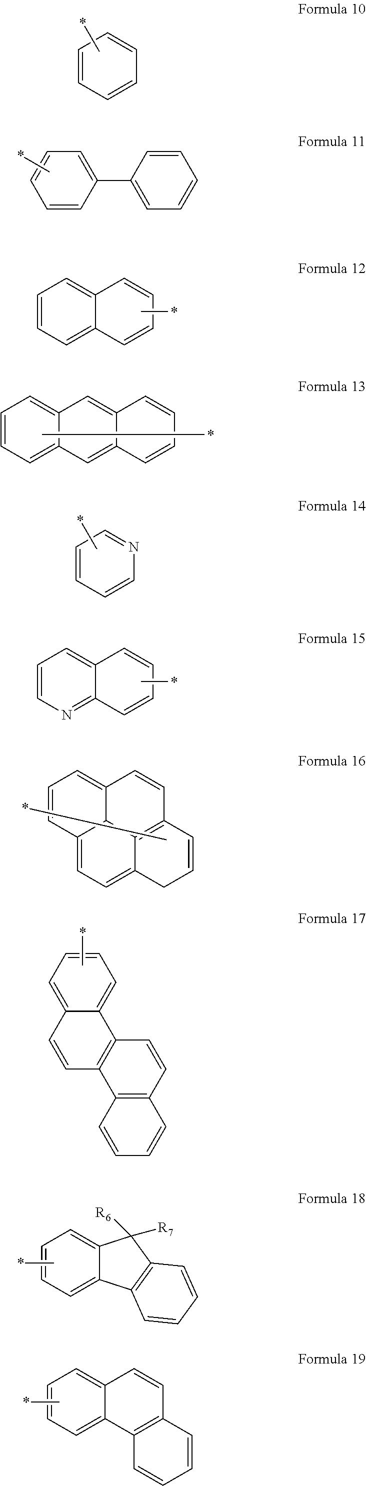
wherein, in Formula 18, R₆ and R₇ are each independently a hydrogen atom, a deuterium atom, a substituted or unsubstituted C₁-C₂₀ alkyl group, a substituted or unsubstituted C₆-C₂₀ cycloalkyl group, a substituted or unsubstituted C₁-C₂₀ alkoxy group, or a substituted or unsubstituted C₆-C₁₂ aryl group; and R₆ and R₇ are optionally linked to form a ring; and
at least one hydrogen atom in Formulae 10 to 19 is optionally replaced with a deuterium atom, a halogen atom, a hydroxyl group, a nitro group, a cyano group, an amino group, an amidino group, hydrazine, hydrazone, a carboxyl group or a salt thereof, a sulfonic acid group or a salt thereof, a phosphoric acid or a salt thereof, a C₁-C₁₀ alkyl group, a C₁-C₁₀ alkoxy group, a C₂-C₁₀ alkenyl group, a C₂-C₁₀ alkynyl group, a C₆-C₁₆ aryl group, or a C₄-C₁₆ heteroaryl group, wherein * indicates the respective attachment point to the parent molecule.

12. The organic light-emitting device of claim 1, wherein the compound of Formula 1 is one of the compounds below:

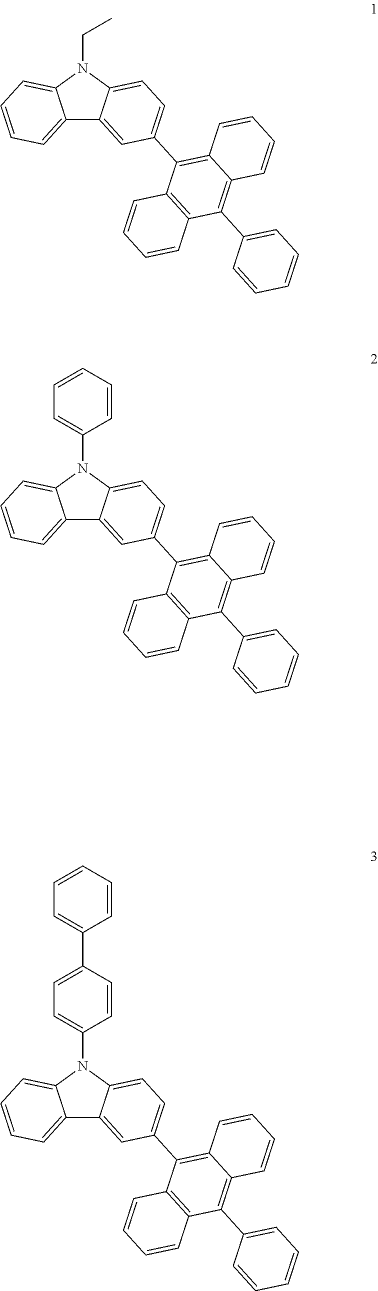 [SMILES: CCn1c2ccccc2c2cc(-c3c4ccccc4c(-c4ccccc4)c4ccccc34)ccc21 ; c1ccc(-c2c3ccccc3c(-c3ccc4c(c3)c3ccccc3n4-c3ccccc3)c3ccccc23)cc1 ; c1ccc(-c2ccc(-n3c4ccccc4c4cc(-c5c6ccccc6c(-c6ccccc6)c6ccccc56)ccc43)cc2)cc1]

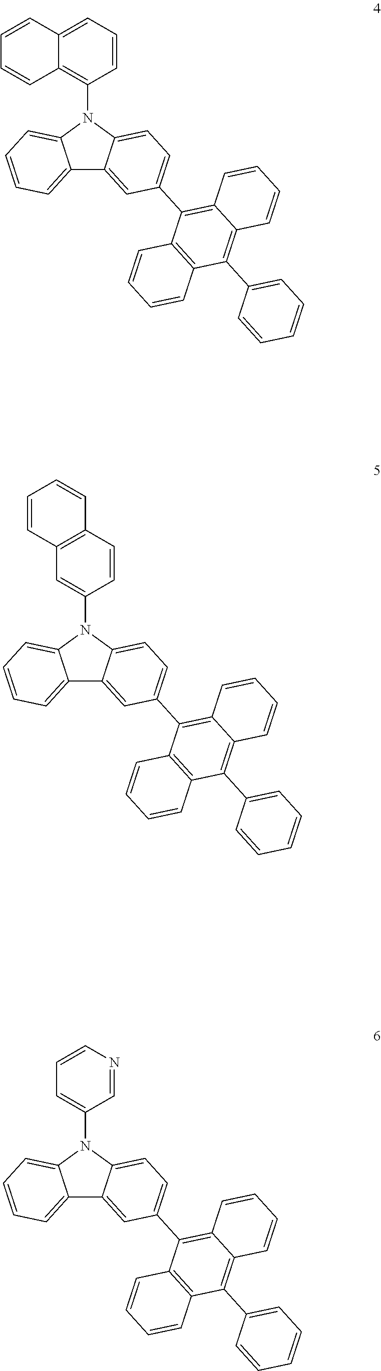 [SMILES: c1ccc(-c2c3ccccc3c(-c3ccc4c(c3)c3ccccc3n4-c3cccc4ccccc34)c3ccccc23)cc1 ; c1ccc(-c2c3ccccc3c(-c3ccc4c(c3)c3ccccc3n4-c3ccc4ccccc4c3)c3ccccc23)cc1 ; c1ccc(-c2c3ccccc3c(-c3ccc4c(c3)c3ccccc3n4-c3cccnc3)c3ccccc23)cc1]

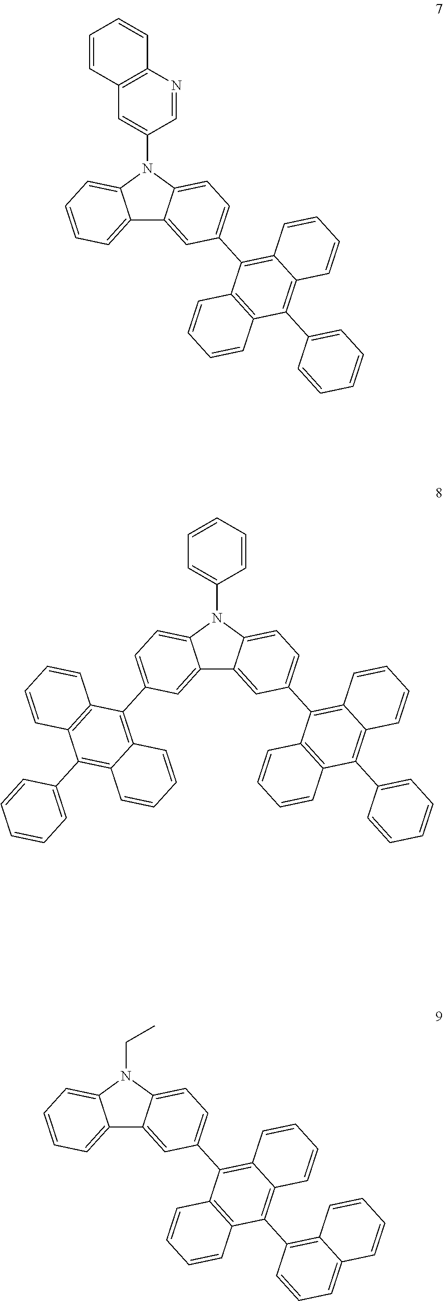 [SMILES: c1ccc(-c2c3ccccc3c(-c3ccc4c(c3)c3ccccc3n4-c3cnc4ccccc4c3)c3ccccc23)cc1 ; c1ccc(-c2c3ccccc3c(-c3ccc4c(c3)c3cc(-c5c6ccccc6c(-c6ccccc6)c6ccccc56)ccc3n4-c3ccccc3)c3ccccc23)cc1 ; CCn1c2ccccc2c2cc(-c3c4ccccc4c(-c4cccc5ccccc45)c4ccccc34)ccc21]

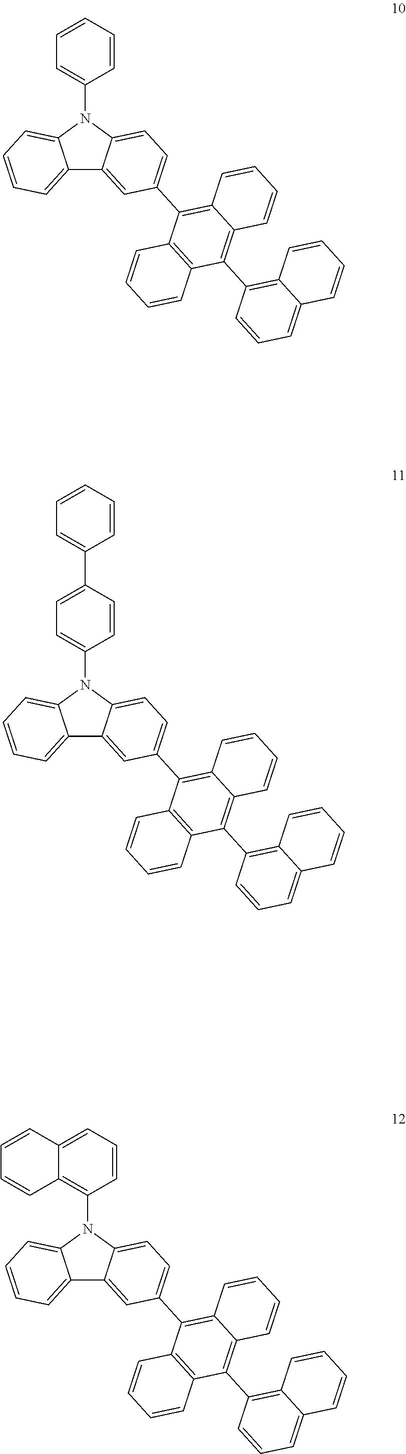 [SMILES: c1ccc(-n2c3ccccc3c3cc(-c4c5ccccc5c(-c5cccc6ccccc56)c5ccccc45)ccc32)cc1 ; c1ccc(-c2ccc(-n3c4ccccc4c4cc(-c5c6ccccc6c(-c6cccc7ccccc67)c6ccccc56)ccc43)cc2)cc1 ; c1ccc2c(-c3c4ccccc4c(-c4ccc5c(c4)c4ccccc4n5-c4cccc5ccccc45)c4ccccc34)cccc2c1]

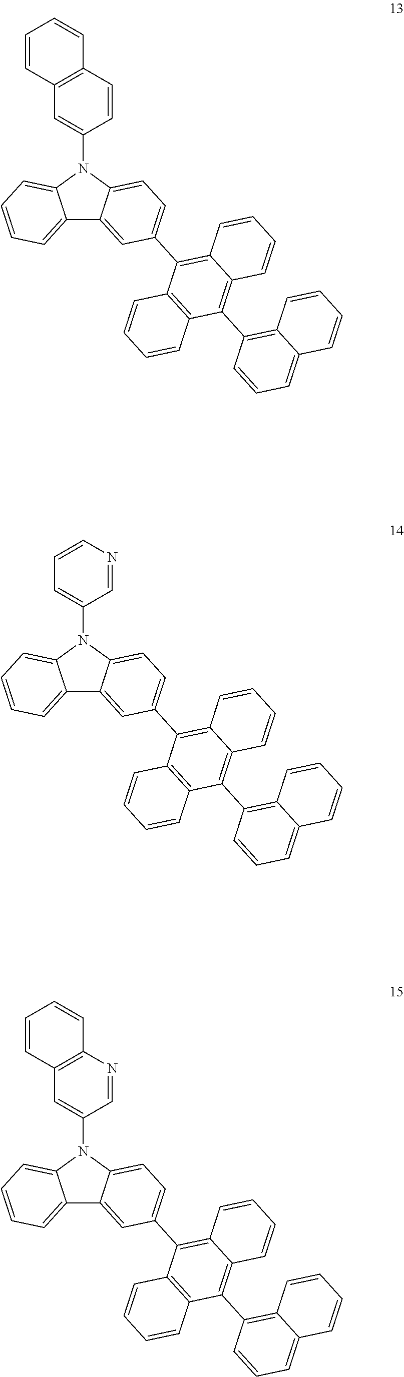 [SMILES: c1ccc2cc(-n3c4ccccc4c4cc(-c5c6ccccc6c(-c6cccc7ccccc67)c6ccccc56)ccc43)ccc2c1 ; c1cncc(-n2c3ccccc3c3cc(-c4c5ccccc5c(-c5cccc6ccccc56)c5ccccc45)ccc32)c1 ; c1ccc2ncc(-n3c4ccccc4c4cc(-c5c6ccccc6c(-c6cccc7ccccc67)c6ccccc56)ccc43)cc2c1]

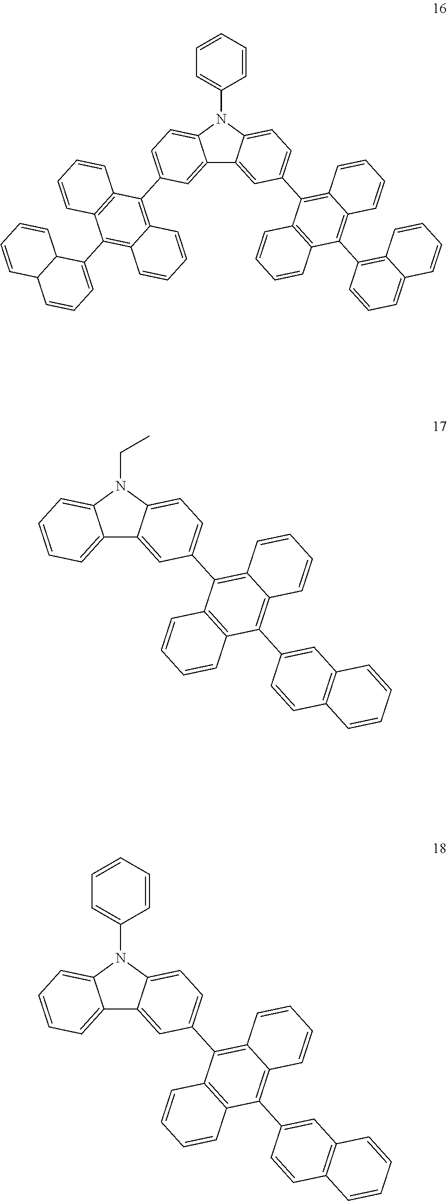 [SMILES: C1=CC2C=CC=C(c3c4ccccc4c(-c4ccc5c(c4)c4cc(-c6c7ccccc7c(-c7cccc8ccccc78)c7ccccc67)ccc4n5-c4ccccc4)c4ccccc34)C2C=C1 ; CCn1c2ccccc2c2cc(-c3c4ccccc4c(-c4ccc5ccccc5c4)c4ccccc34)ccc21 ; c1ccc(-n2c3ccccc3c3cc(-c4c5ccccc5c(-c5ccc6ccccc6c5)c5ccccc45)ccc32)cc1]

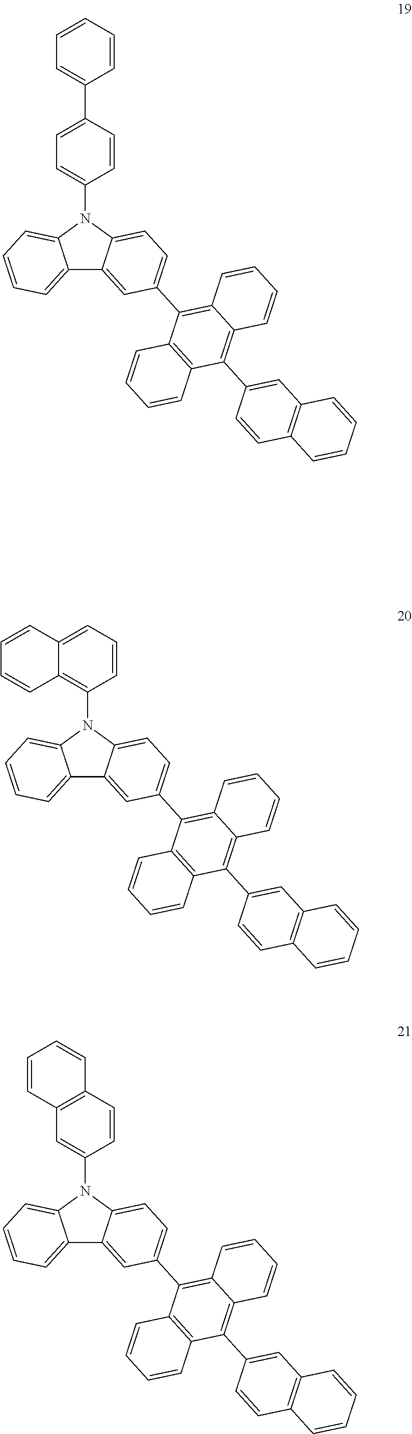 [SMILES: c1ccc(-c2ccc(-n3c4ccccc4c4cc(-c5c6ccccc6c(-c6ccc7ccccc7c6)c6ccccc56)ccc43)cc2)cc1 ; c1ccc2cc(-c3c4ccccc4c(-c4ccc5c(c4)c4ccccc4n5-c4cccc5ccccc45)c4ccccc34)ccc2c1 ; c1ccc2cc(-c3c4ccccc4c(-c4ccc5c(c4)c4ccccc4n5-c4ccc5ccccc5c4)c4ccccc34)ccc2c1]

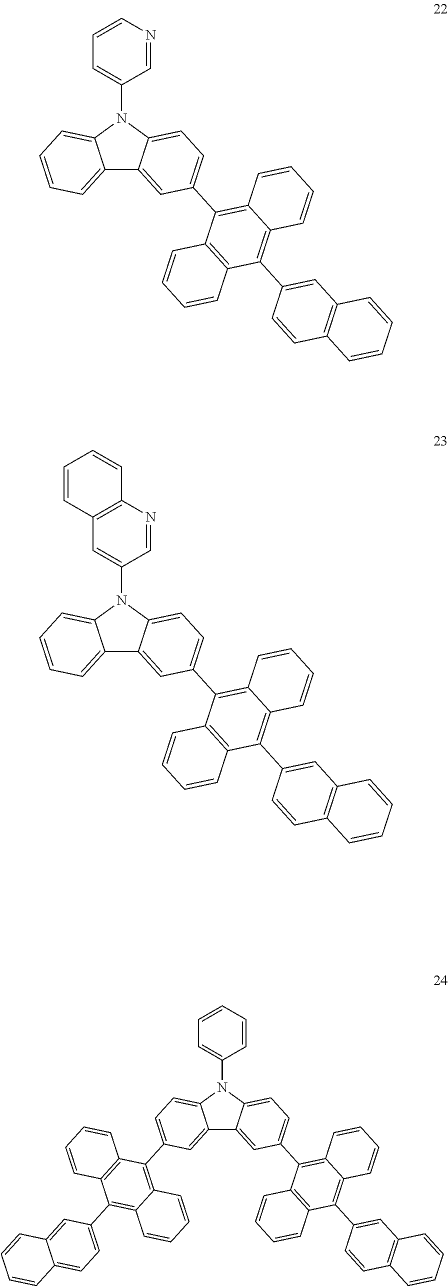 [SMILES: c1cncc(-n2c3ccccc3c3cc(-c4c5ccccc5c(-c5ccc6ccccc6c5)c5ccccc45)ccc32)c1 ; c1ccc2cc(-c3c4ccccc4c(-c4ccc5c(c4)c4ccccc4n5-c4cnc5ccccc5c4)c4ccccc34)ccc2c1 ; c1ccc(-n2c3ccc(-c4c5ccccc5c(-c5ccc6ccccc6c5)c5ccccc45)cc3c3cc(-c4c5ccccc5c(-c5ccc6ccccc6c5)c5ccccc45)ccc32)cc1]

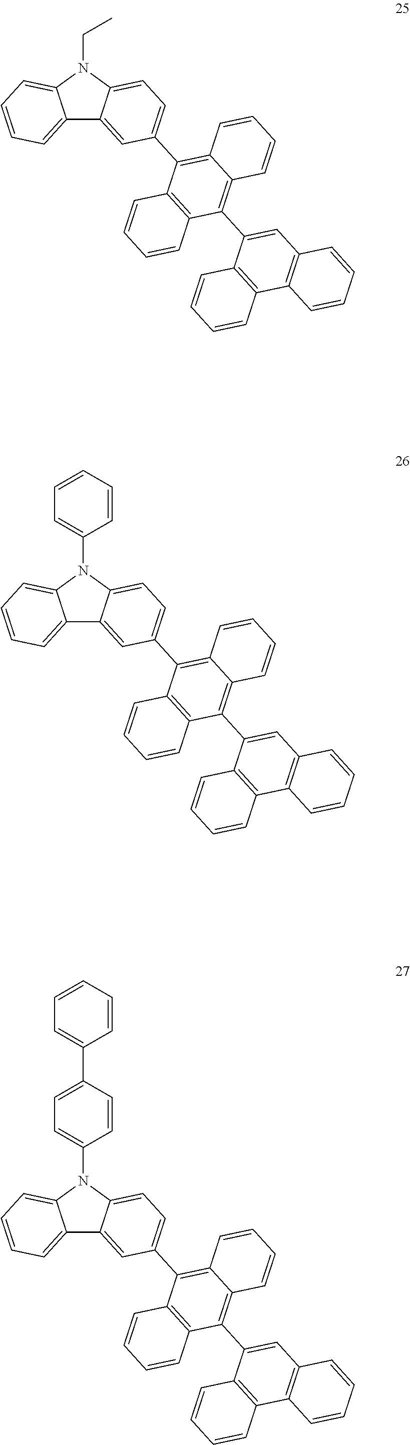 [SMILES: CCn1c2ccccc2c2cc(-c3c4ccccc4c(-c4cc5ccccc5c5ccccc45)c4ccccc34)ccc21 ; c1ccc(-n2c3ccccc3c3cc(-c4c5ccccc5c(-c5cc6ccccc6c6ccccc56)c5ccccc45)ccc32)cc1 ; c1ccc(-c2ccc(-n3c4ccccc4c4cc(-c5c6ccccc6c(-c6cc7ccccc7c7ccccc67)c6ccccc56)ccc43)cc2)cc1]

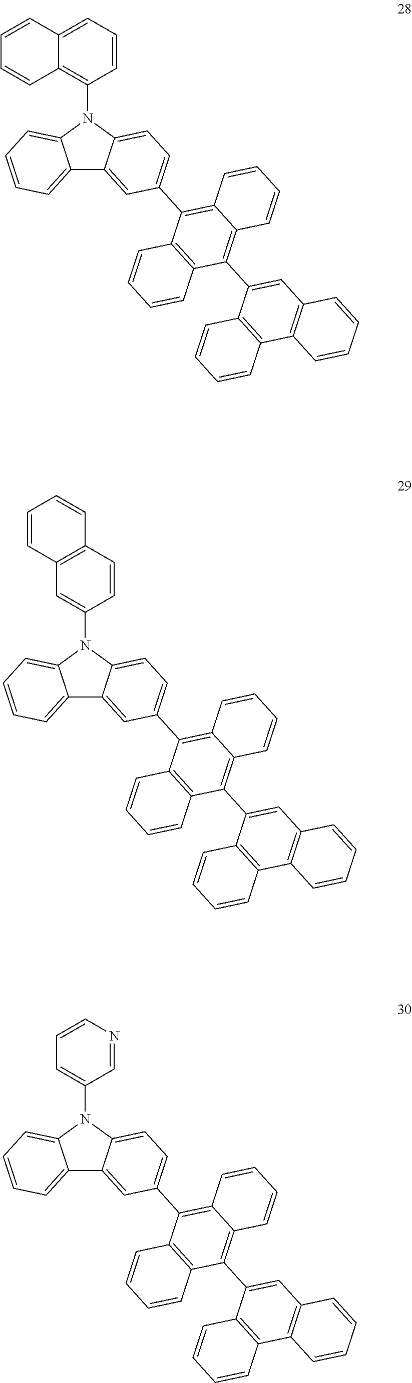 [SMILES: c1ccc2c(-n3c4ccccc4c4cc(-c5c6ccccc6c(-c6cc7ccccc7c7ccccc67)c6ccccc56)ccc43)cccc2c1 ; c1ccc2cc(-n3c4ccccc4c4cc(-c5c6ccccc6c(-c6cc7ccccc7c7ccccc67)c6ccccc56)ccc43)ccc2c1 ; c1cncc(-n2c3ccccc3c3cc(-c4c5ccccc5c(-c5cc6ccccc6c6ccccc56)c5ccccc45)ccc32)c1]

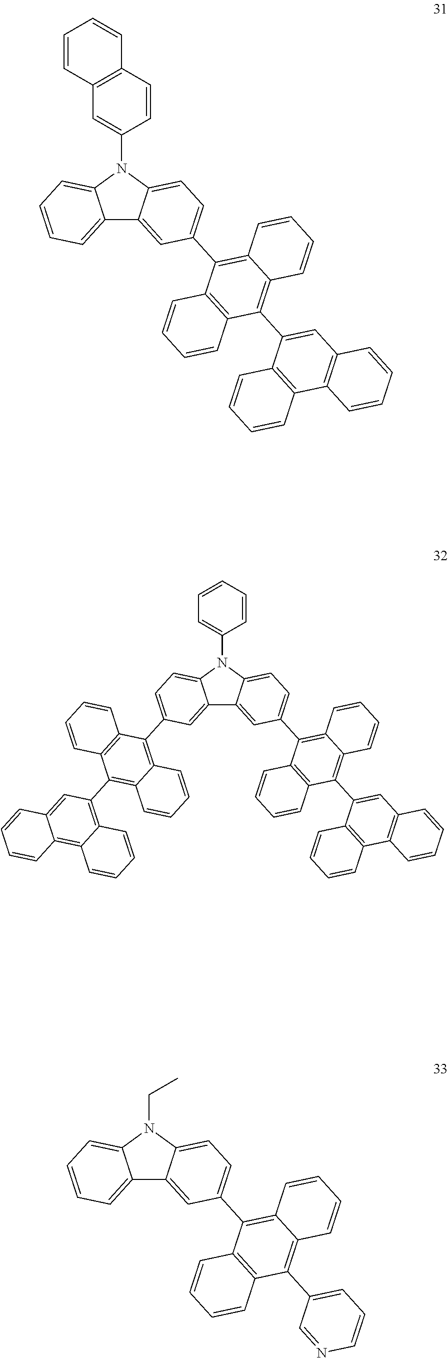 [SMILES: c1ccc2cc(-n3c4ccccc4c4cc(-c5c6ccccc6c(-c6cc7ccccc7c7ccccc67)c6ccccc56)ccc43)ccc2c1 ; c1ccc(-n2c3ccc(-c4c5ccccc5c(-c5cc6ccccc6c6ccccc56)c5ccccc45)cc3c3cc(-c4c5ccccc5c(-c5cc6ccccc6c6ccccc56)c5ccccc45)ccc32)cc1 ; CCn1c2ccccc2c2cc(-c3c4ccccc4c(-c4cccnc4)c4ccccc34)ccc21]

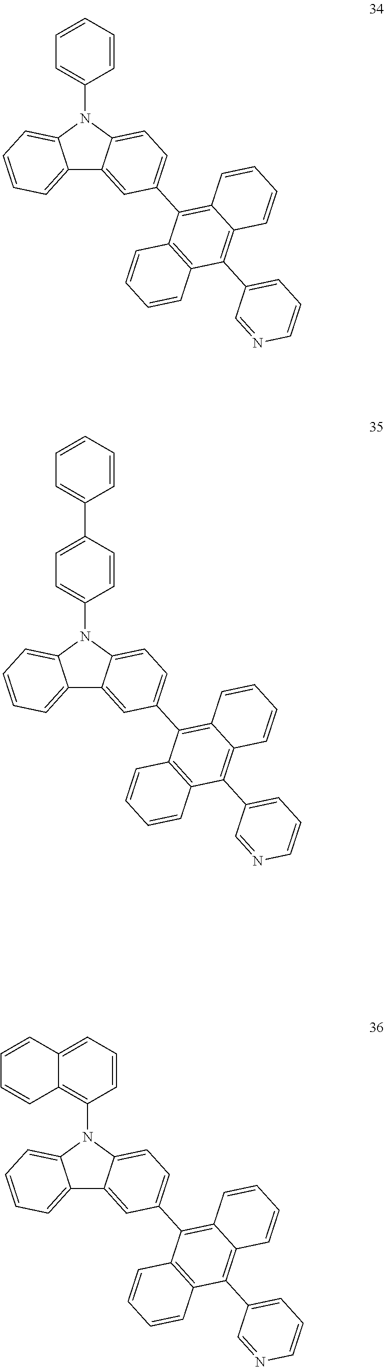 [SMILES: c1ccc(-n2c3ccccc3c3cc(-c4c5ccccc5c(-c5cccnc5)c5ccccc45)ccc32)cc1 ; c1ccc(-c2ccc(-n3c4ccccc4c4cc(-c5c6ccccc6c(-c6cccnc6)c6ccccc56)ccc43)cc2)cc1 ; c1cncc(-c2c3ccccc3c(-c3ccc4c(c3)c3ccccc3n4-c3cccc4ccccc34)c3ccccc23)c1]

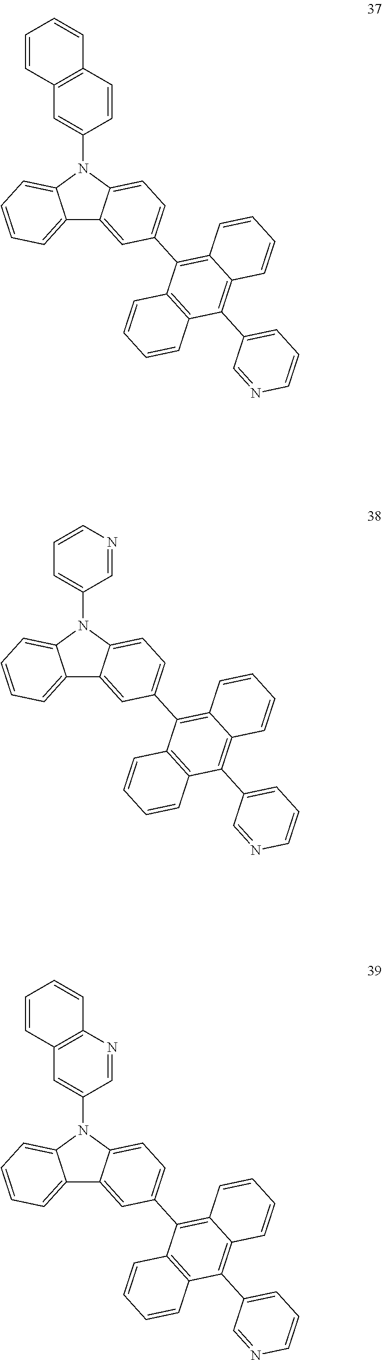 [SMILES: c1cncc(-c2c3ccccc3c(-c3ccc4c(c3)c3ccccc3n4-c3ccc4ccccc4c3)c3ccccc23)c1 ; c1cncc(-c2c3ccccc3c(-c3ccc4c(c3)c3ccccc3n4-c3cccnc3)c3ccccc23)c1 ; c1cncc(-c2c3ccccc3c(-c3ccc4c(c3)c3ccccc3n4-c3cnc4ccccc4c3)c3ccccc23)c1]

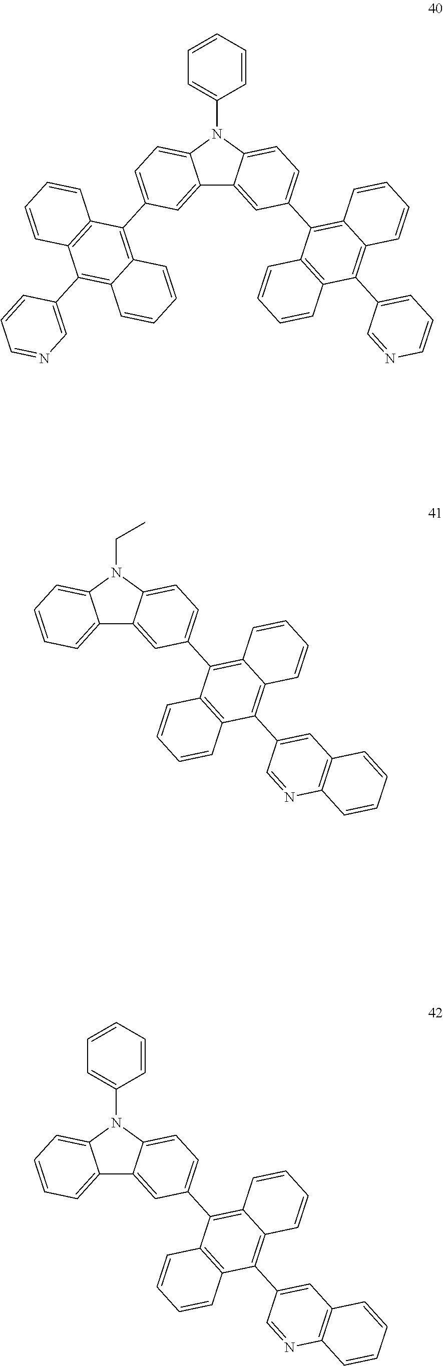 [SMILES: c1ccc(-n2c3ccc(-c4c5ccccc5c(-c5cccnc5)c5ccccc45)cc3c3cc(-c4c5ccccc5c(-c5cccnc5)c5ccccc45)ccc32)cc1 ; CCn1c2ccccc2c2cc(-c3c4ccccc4c(-c4cnc5ccccc5c4)c4ccccc34)ccc21 ; c1ccc(-n2c3ccccc3c3cc(-c4c5ccccc5c(-c5cnc6ccccc6c5)c5ccccc45)ccc32)cc1]

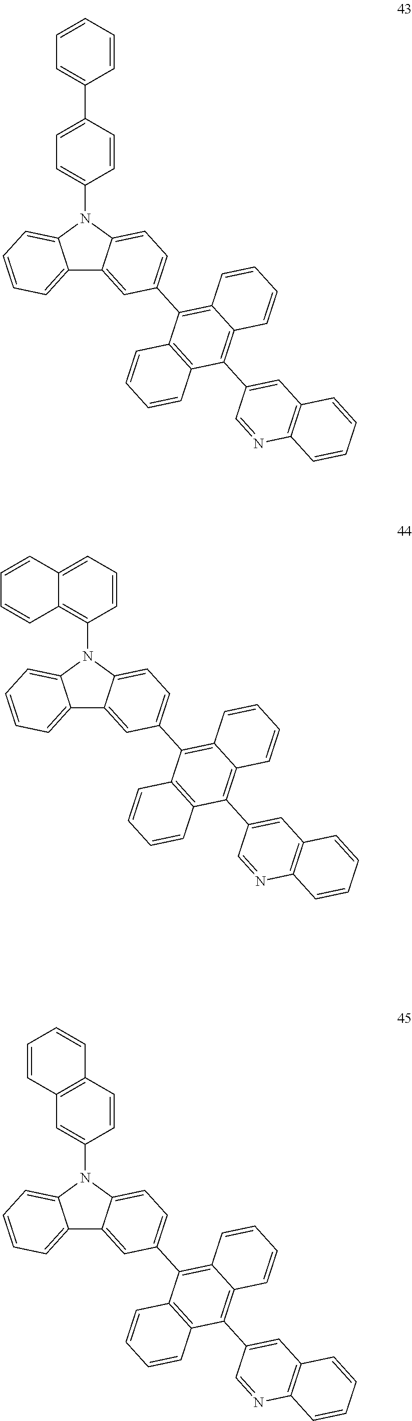 [SMILES: c1ccc(-c2ccc(-n3c4ccccc4c4cc(-c5c6ccccc6c(-c6cnc7ccccc7c6)c6ccccc56)ccc43)cc2)cc1 ; c1ccc2ncc(-c3c4ccccc4c(-c4ccc5c(c4)c4ccccc4n5-c4cccc5ccccc45)c4ccccc34)cc2c1 ; c1ccc2cc(-n3c4ccccc4c4cc(-c5c6ccccc6c(-c6cnc7ccccc7c6)c6ccccc56)ccc43)ccc2c1]

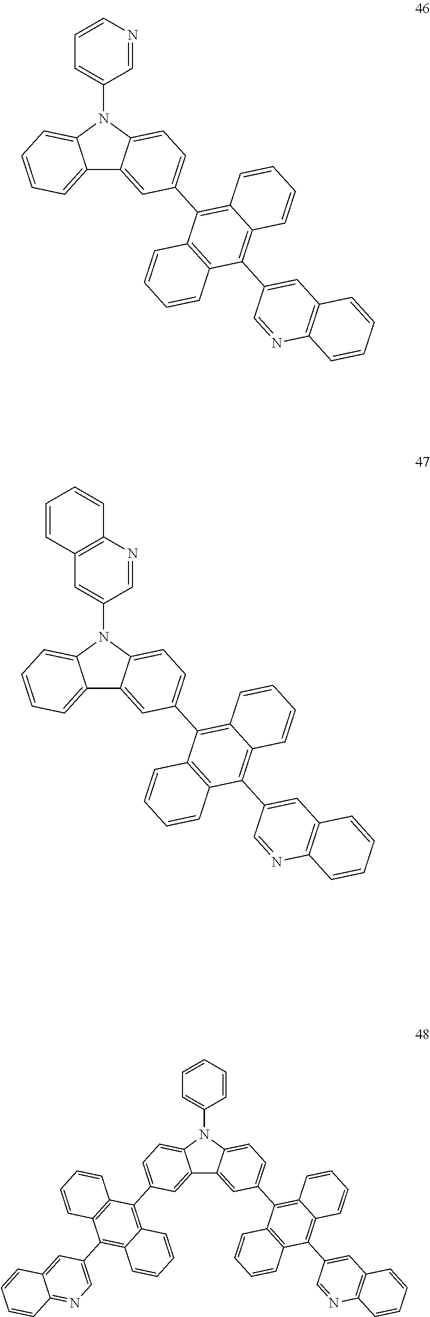 [SMILES: c1cncc(-n2c3ccccc3c3cc(-c4c5ccccc5c(-c5cnc6ccccc6c5)c5ccccc45)ccc32)c1 ; c1ccc2ncc(-c3c4ccccc4c(-c4ccc5c(c4)c4ccccc4n5-c4cnc5ccccc5c4)c4ccccc34)cc2c1 ; c1ccc(-n2c3ccc(-c4c5ccccc5c(-c5cnc6ccccc6c5)c5ccccc45)cc3c3cc(-c4c5ccccc5c(-c5cnc6ccccc6c5)c5ccccc45)ccc32)cc1]

13. The organic light-emitting device of claim 1, wherein the compound of Formula 2 is one of the compounds below:

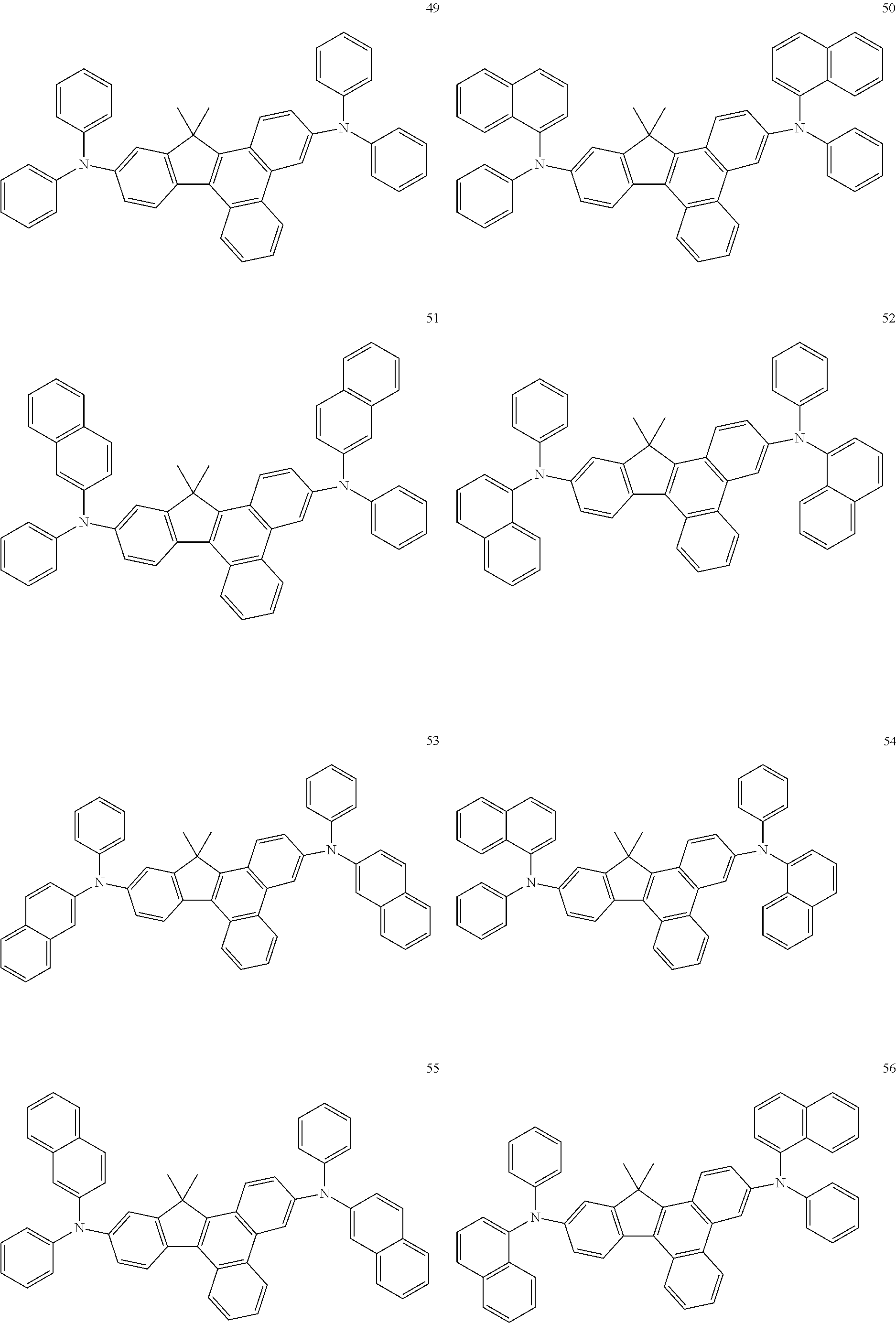

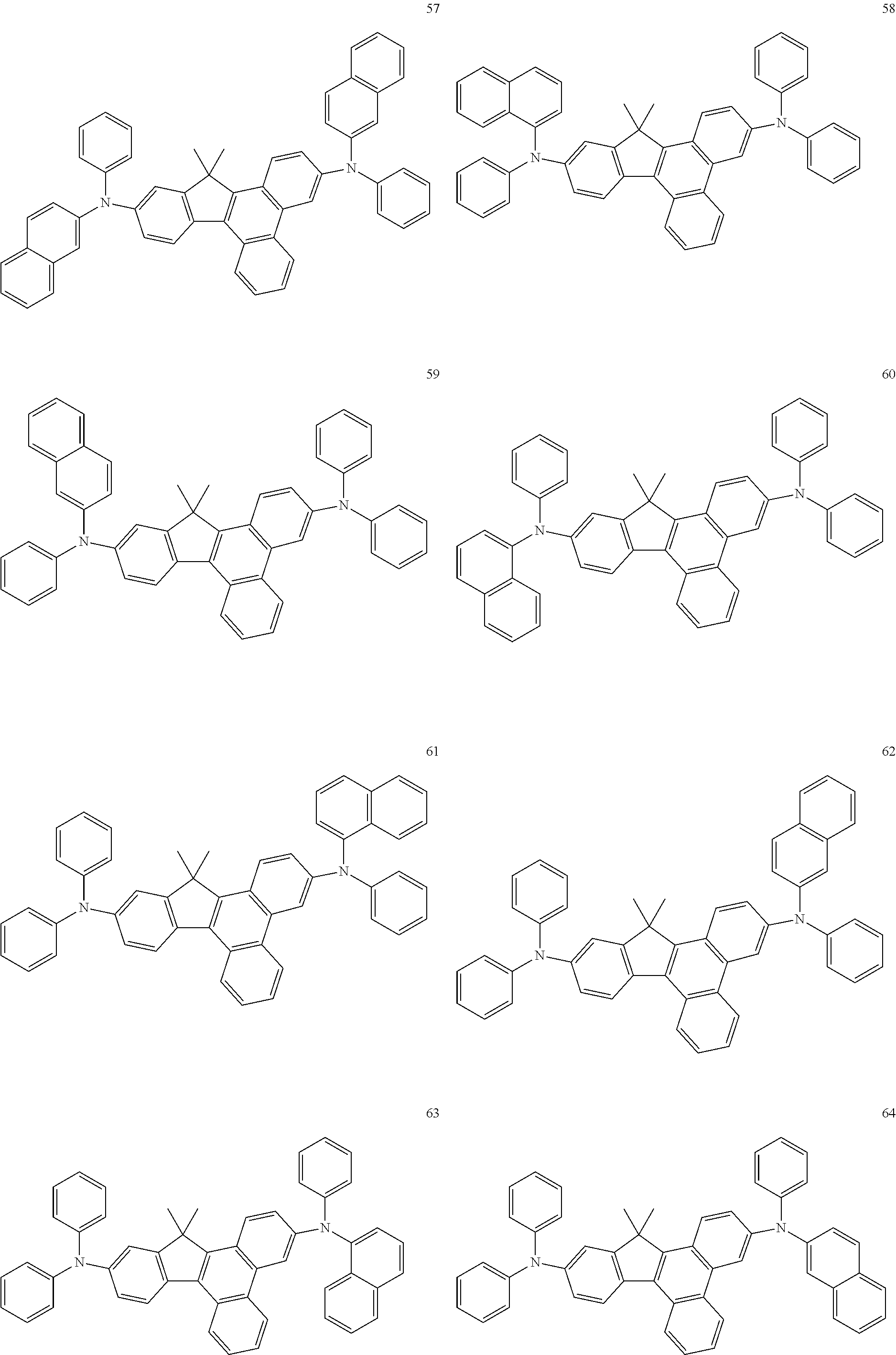

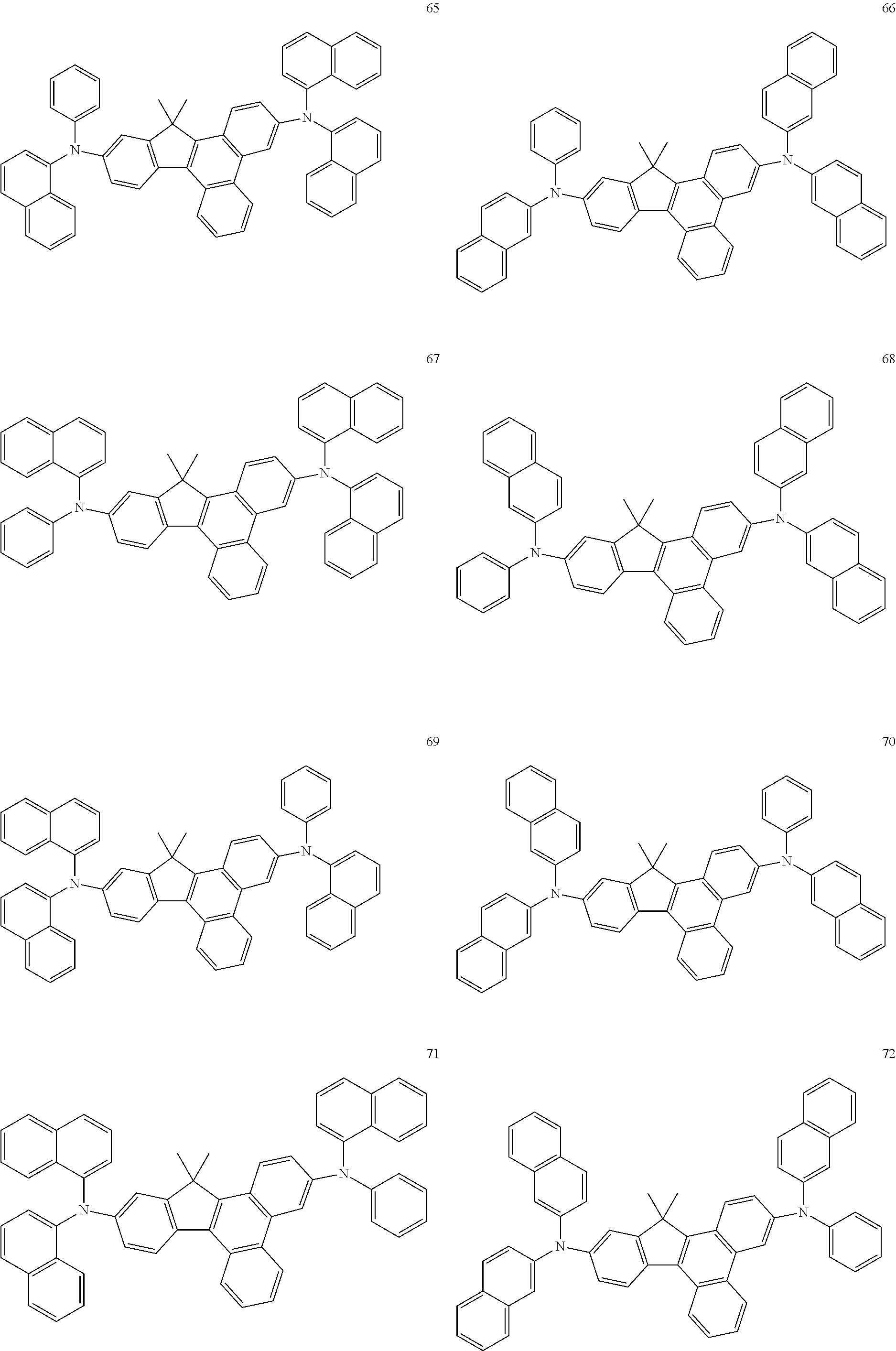

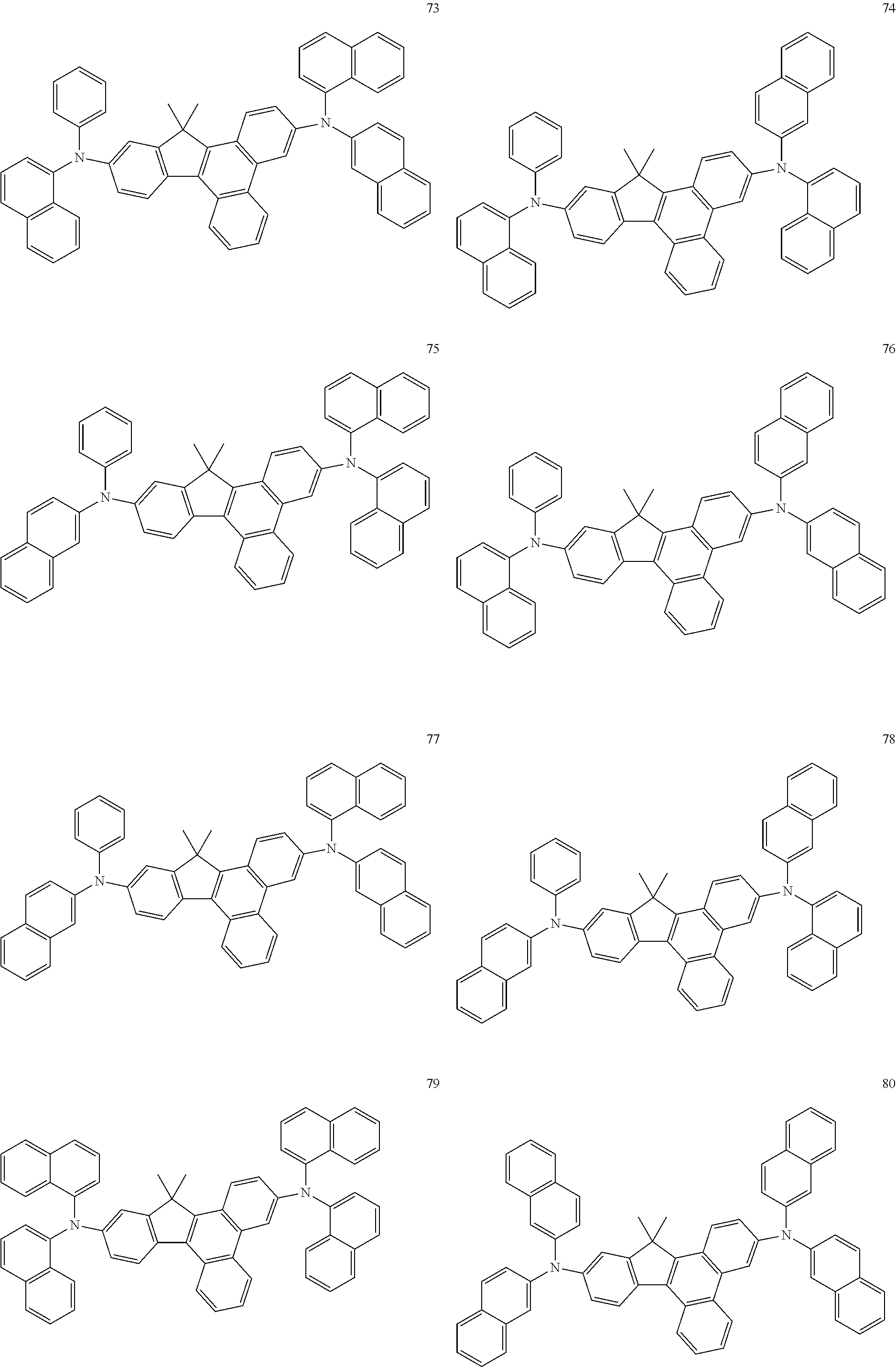

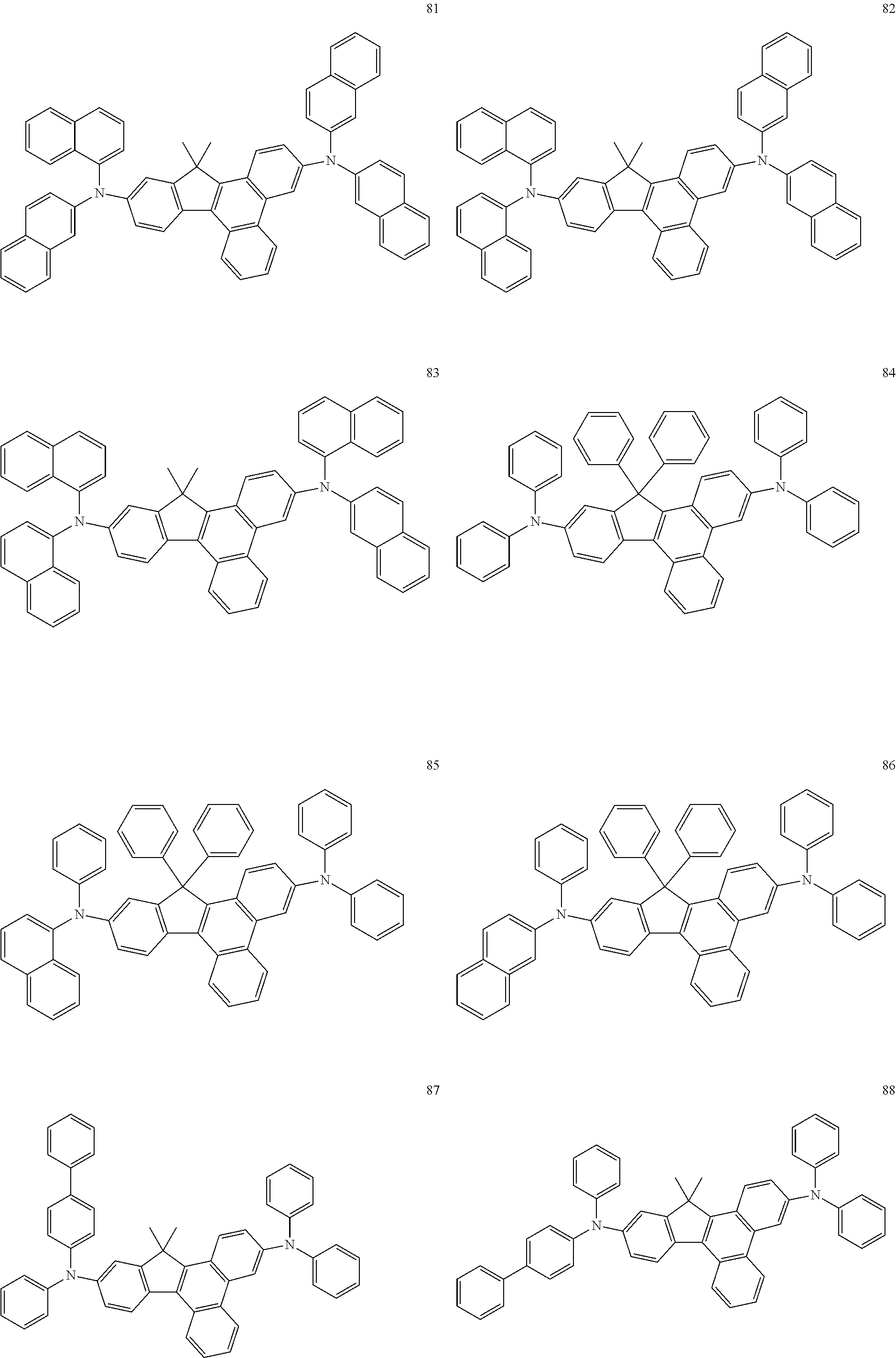

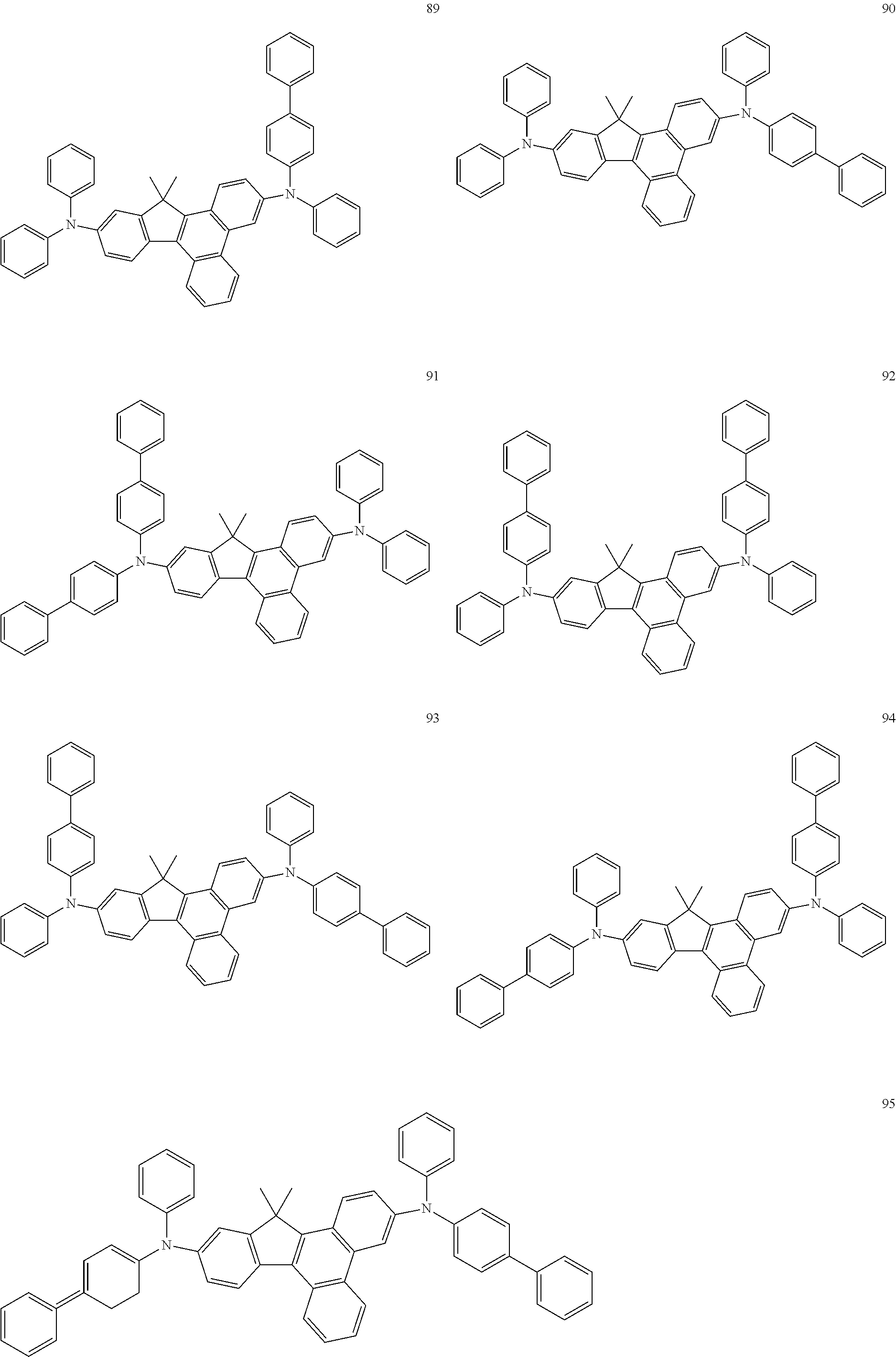

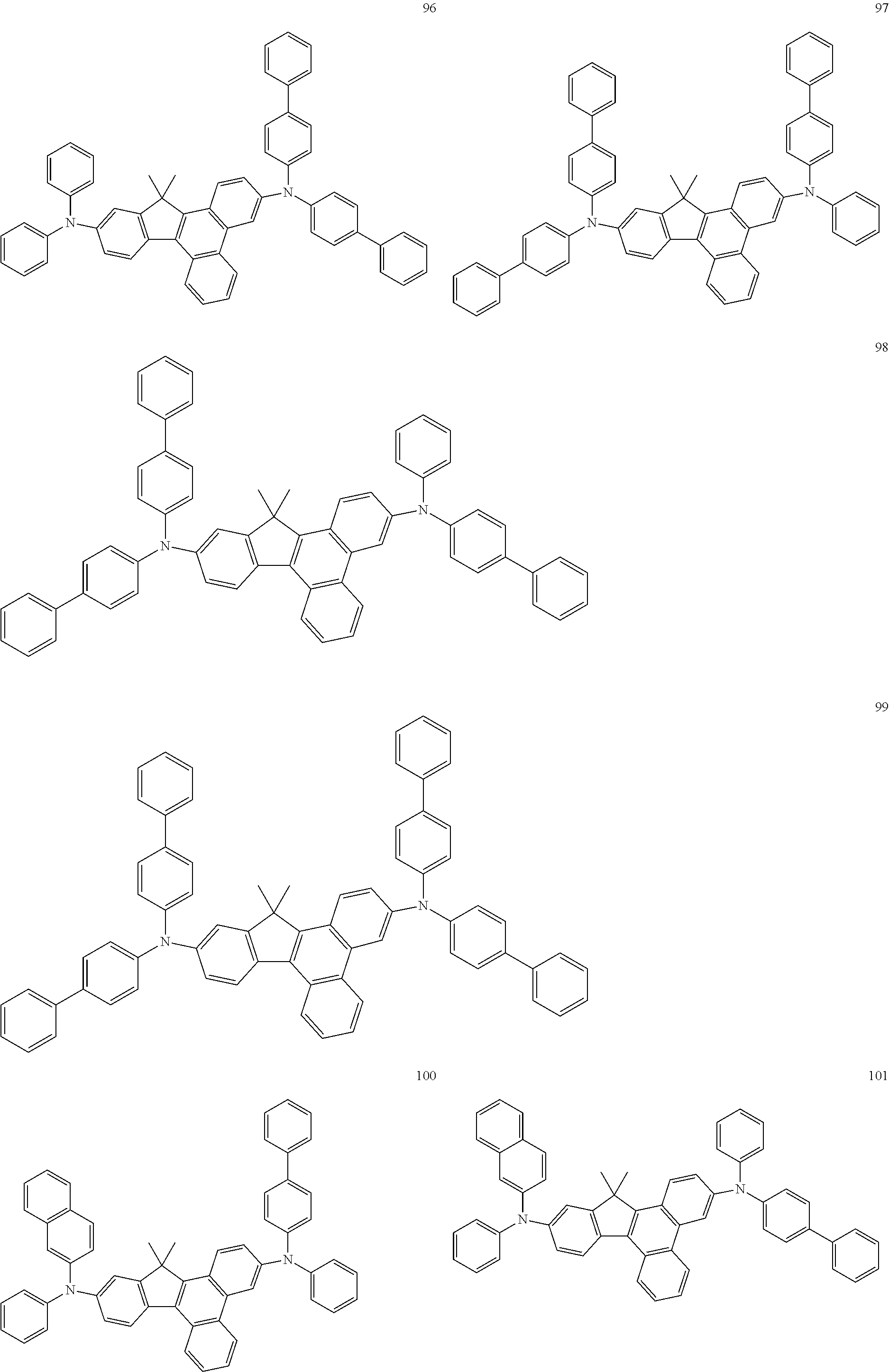

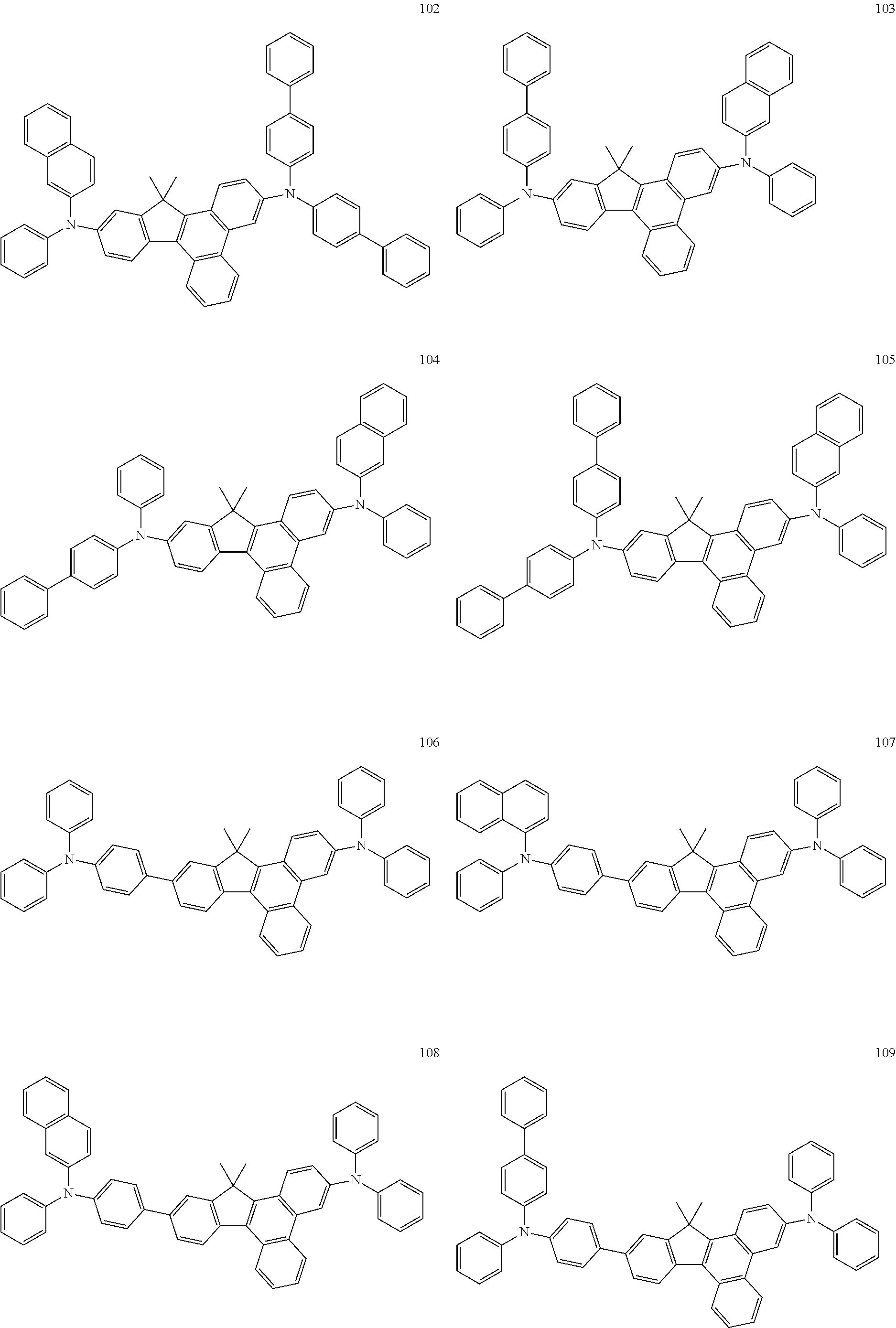

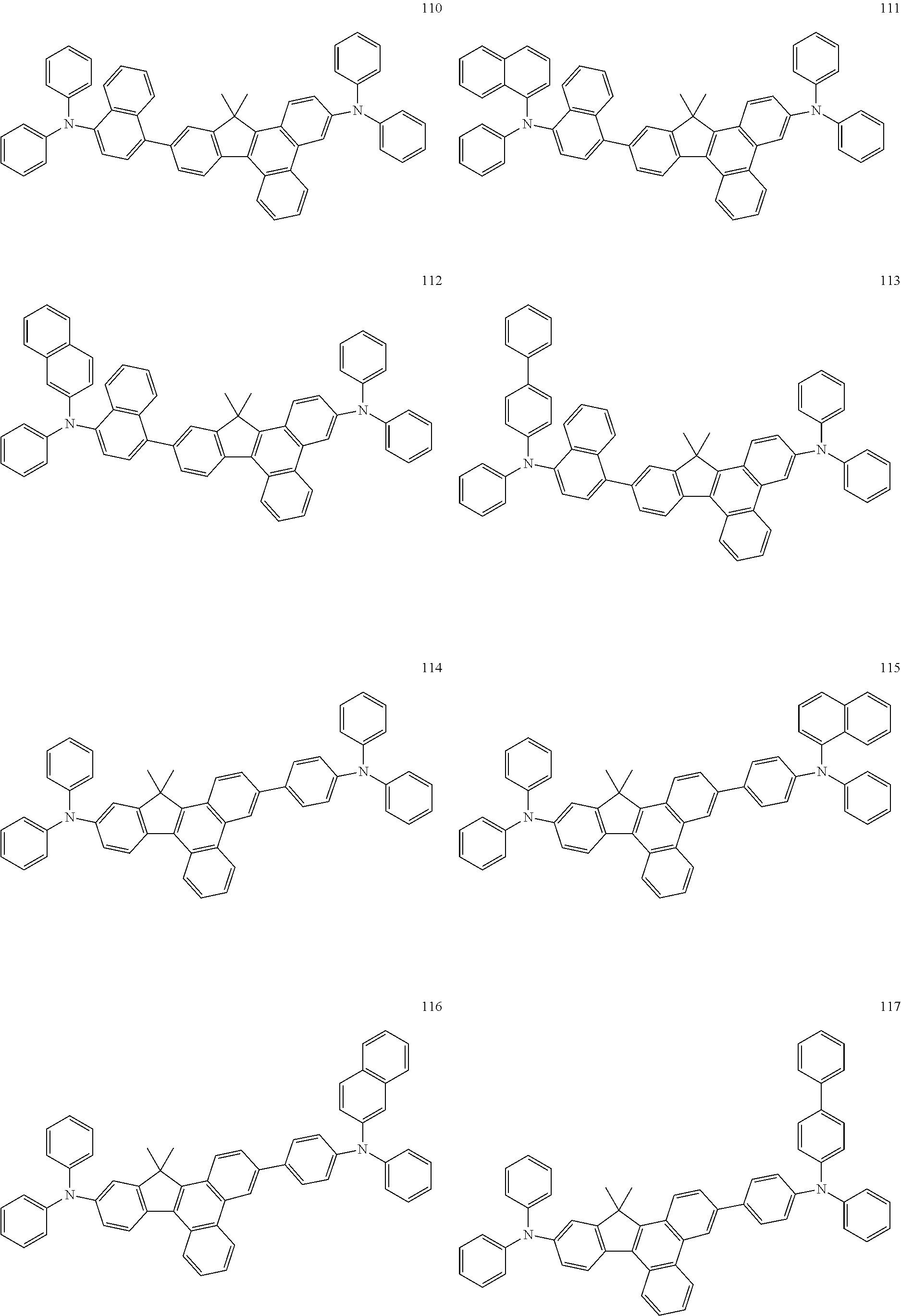

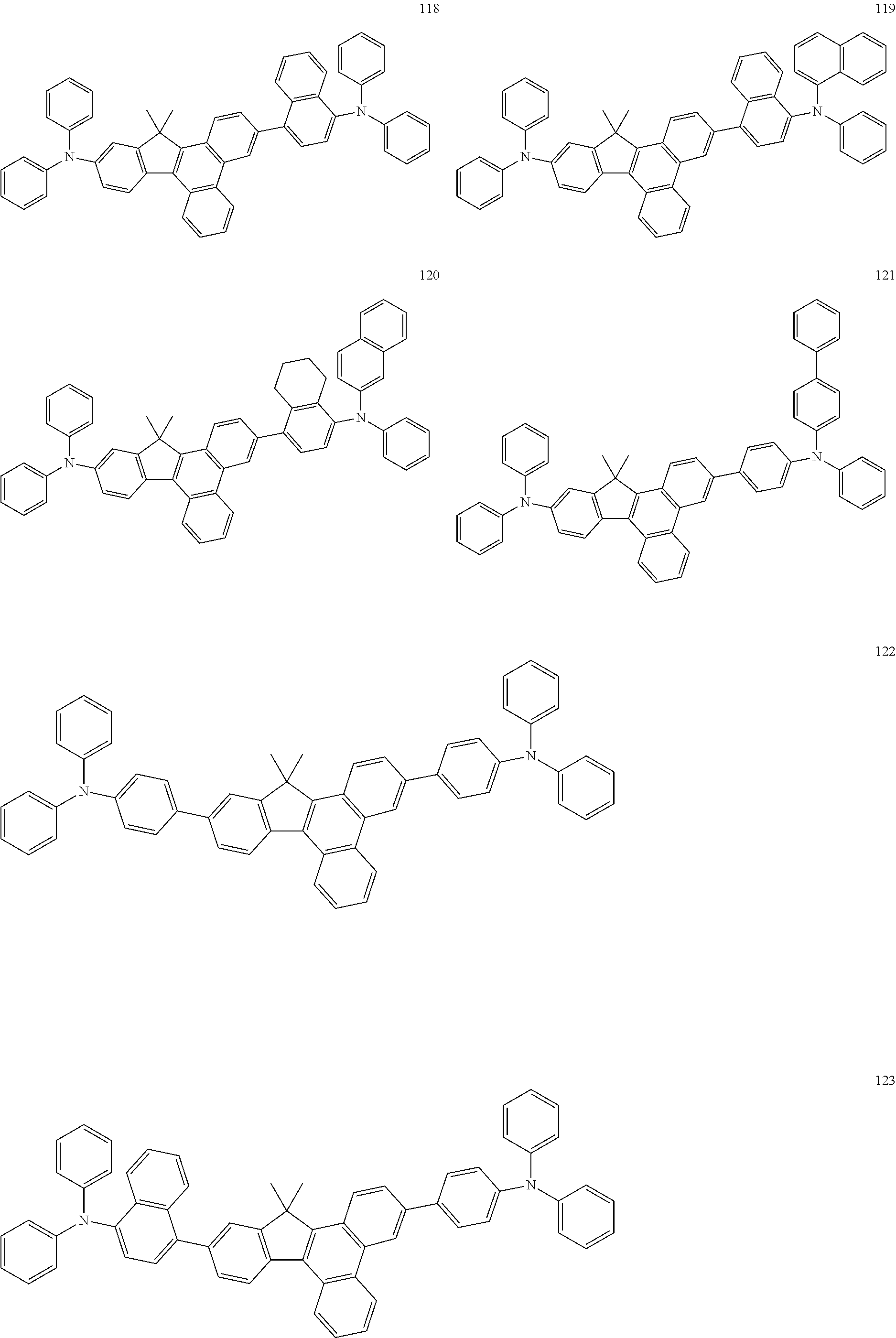

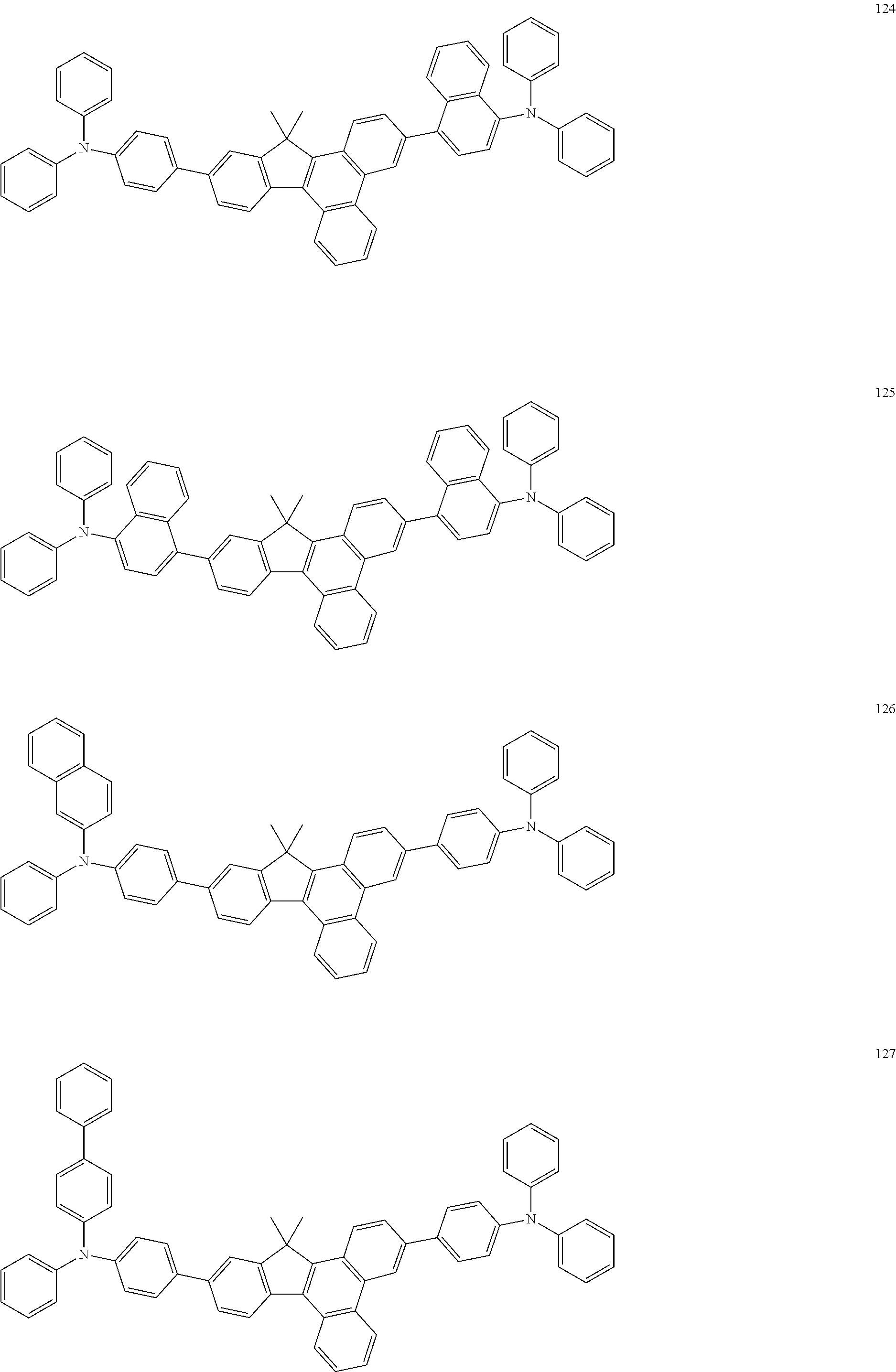 [SMILES: CC1(C)c2cc(-c3ccc(N(c4ccccc4)c4ccccc4)cc3)ccc2-c2c1c1ccc(-c3ccc(N(c4ccccc4)c4ccccc4)c4ccccc34)cc1c1ccccc21 ; CC1(C)c2cc(-c3ccc(N(c4ccccc4)c4ccccc4)c4ccccc34)ccc2-c2c1c1ccc(-c3ccc(N(c4ccccc4)c4ccccc4)c4ccccc34)cc1c1ccccc21 ; CC1(C)c2cc(-c3ccc(N(c4ccccc4)c4ccc5ccccc5c4)cc3)ccc2-c2c1c1ccc(-c3ccc(N(c4ccccc4)c4ccccc4)cc3)cc1c1ccccc21 ; CC1(C)c2cc(-c3ccc(N(c4ccccc4)c4ccc(-c5ccccc5)cc4)cc3)ccc2-c2c1c1ccc(-c3ccc(N(c4ccccc4)c4ccccc4)cc3)cc1c1ccccc21]

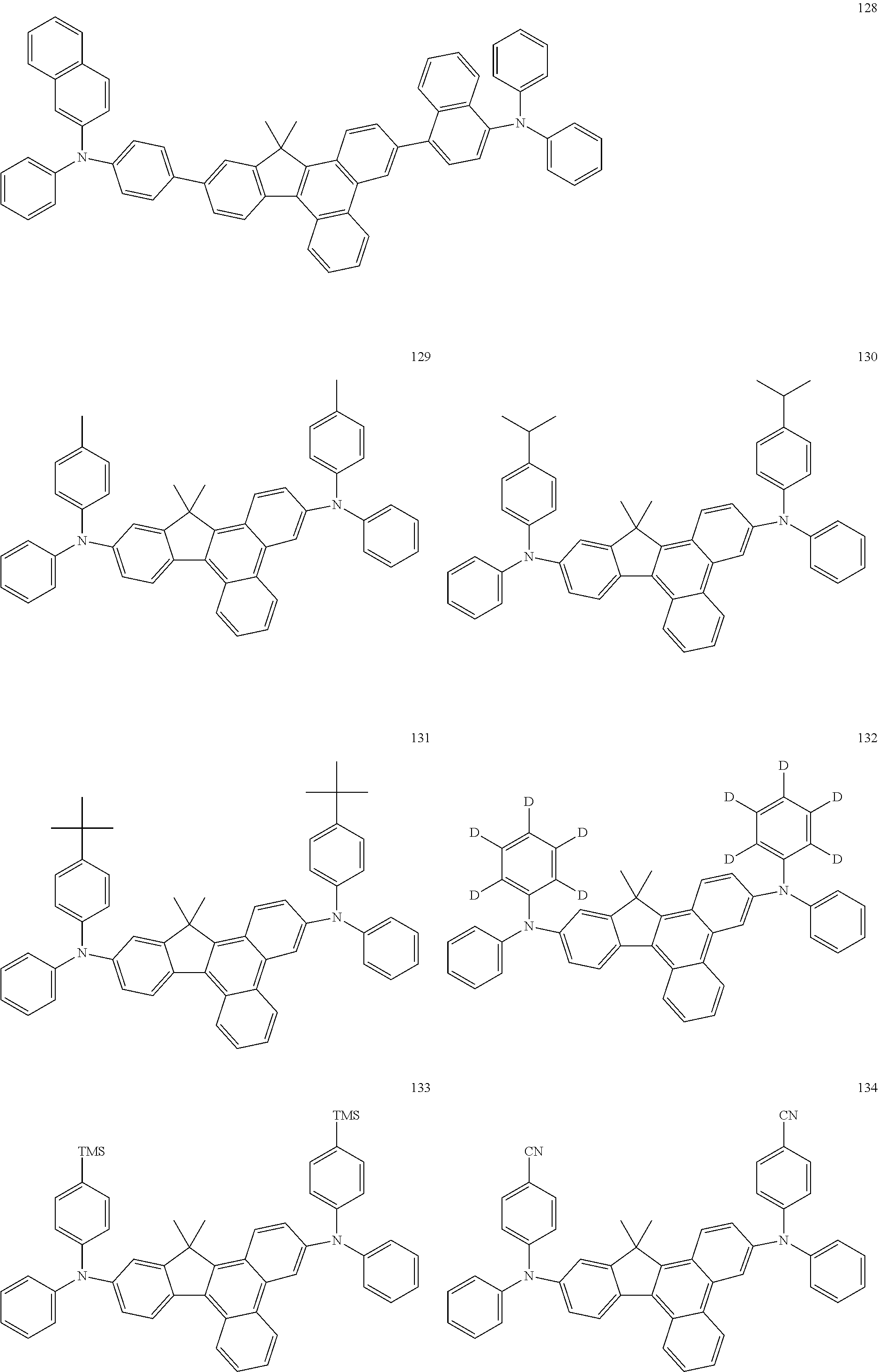

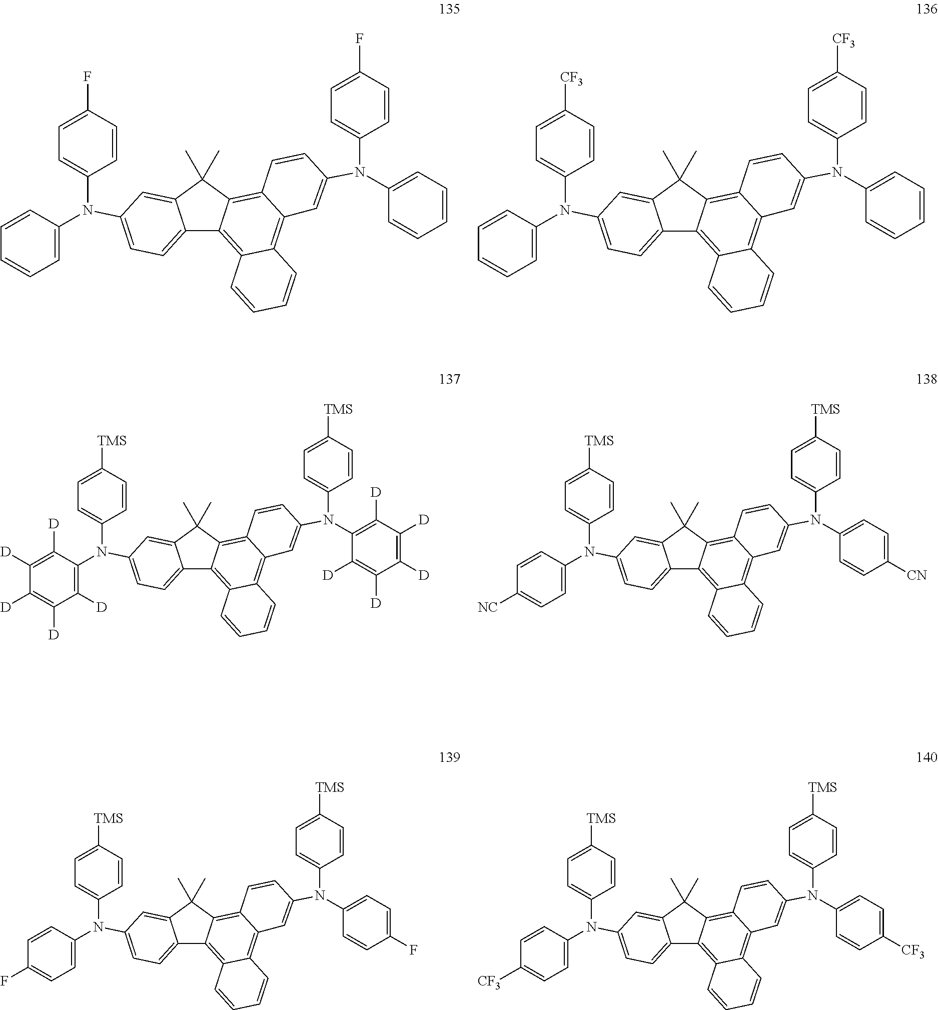

14. The organic light-emitting device of claim 1, wherein the organic layer comprises a blue emission layer.

15. The organic light-emitting device of claim 1, wherein the organic layer comprises an emission layer, a hole injection layer, a hole transport layer, or a functional layer having both hole injection and hole transport capabilities, and the emission layer comprises red, green, blue, and white emission layers one of which comprises a phosphorescent compound.

16. The organic light-emitting device of claim 15, wherein at least one of the hole injection layer, the hole transport layer, and the functional layer having both hole injection and hole transport capabilities further comprises a charge-generating material.

17. The organic light-emitting device of claim 1, wherein the charge-generating material is a p-type dopant.

18. The organic light-emitting device of claim 1, wherein the organic light-emitting device is a white organic light-emitting device.

19. The organic light-emitting device of claim 1, wherein the organic layer is formed from the compound of Formula 1 or the compound of Formula 2 using a wet process.

20. A flat panel display device comprising the organic light-emitting device of claim 1, wherein the first electrode of the organic light-emitting device is electrically connected to a source electrode or a drain electrode of a thin-film transistor.
